(19) United States
(12) Patent Application Publication
(10) Pub. No.: US 2025/0311529 A1
(43) Pub. Date: Oct. 2, 2025

(54) ORGANIC ELECTROLUMINESCENT DEVICE AND DISPLAY DEVICE THEREOF

(71) Applicant: BEIJING SUMMER SPROUT TECHNOLOGY CO., LTD., Beijing (CN)

(72) Inventors: Chi Yuen Raymond Kwong, Beijing (CN); Zhen WANG, Beijing (CN); Hongbo LI, Beijing (CN); Zheng Wang, Beijing (CN); Wei CAI, Beijing (CN); Chunliang ZHAO, Beijing (CN); Xuechao TIAN, Beijing (CN); Chuanjun XIA, Beijing (CN)

(21) Appl. No.: 19/092,964

(22) Filed: Mar. 27, 2025

(30) Foreign Application Priority Data
Mar. 29, 2024 (CN) 202410378512.5

(51) Int. Cl. H10K 50/11; H10K 85/30; H10K 85/60; H10K 101/25

(52) U.S. Cl. CPC H10K 50/11; H10K 85/342; H10K 85/622; H10K 85/631; H10K 85/654; H10K 85/656; H10K 85/6572; H10K 85/6574; H10K 85/6576; H10K 85/658; H10K 2101/25

(57) ABSTRACT

Provided are an organic electroluminescent device and a display device. The organic electroluminescent device includes an anode, a cathode and an emissive layer disposed between the anode and the cathode, where the emissive layer includes a metal complex having a particular ligand L. and a fluorescent emissive material. The organic electroluminescent device of the present disclosure can further achieve a significant improvement in device efficiency and lifetime on the basis of maintaining a relatively low drive voltage and a relatively narrow half width at half maximum, having excellent overall performance. Further provided is a display device comprising the organic electroluminescent device.

### CROSS-REFERENCE TO RELATED APPLICATION(S)

This application claims priority to Chinese Patent Application No. 202410378512.5 filed on Mar. 29, 2024, the disclosure of which is incorporated herein by reference in its entirety.

### TECHNICAL FIELD

The present disclosure relates to organic electronic devices, for example, organic electroluminescent devices. More particularly, the present disclosure relates to an organic electroluminescent device comprising a metal complex and a fluorescent emissive material in an emissive layer and a display device comprising the organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron transport layer and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

At present, the performance of fluorescent devices, such as the voltage, device efficiency and lifetime, still needs to be improved. Therefore, this type of device is worthy of deep research and development.

### SUMMARY

The present disclosure aims to provide a new organic electroluminescent device to solve at least part of the above problems. An emissive layer of the organic electroluminescent device comprises a metal complex having a particular ligand La and a fluorescent emissive material. The new organic electroluminescent device of the present disclosure can further achieve a significant improvement in device efficiency and/or lifetime on the basis of maintaining a relatively low drive voltage and a relatively narrow half width at half maximum, having excellent overall performance.

According to an embodiment of the present disclosure, disclosed is an organic electroluminescent device. The organic electroluminescent device comprises:
an anode,
a cathode, and
an emissive layer disposed between the anode and the cathode, wherein the emissive layer comprises at least a metal complex and a fluorescent emissive material;
wherein the metal complex comprises a metal M and a ligand La coordinated to the metal M, the metal M is selected from a metal with a relative atomic mass greater than 40, and La has a structure represented by Formula 1:

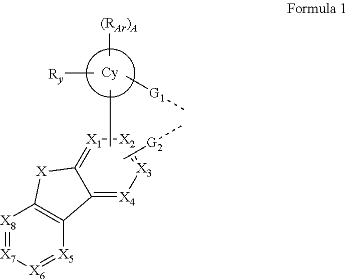

wherein,
the ring C_{y} is, at each occurrence identically or differently, selected from an aromatic ring having 6 to 30 ring atoms, a heteroaromatic ring having 5 to 30 ring atoms or a combination thereof;
G₁ and G₂ are, at each occurrence identically or differently, selected from a single bond, O, S or NR′,
X is selected from the group consisting of O, S, Se, CR₁R₁, SiR₁R₁ and GeR₁R₁;
X₁ to X₄ are each independently selected from C, CRₓ or N, one of X₁ to X₄ is selected from C and joined to the ring C_{y}, and one of X₁ to X₄ is selected from C or N and joined to G₂;
X₅ to X₈ are, at each occurrence identically or differently, selected from CRₓ or N;
R_{Ar} is, at each occurrence identically or differently, selected from the group consisting of: substituted or unsubstituted aryl having 6 to 30 carbon atoms, substituted or unsubstituted heteroaryl having 3 to 30 carbon atoms and combinations thereof;
A is, at each occurrence identically or differently, selected from 1, 2, 3 or 4;
R_{y} represents, at each occurrence identically or differently, mono-substitution, multiple substitutions or non-substitution;
Rₓ, R_{y}, R′ and R₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ, R_{y}, R′, R_{Ar} and R₁ can be optionally joined to form a ring.

According to another embodiment of the present disclosure, further disclosed is a display device comprising the organic electroluminescent device described above.

According to another embodiment of the present disclosure, further disclosed is an application of the organic electroluminescent device described above in a display device.

### BRIEF DESCRIPTION OF DRAWINGS

FIG. 1 is a schematic diagram of an organic light-emitting apparatus that may include an organic electroluminescent device disclosed herein.

FIG. 2 is a schematic diagram of another organic light-emitting apparatus that may include an organic electroluminescent device disclosed herein.

### DETAILED DESCRIPTION

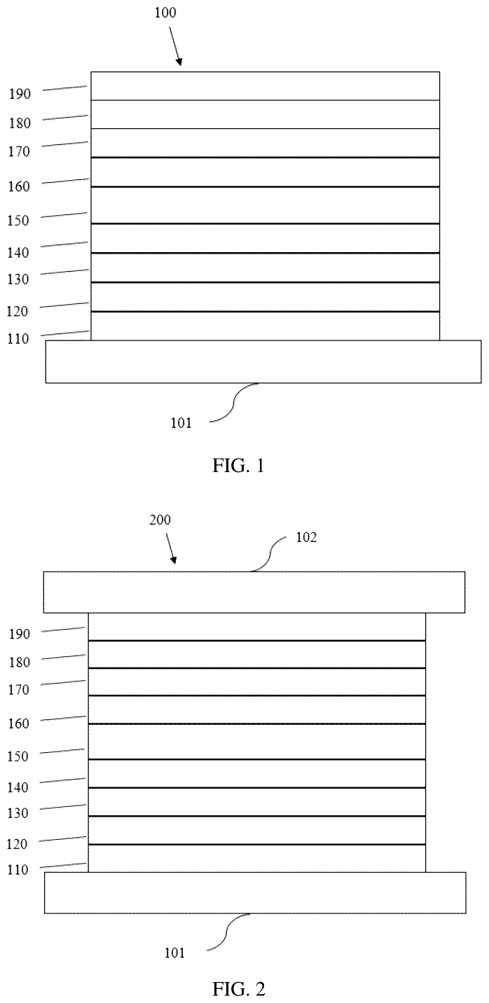

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly on the exterior of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

As used herein, “terminal emissive material” aims to refer to a material as a final light-emitting source when the organic electroluminescent device (a device with an emissive layer comprising at least two emissive materials) described herein is lit. For example, if the emissive layer of the organic electroluminescent device comprises a metal complex (a phosphorescent emissive material) and a fluorescent emissive material, when the device is lit, the two materials cause the metal complex not to emit light/almost not to emit light due to energy transfer. The fluorescent emissive material is used as a main light-emitting source in the device. Therefore, in this case, the fluorescent emissive material is the terminal emissive material of the organic electroluminescent device and includes, but is not limited to, Device Examples 1 and 2 of the present disclosure.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethvlisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethvl, trimethylsilylethyl, trimethylsilylisopropyl, triisopropylsilylmethyl and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group or an aromatic ring—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocyclyl—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl or a heteroaromatic ring—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, I-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

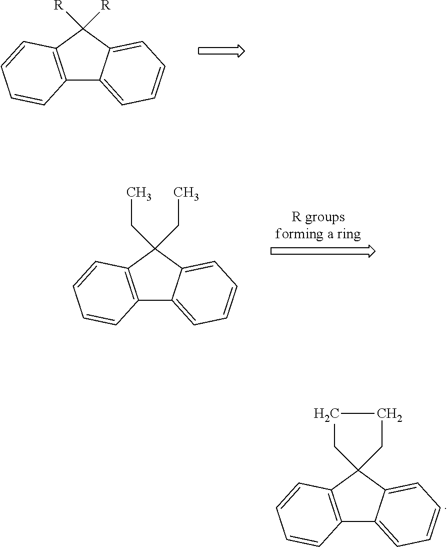

The expression that adjacent substituents can be optionally joined to form a ring is also intended to mean that two substituents bonded to carbon atoms which are directly bonded to each other are joined to each other via a chemical bond to form a ring, which can be exemplified by the following formula:

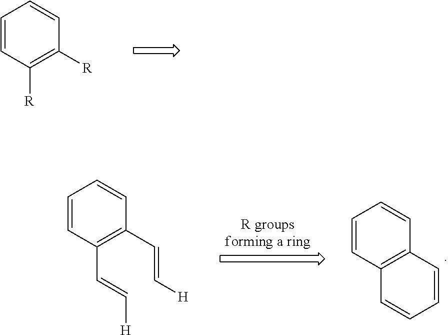

The expression that adjacent substituents can be optionally joined to form a ring is also intended to mean that two substituents bonded to further distant carbon atoms are joined to each other via a chemical bond to form a ring, which can be exemplified by the following formula:

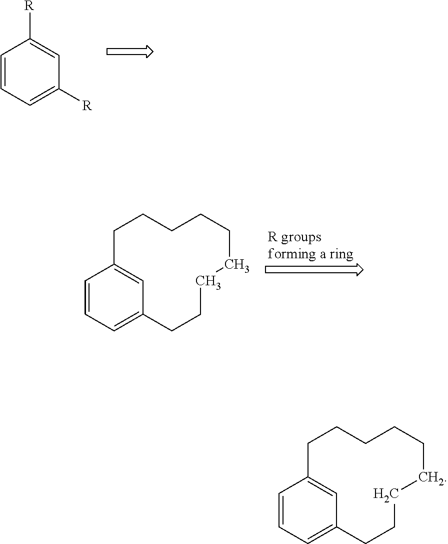

Furthermore, the expression that adjacent substituents can be optionally joined to form a ring is also intended to mean that, in the case where one of the two adjacent substituents represents hydrogen, the second substituent is bonded at a position at which the hydrogen atom is bonded, thereby forming a ring. This is exemplified by the following formula:

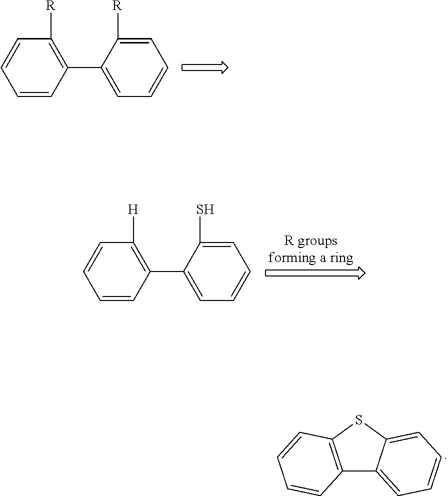

According to an embodiment of the present disclosure, disclosed is an organic electroluminescent device. The organic electroluminescent device comprises:
an anode,
a cathode, and
an emissive layer disposed between the anode and the cathode, wherein the emissive layer comprises at least a metal complex and a fluorescent emissive material;
wherein the metal complex comprises a metal M and a ligand Lₐ coordinated to the metal M, wherein the metal M is selected from a metal with a relative atomic mass greater than 40, and Lₐ has a structure represented by Formula 1:

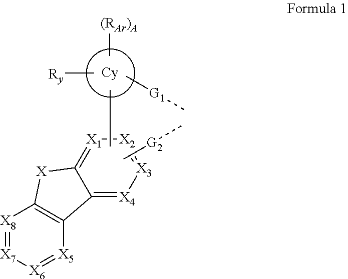

wherein,
the ring C_{y} is, at each occurrence identically or differently, selected from an aromatic ring having 6 to 30 ring atoms, a heteroaromatic ring having 5 to 30 ring atoms or a combination thereof;
G₁ and G₂ are, at each occurrence identically or differently, selected from a single bond, O, S or NR′;
X is selected from the group consisting of O, S, Se, CR₁R₁, SiR₁R₁ and GeR₁R₁;
X₁ to X₄ are each independently selected from C, CRₓ or N, one of X₁ to X₄ is selected from C and joined to the ring C_{y}, and one of X₁ to X₄ is selected from C or N and joined to G₂;
X₅ to X₈ are, at each occurrence identically or differently, selected from CRₓ or N;
R_{Ar} is, at each occurrence identically or differently, selected from the group consisting of: substituted or unsubstituted aryl having 6 to 30 carbon atoms, substituted or unsubstituted heteroaryl having 3 to 30 carbon atoms and combinations thereof;
A is, at each occurrence identically or differently, selected from 1, 2, 3 or 4;
R_{y} represents, at each occurrence identically or differently, mono-substitution, multiple substitutions or non-substitution;
Rₓ, R_{y}, R′ and R₁ are, at each occurrence identically or differently, selected from the group consisting of hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ, R_{y}, R′, R_{Ar} and R₁ can be optionally joined to form a ring.

In this embodiment, the expression that adjacent substituents Rₓ, R_{y}, R′, R_{Ar} and R₁ can be optionally joined to form a ring is intended to mean that any one or more of groups of adjacent substituents, such as two substituents R₁, two substituents Rₓ, two substituents R_{y}, two substituents R_{Ar}, substituents R_{Ar} and R_{y}, substituents R_{Ar} and Rₓ, substituents R_{y} and Rₓ, substituents R₁ and Rₓ, substituents R′ and Rₓ, substituents R′ and R_{y}, substituents R′ and R_{Ar}, and substituents R′ and R₁, can be joined to form a ring. Obviously, it is also possible that none of these groups of adjacent substituents are joined to form a ring.

According to an embodiment of the present disclosure, when X₁, X₂, X₃ or X₄ joined to G₂ is selected from N, G₂ is selected from a single bond, and X₁, X₂, X₃ or X₄ is joined to the metal by forming a metal-nitrogen bond through G₂; when X₁, X₂, X₃ or X₄ joined to G₂ is selected from C, G₂ is selected from a single bond, O, S or NR′, and X₁, X₂, X₃ or X₄ is joined to the metal through G₂: the ring C_{y} is joined to the metal M through G₁.

According to an embodiment of the present disclosure, the metal complex has a structure of Formula M(Lₐ)ₘ(L_{b})ₙ(L_{c})_{q}, wherein the ligands Lₐ, L_{b} and L_{c} are a first ligand, a second ligand and a third ligand coordinated to the metal M, respectively, and the ligands Lₐ, L_{b} and L_{c} can be optionally joined to form a multidentate ligand;
the metal M is selected from a metal with a relative atomic mass greater than 40;
m is selected from 1, 2 or 3, n is selected from 0, 1 or 2, q is selected from 0, 1 or 2, and m+n+q is equal to an oxidation state of the metal M; when m is greater than or equal to 2, multiple Lₐ are the same or different; when n is equal to 2, two L_{b} are the same or different; when q is equal to 2, two L_{c} are the same or different;
L_{b} and L_{c} are, at each occurrence identically or differently, selected from a structure represented by any one of the group consisting of the following:

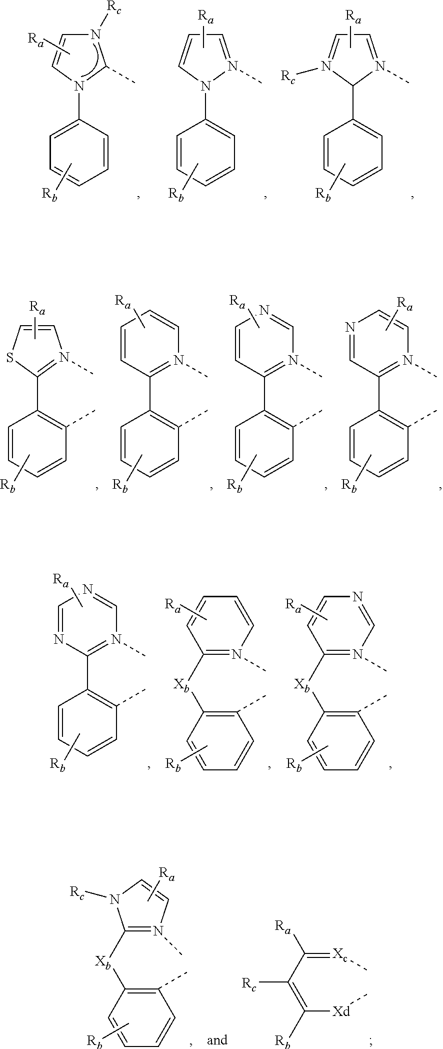

wherein,
Rₐ and R_{b} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N1};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{N2}, R_{C1} and R_{C2} can be optionally joined to form a ring.

In the present disclosure, the expression that “adjacent substituents Rₐ, R_{b}, R_{c}, R_{N1}, R_{N2}, R_{C1} and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. For example, adjacent substituents Rₐ and R_{b} in

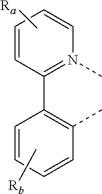

can be optionally joined to form a ring, which can form one or more of the following structures including, but not limited to,

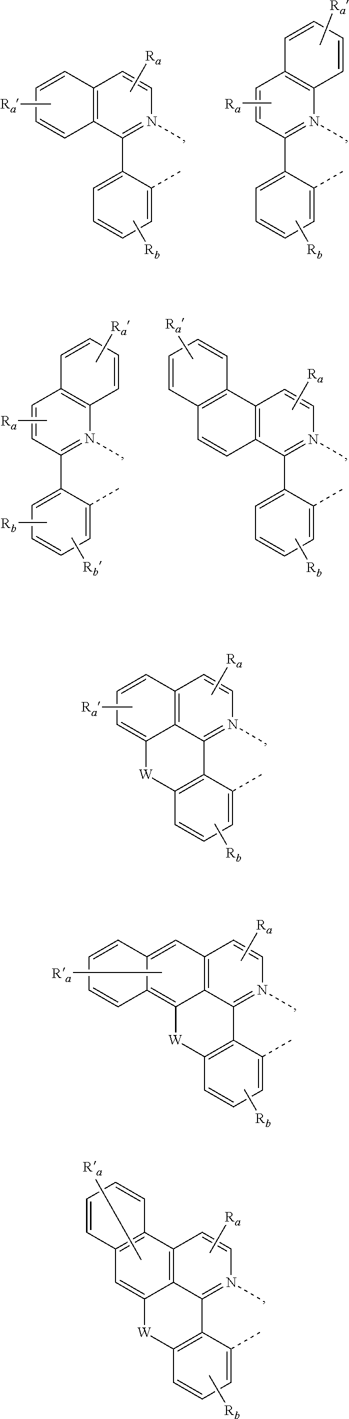

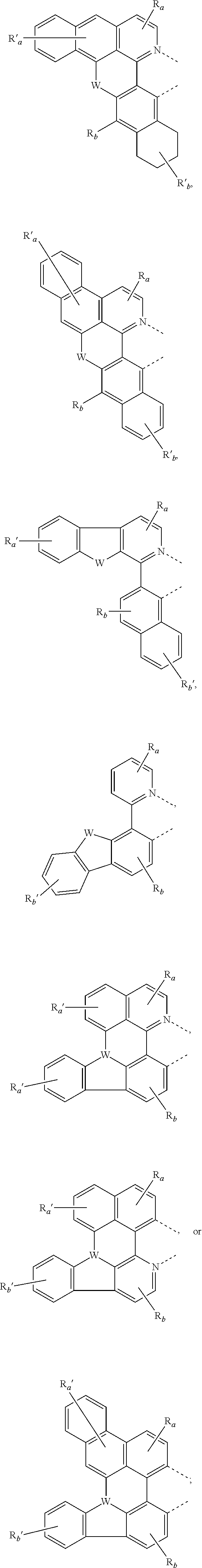

wherein W is selected from O, S, Se, NR_{w} or CR_{w}R_{w}, and R_{w}, Rₐ′ and R_{b}′ are defined the same as Rₐ. Obviously, it is also possible that none of these substituents are joined to form a ring.

According to an embodiment of the present disclosure, the metal M is selected from the group consisting of Cu, Ag, Au, Ru, Rh, Pd, Os, Ir and Pt.

According to an embodiment of the present disclosure, the metal M is selected from Pt or Ir.

According to an embodiment of the present disclosure, G₁ is a single bond, and the ring C_{y} is, at each occurrence identically or differently, selected from any one of the group consisting of the following structures:

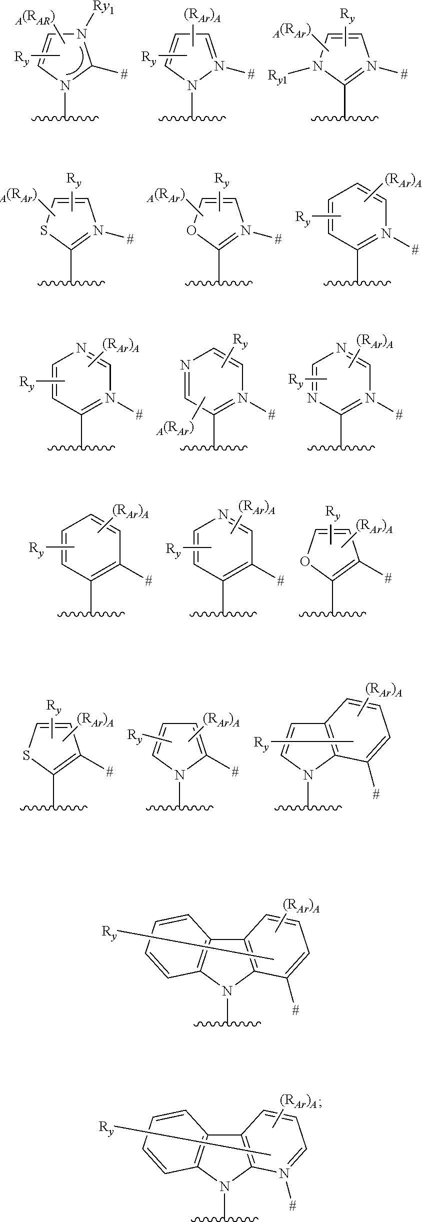

wherein,
R_{Ar} is, at each occurrence identically or differently, selected from the group consisting of: substituted or unsubstituted aryl having 6 to 30 carbon atoms, substituted or unsubstituted heteroaryl having 3 to 30 carbon atoms and combinations thereof;
A is, at each occurrence identically or differently, selected from 1, 2, 3 or 4;
R_{y} represents, at each occurrence identically or differently, mono-substitution, multiple substitutions or non-substitution;
R_{y} and R_{y}, are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{y} and R_{Ar} can be optionally joined to form a ring;
wherein “#” represents a position where C_{y} is joined to the metal M, and

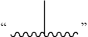

represents a position where C_{y} is joined to X₁, X₂, X₃ or X₄.

In this embodiment, the expression that “adjacent substituents R_{y} and R_{Ar} can be optionally joined to form a ring” is intended to mean that any one or more of groups of adjacent substituents, such as two substituents R_{y}, two substituents R_{Ar}, and substituents R_{Ar} and R_{y}, can be joined to form a ring. Obviously, it is also possible that none of these groups of adjacent substituents are joined to form a ring.

According to an embodiment of the present disclosure, the metal complex has a structure of Formula Ir(Lₐ)ₘ(L_{b})₃₋ₘ and has a structure represented by Formula 2:

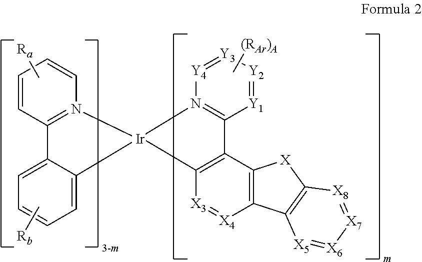

wherein,
m is selected from 1 or 2; when m is selected from 1, two L_{b} are the same or different; when m is selected from 2, two Lₐ are the same or different; preferably, m is 1;
X is selected from the group consisting of O, S, Se, CR₁R₁, SiR₁R₁ and GeR₁R₁;
X₃ to X₈ are each independently selected from CRₓ or N;
Y₁ to Y₄ are each independently selected from C, CR_{y} or N, and when Y₁ to Y₄ are selected from C, Y₁ to Y₄ are joined to R_{Ar};
A is, at each occurrence identically or differently, selected from 1, 2, 3 or 4;
R_{Ar} is, at each occurrence identically or differently, selected from the group consisting of: substituted or unsubstituted aryl having 6 to 30 carbon atoms, substituted or unsubstituted heteroaryl having 3 to 30 carbon atoms and combinations thereof;
Rₐ and R_{b} represent, at each occurrence identically or differently, mono-substitution, multiple substitutions or non-substitution;
Rₓ, R_{y}, R₁, Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁, Rₓ, R_{y}, R_{Ar}, Rₐ and R_{b} can be optionally joined to form a ring.

In this embodiment, the expression that adjacent substituents R₁, Rₓ, R_{y}, R_{Ar}, Rₐ and R_{b} can be optionally joined to form a ring is intended to mean that any one or more of groups of adjacent substituents, such as two substituents R₁, two substituents Rₓ, two substituents R_{y}, two substituents R_{Ar}, substituents R_{Ar} and R_{y}, substituents R_{Ar} and Rₓ, substituents R_{y} and Rₓ, substituents R₁ and Rₓ, two substituents Rₐ, two substituents R_{b}, and substituents Rₐ and R_{b}, can be joined to form a ring. Obviously, it is also possible that none of these groups of adjacent substituents are joined to form a ring.

According to an embodiment of the present disclosure, A is selected from 1 or 2.

According to an embodiment of the present disclosure, A is selected from 1.

According to an embodiment of the present disclosure, X is selected from O, S, Se and CR₁R₁.

According to an embodiment of the present disclosure, X is selected from O or S.

According to an embodiment of the present disclosure, X is selected from O.

According to an embodiment of the present disclosure, Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group and combinations thereof.

According to an embodiment of the present disclosure, at least one of Rₐ and/or at least one of R_{b} is(are), at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, a hydroxyl group, a sulfanyl group and combinations thereof.

According to an embodiment of the present disclosure, Rₓ and R_{y} are, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms and combinations thereof.

According to an embodiment of the present disclosure, Rₓ and R_{y} are, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted amino having 0 to 20 carbon atoms and combinations thereof.

According to an embodiment of the present disclosure, at least one of Y₁ to Y₄ is selected from CR_{y}, and R_{y} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, at least one of Y₁ or Y₄ is selected from CR_{y}, and R_{y} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof.

According to an embodiment of the present disclosure, Y₂ or Y₃ is selected from CR_{y}, and R_{y} is, at each occurrence identically or differently, selected from the group consisting of; deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof.

According to an embodiment of the present disclosure, Y₂ is selected from C and directly joined to R_{Ar}, or Y₃ is selected from C and directly joined to R_{Ar}.

According to an embodiment of the present disclosure, Y₂ is selected from C and directly joined to R_{Ar}, and Y₃ is selected from CR_{y}; or Y₃ is selected from C and directly joined to RA, and Y₂ is selected from CR_{y}; R_{y} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, a hydroxyl group, a sulfanyl group and combinations thereof.

According to an embodiment of the present disclosure, Y₂ is selected from C and directly joined to R_{Ar}, and Y₃ is selected from CR_{y}; or Y₃ is selected from C and directly joined to R_{Ar}, and Y₂ is selected from CR_{y}; R_{y} is, at each occurrence identically or differently, selected from substituted or unsubstituted alkyl having 1 to 20 carbon atoms, substituted or unsubstituted cycloalkyl having 3 to 20 ring carbon atoms or a combination thereof.

According to an embodiment of the present disclosure, X₃ to X₈ are each independently selected from CRₓ.

According to an embodiment of the present disclosure, X₃ to X₈ are each independently selected from CRₓ, and Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, a hydroxyl group, a sulfanyl group and combinations thereof.

According to an embodiment of the present disclosure, Rₓ is, at each occurrence identically or differently, selected from the group consisting of: hydrogen, deuterium, fluorine, cyano, hydroxyl, sulfanyl, methyl, deuterated methyl, ethyl, n-propyl, isopropyl, cyclopropyl, n-butyl, isobutyl, r-butyl, cyclopentyl, neopentyl, cyclohexyl, trimethylsilyl, trimethylgermanyl, phenyl, biphenyl, terphenyl, triphenylene, naphthyl, phenanthryl, anthryl, indenyl, fluorenyl, indolyl, carbazolyl, benzofuranyl, dibenzofuranyl, benzosilolyl, dibenzosilolyl, benzothienyl, dibenzothienyl, dibenzoselenophenyl and combinations thereof.

According to an embodiment of the present disclosure, at least one of X₃ to X₈ is selected from N.

According to an embodiment of the present disclosure, X₈ is selected from N.

According to an embodiment of the present disclosure, X₈ is N, X₃ to X₇ are selected from CRₓ, and Rₓ is, at each occurrence identically or differently, selected from the group consisting of hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group and combinations thereof.

According to an embodiment of the present disclosure, at least one of X₃ to X₈ is selected from CRₓ, and Rₓ is selected from cyano or fluorine.

According to an embodiment of the present disclosure, X₇ is selected from CRₓ, Rₓ is cyano or fluorine; or X₈ is selected from CRₓ, and Rₓ is cyano.

According to an embodiment of the present disclosure, R_{Ar} has a structure represented by any one of Ar-1 to Ar-86, wherein the specific structures of Ar-1 to Ar-86 are referred to in claim 13.

According to an embodiment of the present disclosure, hydrogen in Ar-1 to Ar-86 can be partially or fully substituted with deuterium.

According to an embodiment of the present disclosure, R_{Ar} has a structure represented by Ar-68 to Ar-86.

According to an embodiment of the present disclosure, Lₐ is, at each occurrence identically or differently, selected from the group consisting of Lₐ₁ to Lₐ₅₉₀, wherein the specific structures of Lₐ₁ to Lₐ₅₉₀ are referred to in claim 14.

According to an embodiment of the present disclosure, * in the structures of P1 to P20 represents a position where P1 to P20 are joined to the ligand Lₐ.

According to an embodiment of the present disclosure, L_{b} is, at each occurrence identically or differently, selected from the group consisting of L_{b1} to L_{b162}, wherein the specific structures of L_{b1} to L_{b162} are referred to in claim 15.

According to an embodiment of the present disclosure, hydrogen in L_{b1} to L_{b18}, L_{b20} to L_{b26} and L_{b31} to L_{b162} can be partially or fully substituted with deuterium.

According to an embodiment of the present disclosure, the metal complex has a structure of Ir(Lₐ)(L_{b})₂, wherein the two L_{b} are the same or different, Lₐ is, at each occurrence identically or differently, selected from any one of the group consisting of Lₐ₁ to Lₐ₅₉₀, and L_{b} is, at each occurrence identically or differently, selected from any two of the group consisting of L_{b1} to L_{b162}.

According to an embodiment of the present disclosure, the metal complex is selected from the group consisting of Metal Complex 1 to Metal Complex 688, and Metal Complex 1 to Metal Complex 688 each have a structure represented by Ir(Lₐ)(L_{b})₂, wherein the specific structures of Metal Complex 1 to Metal Complex 688 are referred to in claim 16.

According to an embodiment of the present disclosure, hydrogen in Metal Complex 1 to Metal Complex 688 can be partially or fully substituted with deuterium.

According to an embodiment of the present disclosure, a maximum emission wavelength in a photoluminescence spectrum of the metal complex is λₘₐₓ₁, and 500 nm≤λₘₐₓ₁≤600 nm.

According to an embodiment of the present disclosure, a maximum emission wavelength in a photoluminescence spectrum of the metal complex is λₘₐₓ₁, and 505 nm≤λₘₐₓ₁≤560 nm.

According to an embodiment of the present disclosure, a maximum emission wavelength in a photoluminescence spectrum of the metal complex is λₘₐₓ₁, and 510 nm≤λₘₐₓ₁≤550 nm.

According to an embodiment of the present disclosure, the fluorescent emissive material comprises at least one boron-nitrogen heterocyclic structure.

According to an embodiment of the present disclosure, the fluorescent emissive material comprises at least one substituted or unsubstituted carbazole structure.

According to an embodiment of the present disclosure, the fluorescent emissive material comprises at least two substituted or unsubstituted carbazole structures.

According to an embodiment of the present disclosure, the fluorescent emissive material comprises at least one substituted or unsubstituted diarylamino structure.

According to an embodiment of the present disclosure, the fluorescent emissive material comprises at least two substituted or unsubstituted diarylamino structures.

According to an embodiment of the present disclosure, the fluorescent emissive material comprises at least one substituted or unsubstituted carbazole group and at least one substituted or unsubstituted diarylamino structure.

According to an embodiment of the present disclosure, the fluorescent emissive material has a structure represented by Formula 3:

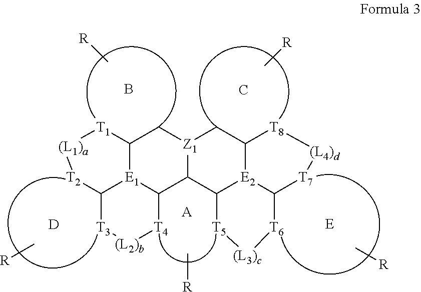

wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Z₁, E₁ and E₂ are each independently selected from B, N, P, P═O, P=S, As, As═O, As═S, SiR_{Si1} or GeR_{Ge1};
T₁ to T₈ are each independently selected from C, CRₜ or N,
a, b, c and d are each independently selected from 0 or 1;
L₁, L₂, L₃ and L₄ are, at each occurrence identically or differently, selected from a single bond, O, S, Se, BR_{L} or NR_{L};
R represents, at each occurrence identically or differently, mono-substitution, multiple substitutions or non-substitution;
R, Rₜ, R_{L}, R_{Si1} and R_{Ge1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of; hydrogen, deuterium, halogen, substituted or unsubstituted alkyl having 1 to 20 carbon atoms. substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and adjacent substituents R, Rₜ, R_{L}, R_{Si1}, R^{Ge1} and R^{B} can be optionally joined to form a ring.

In this embodiment, the expression that “a, b, c and d are each independently selected from 0 or 1” is intended to mean that T₁ and T₂ that correspond to a, T₃ and T₄ that correspond to b, T₅ and T₆ that correspond to c and T₇ and T₈ that correspond to d are joined or disjoined. For example, when a is 0, T₁ and T₂ are disjoined (that is, T₁ is not joined to T₂), and the same is true when one or more of a, b, c and d are 0.

In the present disclosure, the expression that adjacent substituents R, Rₜ, R_{L}, R_{Si1}, R_{Ge1} and R^{B} can be optionally joined to form a ring is intended to mean that any one or more of groups of adjacent substituents, such as two substituents R, two substituents R^{B}, substituents R and R_{Si1}, substituents R and R_{Ge1}, substituents R and R_{L}, and substituents R and R^{B}, can be joined to form a ring. Obviously, it is also possible that none of these groups of adjacent substituents are joined to form a ring.

In the present disclosure, “carbocyclic ring” comprises a saturated carbocyclic ring and an unsaturated carbocyclic ring, “unsaturated carbocyclic ring” comprises an aromatic unsaturated carbocyclic ring and anon-aromatic unsaturated carbocyclic ring, “heterocyclic ring” comprises a saturated heterocyclic ring and an unsaturated heterocyclic ring, and “unsaturated heterocyclic ring” comprises an aromatic unsaturated heterocyclic ring and a non-aromatic unsaturated heterocyclic ring.

According to an embodiment of the present disclosure, the fluorescent emissive material has a structure represented by Formula 5:

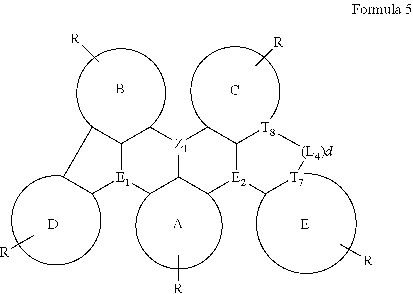

wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Z₁, E₁ and E₂ are each independently selected from B, N, P, P═O, P═S, As, As═O, As═S, SiR_{Si1} or GeR_{Ge1},
T₇ and T₈ are each independently selected from C, CRₜ or N;
d is selected from 0 and 1;
L₄ is, at each occurrence identically or differently, selected from a single bond, O, S, Se, BR_{L} or NR_{L};
R represents, at each occurrence identically or differently, mono-substitution, multiple substitutions or non-substitution;
R, Rₜ, R_{L}, R_{Si1} and R_{Ge1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, Rₜ, R_{L}, R_{Si1}, R_{Ge1} and R^{B} can be optionally joined to form a ring.

According to an embodiment of the present disclosure, the ring A, the ring B, the ring C, the ring D and the ring E are each independently selected from a five-membered unsaturated carbocyclic ring, an aromatic ring having 6 to 30 carbon atoms or a heteroaromatic ring having 3 to 30 carbon atoms.

According to an embodiment of the present disclosure, the ring A, the ring B, the ring C, the ring D and the ring E are each independently selected from a five-membered unsaturated carbocyclic ring, an aromatic ring having 6 to 18 carbon atoms or a heteroaromatic ring having 3 to 18 carbon atoms.

According to an embodiment of the present disclosure, the ring A, the ring B, the ring C, the ring D and the ring E are each independently selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring or a combination thereof.

According to an embodiment of the present disclosure, the ring A, the ring B, the ring C, the ring D and the ring E are selected from a benzene ring.

According to an embodiment of the present disclosure, Z₁ is selected from B, P═O or P═S, and E₁ and E₂ are each independently selected from N or P.

According to an embodiment of the present disclosure, Z₁ is selected from B, and E₁ and E₂ are selected from N.

According to an embodiment of the present disclosure, Z₁ is selected from N or P, and E₁ and E₂ are each independently selected from B, P═O or P═S.

According to an embodiment of the present disclosure, Z₁ is selected from N, and E₁ and E₂ are selected from B.

According to an embodiment of the present disclosure, L₁, L₂, L₃ and L₄ are, at each occurrence identically or differently, selected from a single bond, O, BR_{L} or NR_{L}.

According to an embodiment of the present disclosure, a+b+c+d is greater than or equal to 1.

According to an embodiment of the present disclosure, a+d is greater than or equal to 1.

According to an embodiment of the present disclosure, a is 0, and d is 1.

According to an embodiment of the present disclosure, a is 1, and d is 1.

According to an embodiment of the present disclosure, the fluorescent emissive material has a structure represented by any one of Formula 4-1 to Formula 4-7:

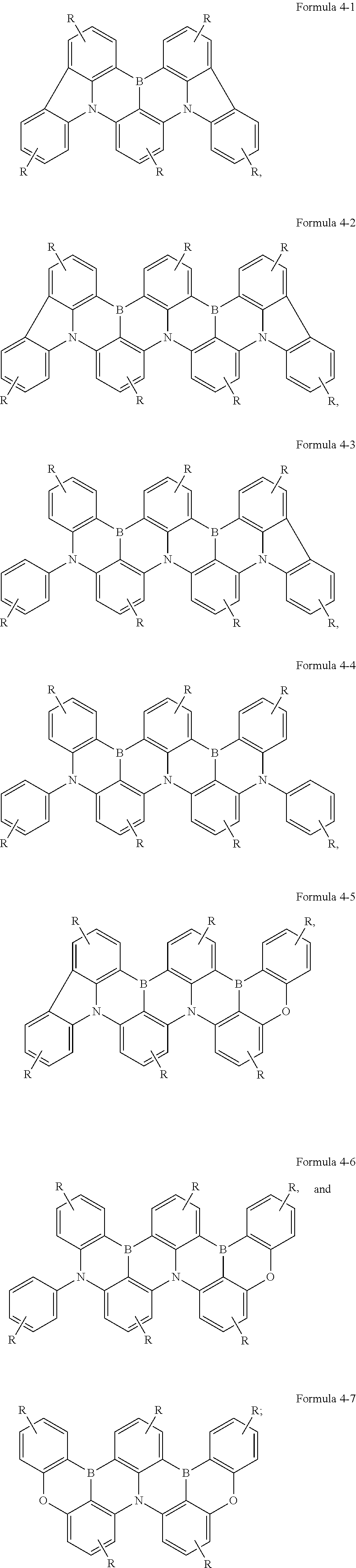

wherein,
R represents, at each occurrence identically or differently, mono-substitution, multiple substitutions or non-substitution;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR¹R^{B} and combinations thereof;
R^{B} is, at each occurrence identically or differently, selected from the group consisting of; hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R and R^{B} can be optionally joined to form a ring.

In this embodiment, the expression that adjacent substituents Rand R^{B} can be optionally joined to form a ring is intended to mean that on the same ring, two adjacent substituents R can be joined to form a ring and adjacent substituents R and R^{B} can be optionally joined to form a ring. Obviously, it is also possible that on the same ring, two adjacent substituents R are not joined to form a ring and adjacent substituents R and R^{B} are not joined to form a ring.

According to an embodiment of the present disclosure, the fluorescent emissive material has a structure represented by Formula 4-1 or Formula 4-2.

According to an embodiment of the present disclosure, R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms and combinations thereof.

According to an embodiment of the present disclosure, R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms and combinations thereof.

According to an embodiment of the present disclosure, a plurality of R exist in Formula 4-1 to Formula 4-7, and at least one (for example, one, two, three or four) of the plurality of R is selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms or a combination thereof.

According to an embodiment of the present disclosure, the fluorescent emissive material is selected from the group consisting of Compound DF-1 to Compound DF-102, wherein the specific structures of Compound DF-1 to Compound DF-102 are referred to in claim 25.

According to an embodiment of the present disclosure, hydrogen in Compound DF-1 to Compound DF-102 can be partially or fully substituted with deuterium.

According to an embodiment of the present disclosure, the fluorescent emissive material is a delayed fluorescence material.

According to an embodiment of the present disclosure, the fluorescent emissive material is a thermally activated delayed fluorescence (TADF) material.

According to an embodiment of the present disclosure, a maximum emission wavelength in a photoluminescence spectrum of the metal complex is λₘₐₓ₁, and 500 nm≤λₘₐₓ₁≤600 nm.

According to an embodiment of the present disclosure, a maximum emission wavelength in a photoluminescence spectrum of the metal complex is λₘₐₓ₁, and 505 nm≤λₘₐₓ₁≤560 nm.

According to an embodiment of the present disclosure, a maximum emission wavelength in a photoluminescence spectrum of the metal complex is λₘₐₓ₁, and 510 nm≤λₘₐₓ₁≤550 nm.

According to an embodiment of the present disclosure, a maximum emission wavelength in a photoluminescence spectrum of the fluorescent emissive material is λₘₐₓ₂, and 500 nm≤λₘₐₓ₂≤600 nm.

According to an embodiment of the present disclosure, a maximum emission wavelength in a photoluminescence spectrum of the fluorescent emissive material is λₘₐₓ₂, and 510 nm≤λₘₐₓ₂≤580 nm.

According to an embodiment of the present disclosure, a maximum emission wavelength in a photoluminescence spectrum of the fluorescent emissive material is λₘₐₓ₂, and 510 nm≤λₘₐₓ₂≤560 nm.

According to an embodiment of the present disclosure, a maximum emission wavelength in a photoluminescence spectrum of the metal complex is λₘₐₓ₁, and a maximum emission wavelength in a photoluminescence spectrum of the fluorescent emissive material is λₘₐₓ₂, wherein λₘₐₓ₁≤λₘₐₓ₂, or 0<λₘₐₓ₁−λₘₐₓ₂≤30 nm.

According to an embodiment of the present disclosure, 0≤λₘₐₓ₂−λₘₐₓ₁≤40 nm, or 0<λₘₐₓ₁−λₘₐₓ₂≤20 nm.

According to an embodiment of the present disclosure, 10 nm≤λₘₐₓ₂−λₘₐₓ₁≤30 nm, or 0<λₘₐₓ₁−λₘₐₓ₂≤10 nm.

According to an embodiment of the present disclosure, the organic electroluminescent device emits green light or yellow light.

According to an embodiment of the present disclosure, a maximum emission wavelength in an electroluminescent spectrum of the organic electroluminescent device is λₘₐₓ, and 500 nm≤λₘₐₓ≤600 nm.

According to an embodiment of the present disclosure, a maximum emission wavelength in an electroluminescent spectrum of the organic electroluminescent device is λₘₐₓ, and 510 nm≤λₘₐₓ≤580 nm.

According to an embodiment of the present disclosure, a weight of the fluorescent emissive material in the emissive layer of the organic electroluminescent device accounts for 0.01% to 5% of a total weight of the emissive layer.

According to an embodiment of the present disclosure, a weight of the fluorescent emissive material in the emissive layer of the organic electroluminescent device accounts for 0.05% to 3% of a total weight of the emissive layer.

According to an embodiment of the present disclosure, a weight of the fluorescent emissive material in the emissive layer of the organic electroluminescent device accounts for 0.1% to 1% of a total weight of the emissive layer.

According to an embodiment of the present disclosure, full width at half maximum FWHM2 of the fluorescent emissive material in the organic electroluminescent device is ≤60 nm.

According to an embodiment of the present disclosure, full width at half maximum FWHM2 of the fluorescent emissive material in the organic electroluminescent device is ≤50 nm.

According to an embodiment of the present disclosure, full width at half maximum FWHM2 of the fluorescent emissive material in the organic electroluminescent device is ≤40 nm.

According to an embodiment of the present disclosure, a triplet energy level of the metal complex is T_{1(Emt1)}, and a triplet energy level of the fluorescent emissive material is T_{1(Emt2)}, wherein T_{1(Emt1)}>T_{1(Emt2)}.

According to an embodiment of the present disclosure, a triplet energy level of a first host material is T₁₍ₕₒₛₜ₁₎, wherein T₁₍ₕₒₛₜ₁₎>T_{1(Emt1)}, and T₁₍ₕₒₛₜ₁₎>T_{1(Emt2)}.

According to an embodiment of the present disclosure, T₁₍ₕₒₛₜ₁₎>T_{1(Emt1)}>T_{1(Emt2)}.

According to an embodiment of the present disclosure, the emissive layer further comprises a second host material, and a triplet energy level of the second host material is T₁₍ₕₒₛₜ₂₎, wherein T₁₍ₕₒₛₜ₂₎>T_{1(Emt1)}, and T₁₍ₕₒₛₜ₂₎>T_{1(Emt2)}.

According to an embodiment of the present disclosure, T₁₍ₕₒₛₜ₂₎>T_{1(Emt1)}>T_{1(Emt2)}.

According to an embodiment of the present disclosure, T₁₍ₕₒₛₜ₁₎>T₁₍ₕₒₛₜ₂₎>T_{1(Emt1)}>T_{1(Emt2)}.

According to an embodiment of the present disclosure, the fluorescent emissive material is used as a main light-emitting source in the organic electroluminescent device.

According to an embodiment of the present disclosure, the fluorescent emissive material is a terminal emissive material of the organic electroluminescent device.

According to an embodiment of the present disclosure, the fluorescent emissive material comprises a single material or a plurality of different materials.

According to an embodiment of the present disclosure, the organic electroluminescent device emits fluorescence.

According to an embodiment of the present disclosure, the organic electroluminescent device emits delayed fluorescence.

According to an embodiment of the present disclosure, the emissive layer comprises a host material.

According to an embodiment of the present disclosure, the host material is a single host material.

According to an embodiment of the present disclosure, the host material comprises a first host material and/or a second host material.

According to another embodiment of the present disclosure, the first host material has a structure represented by Formula X-1 or Formula X-2:

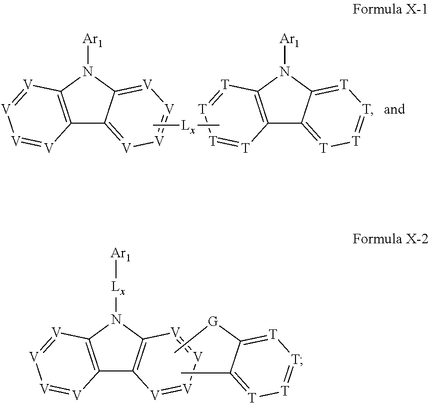

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from C, CRᵥ or N;
in Formula X-1, T is, at each occurrence identically or differently, selected from C, CRT or N;
in Formula X-2, T is, at each occurrence identically or differently, selected from CR_{T} or N;
R_{g}, Rᵥ and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,
Ar₁ is, at each occurrence identically or differently, selected from substituted or unsubstituted aryl having 6 to 30 carbon atoms, substituted or unsubstituted heteroaryl having 3 to 30 carbon atoms or a combination thereof; and
adjacent substituents R_{g}, Rᵥ and R_{T} can be optionally joined to form a ring.

In this embodiment, the expression that “adjacent substituents R_{g}, Rᵥ and R_{T} can be optionally joined to form a ring” is intended to mean that any one or more of groups of adjacent substituents, such as two substituents Rᵥ, two substituents R_{T}, two substituents R_{g}, substituents Rᵥ and R_{T}, substituents Rᵥ and R_{g}, and substituents R_{g} and R_{T}, can be joined to form a ring. Obviously, it is also possible that none of these substituents are joined to form a ring.

According to an embodiment of the present disclosure, the first host compound has a structure represented by one of Formula X-a to Formula X-p:

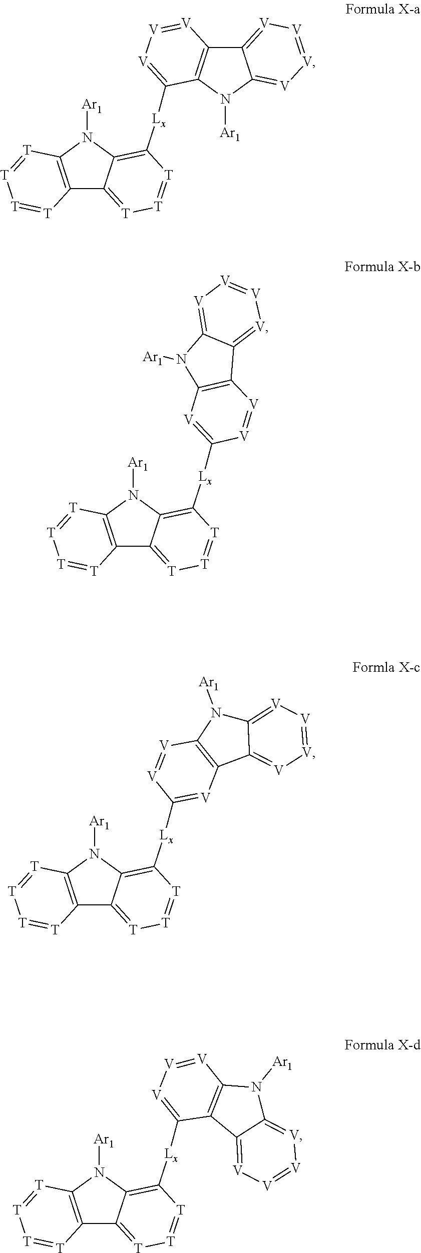

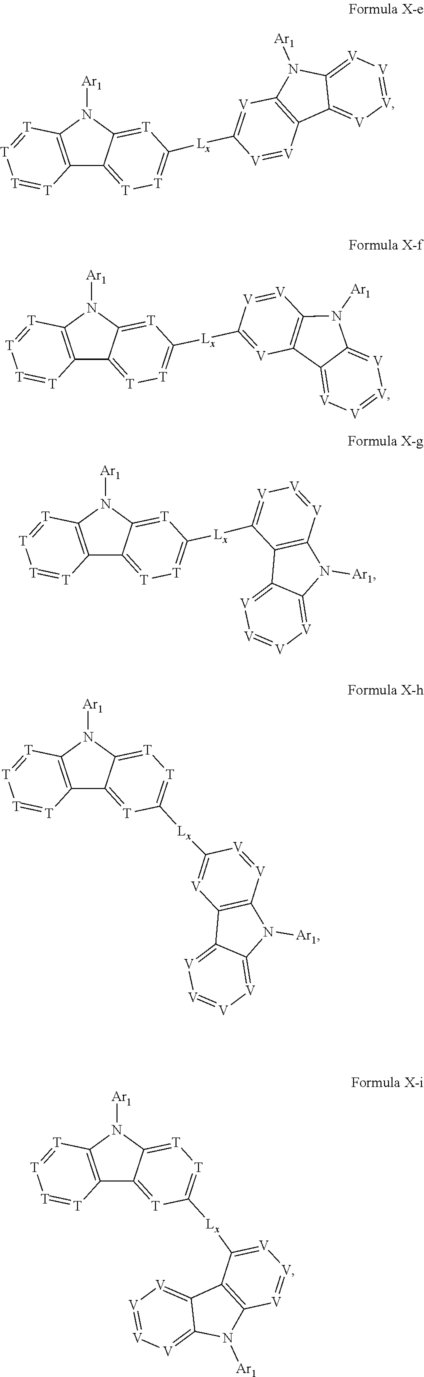

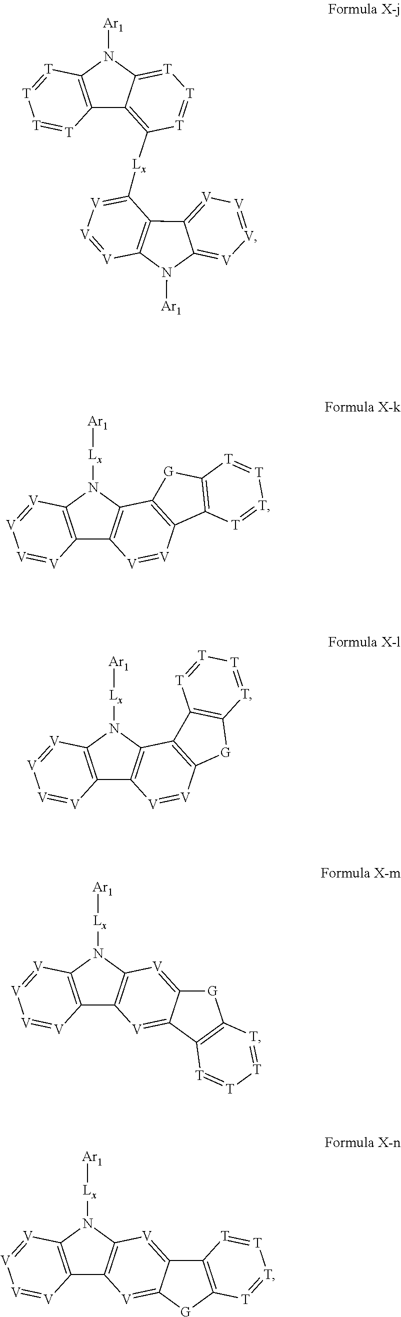

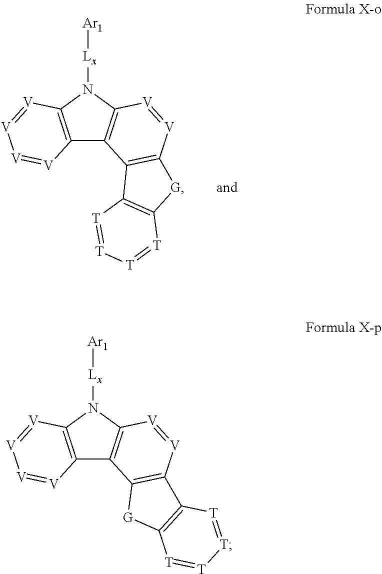

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from CRᵥ or N;
T is, at each occurrence identically or differently, selected from CR_{T} or N;
R_{g}, Rᵥ and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof; and
adjacent substituents R_{g}, Rᵥ and R_{T} can be optionally joined to form a ring.

According to an embodiment of the present disclosure, the first host compound is selected from the group consisting of the following compounds:

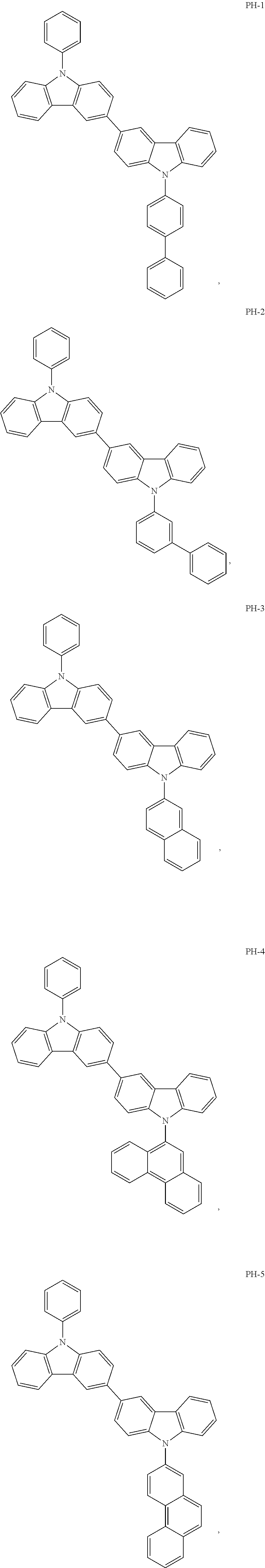 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1]

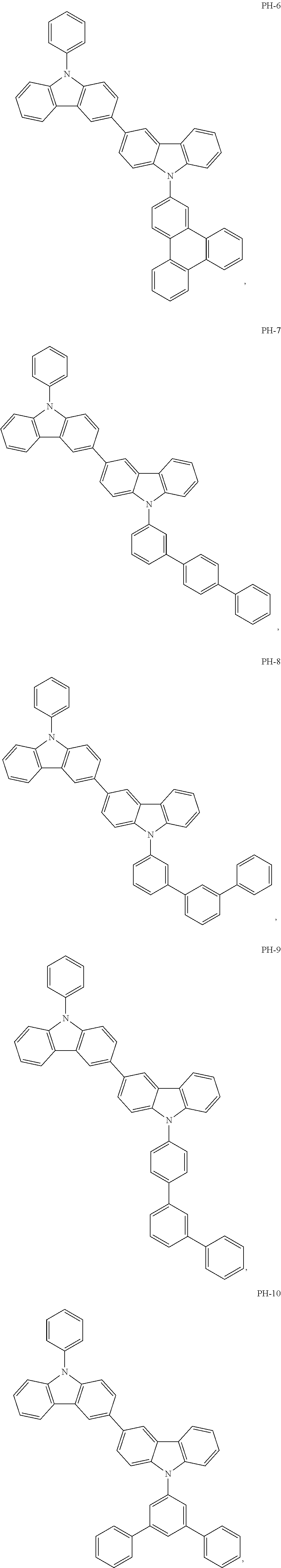 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1 ; c1ccc(-c2cc(-c3ccccc3)cc(-n3c4ccccc4c4cc(-c5ccc6c(c5)c5ccccc5n6-c5ccccc5)ccc43)c2)cc1]

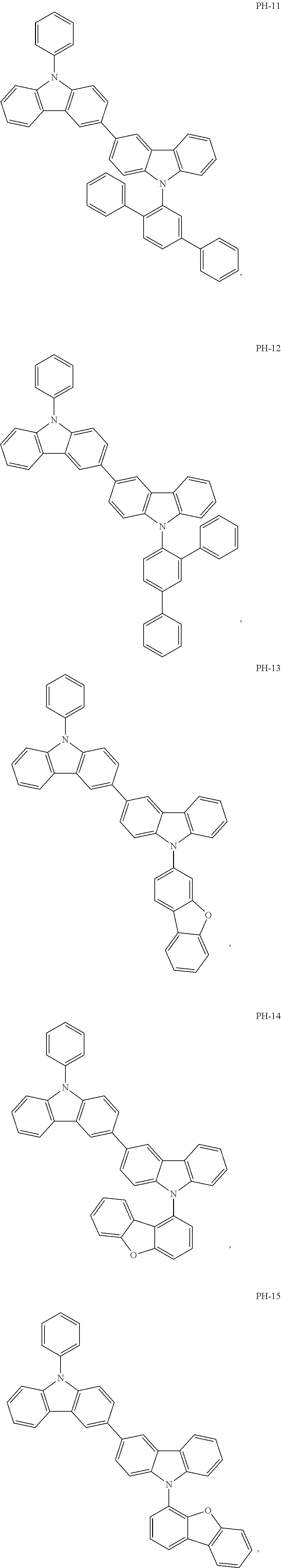 [SMILES: c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1 ; c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1]

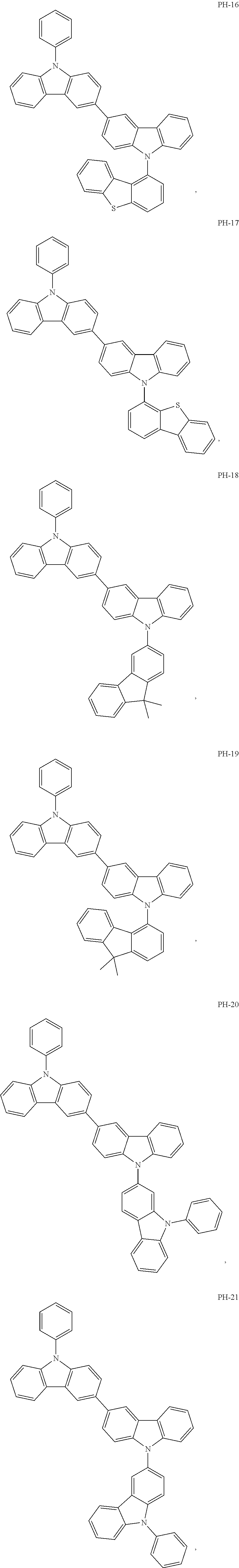 [SMILES: c1ccc(-n2c3ccccc3c3cc(-c4ccc5c(c4)c4ccccc4n5-c4cccc5sc6ccccc6c45)ccc32)cc1 ; c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21 ; CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

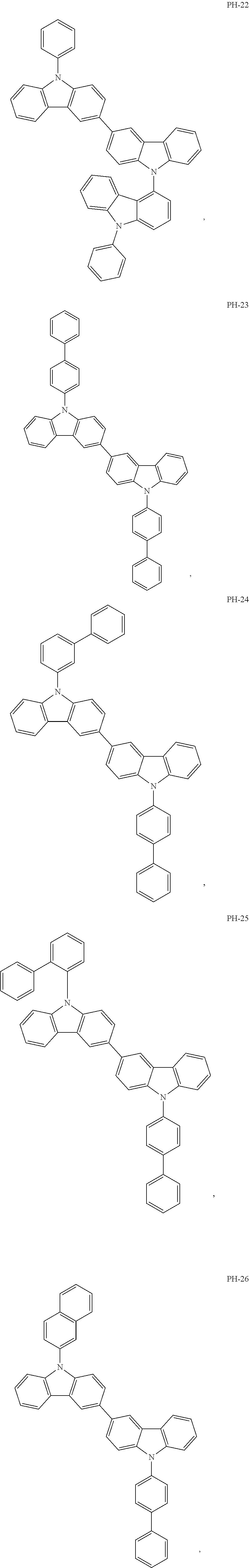 [SMILES: c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1]

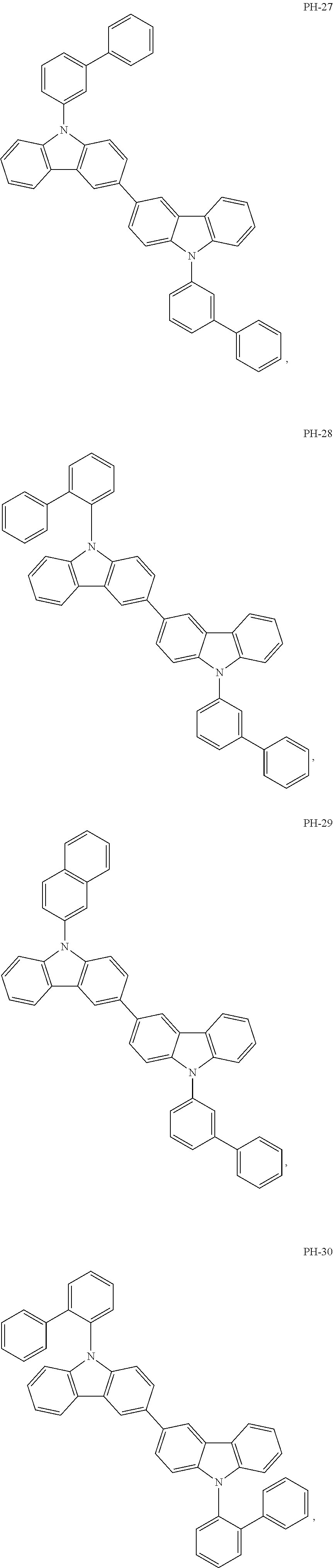 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccccc4-c4ccccc4)ccc32)cc1]

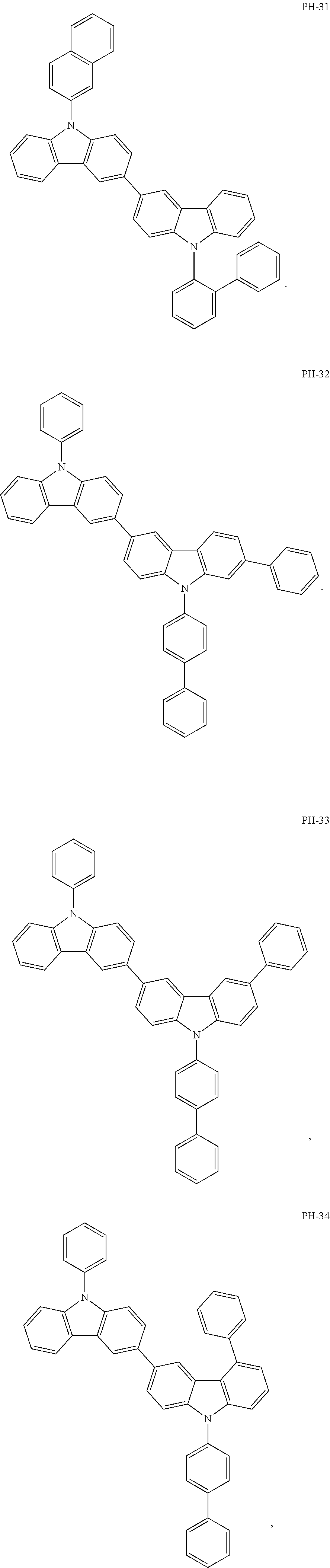 [SMILES: c1ccc(-c2ccccc2-n2c3ccccc3c3cc(-c4ccc5c(c4)c4ccccc4n5-c4ccc5ccccc5c4)ccc32)cc1 ; c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1]

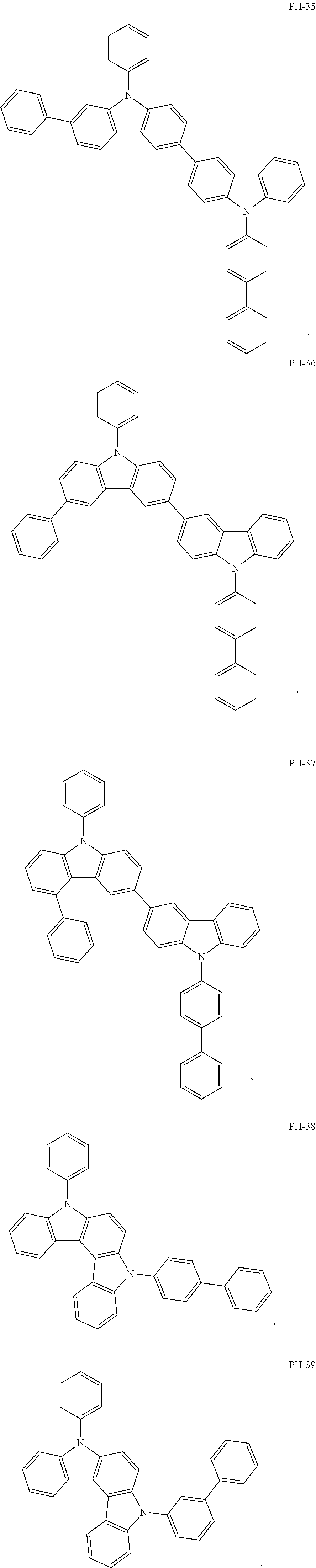 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1]

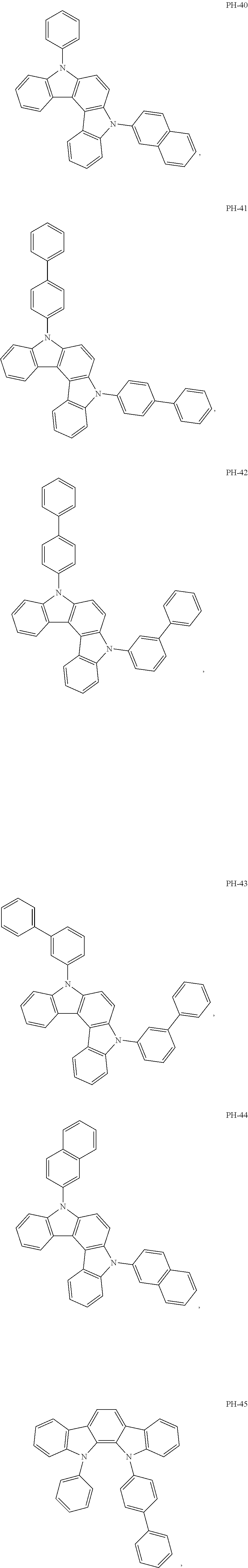 [SMILES: c1ccc(-n2c3ccccc3c3c4c5ccccc5n(-c5ccc6ccccc6c5)c4ccc32)cc1 ; c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6cccc(-c7ccccc7)c6)c5ccc43)cc2)cc1 ; c1ccc(-c2cccc(-n3c4ccccc4c4c5c6ccccc6n(-c6cccc(-c7ccccc7)c6)c5ccc43)c2)cc1 ; c1ccc2cc(-n3c4ccccc4c4c5c6ccccc6n(-c6ccc7ccccc7c6)c5ccc43)ccc2c1 ; c1ccc(-c2ccc(-n3c4ccccc4c4ccc5c6ccccc6n(-c6ccccc6)c5c43)cc2)cc1]

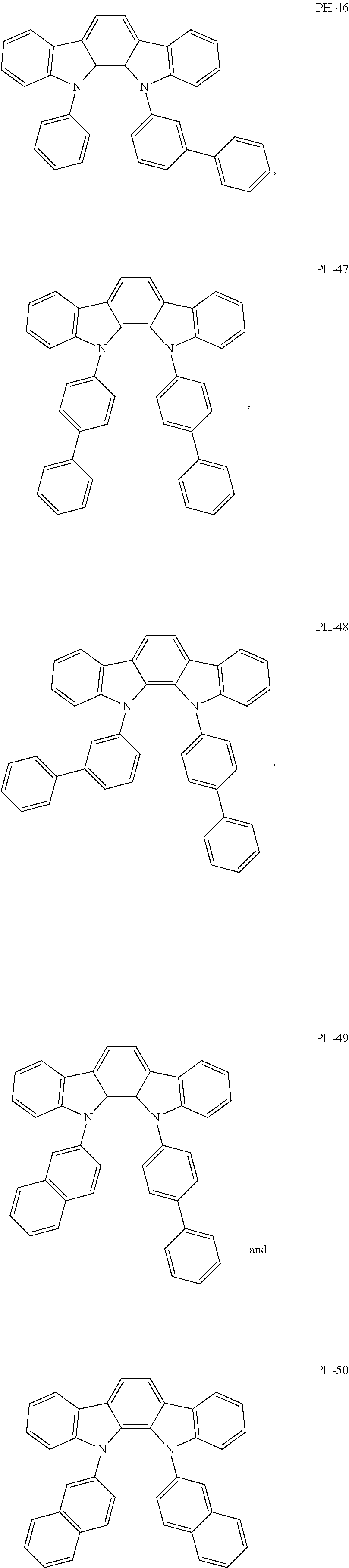 [SMILES: c1ccc(-c2cccc(-n3c4ccccc4c4ccc5c6ccccc6n(-c6ccccc6)c5c43)c2)cc1 ; c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4ccccc4c4ccc5c6ccccc6n(-c6cccc(-c7ccccc7)c6)c5c43)cc2)cc1 ; c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1]

According to an embodiment of the present disclosure, the second host material has a structure represented by Formula Y:

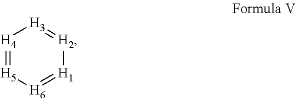

wherein,
H₁ to H₆ are, at each occurrence identically or differently, selected from C, CRₕ or N, at least two of H₁ to H₆ are N, and at least one of H₁ to H₆ is C and joined to Formula A;

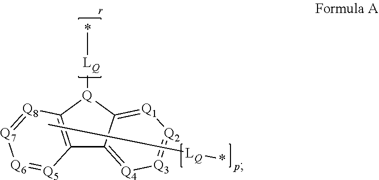

wherein,
Q is, at each occurrence identically or differently, selected from the group consisting of O, S, Se, N, NR_{Q}, CR_{Q}R_{Q}, SiR_{Q}R_{Q}, GeR_{Q}R_{Q} and R_{Q}C═CR_{Q}; when two R_{Q} are present at the same time, the two R_{Q} may be the same or different;
p is 0 or 1; r is 0 or 1;
when Q is selected from N, p is 0, and r is 1;
when Q is selected from the group consisting of O, S. Se. NR_{Q}, CR_{Q}R_{Q}, SiR_{Q}R_{Q}, GeR_{Q}R_{Q} and R_{Q}C═CR_{Q}, p is 1, and r is 0;
L_{Q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
Rₕ, R_{Q} and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“*” represents a position w % here Formula A is joined to Formula Y, and
adjacent substituents Rₕ, R_{Q} and R_{q} can be optionally joined to form a ring.

In the present disclosure, the expression that “adjacent substituents Rₕ, R_{Q} and R_{q} can be optionally joined to form a ring” is intended to mean that any one or more of groups of adjacent substituents, such as two substituents Rₕ, two substituents R_{Q}, two substituents R_{q}, and two substituents R_{Q} and R_{q}, can be joined to form a ring. Obviously, it is also possible that none of these substituents are joined to form a ring.

According to an embodiment of the present disclosure, the second host compound is selected from the group consisting of the following compounds:

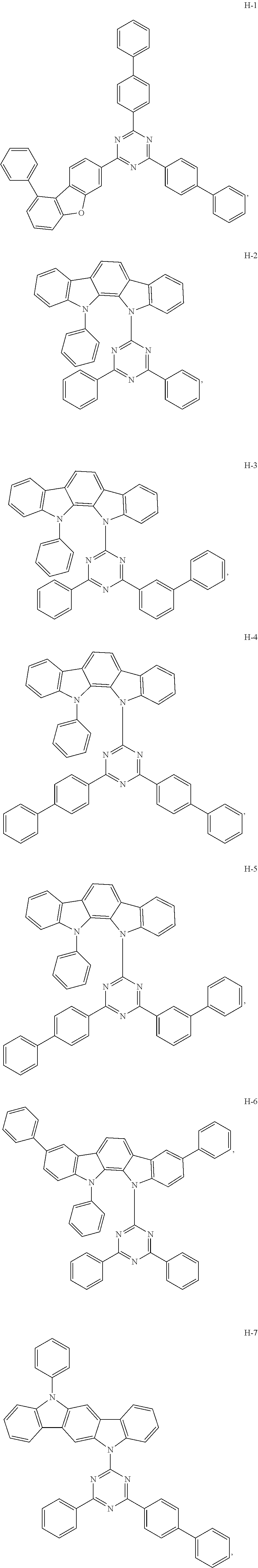

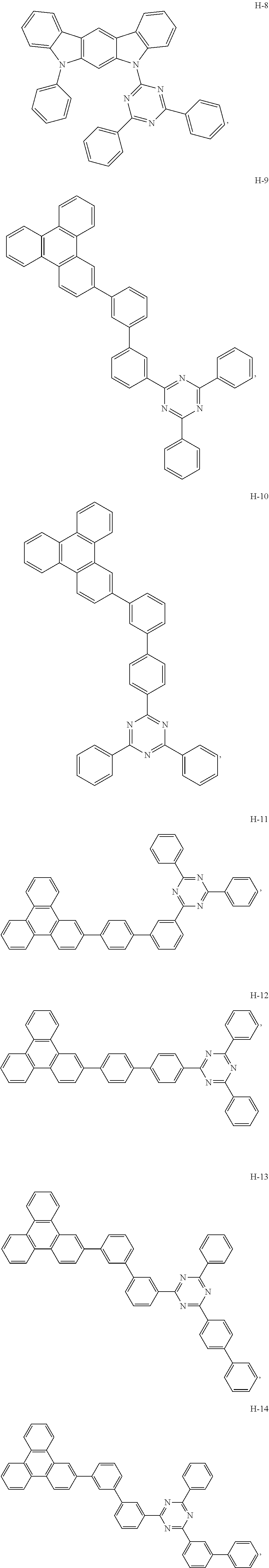

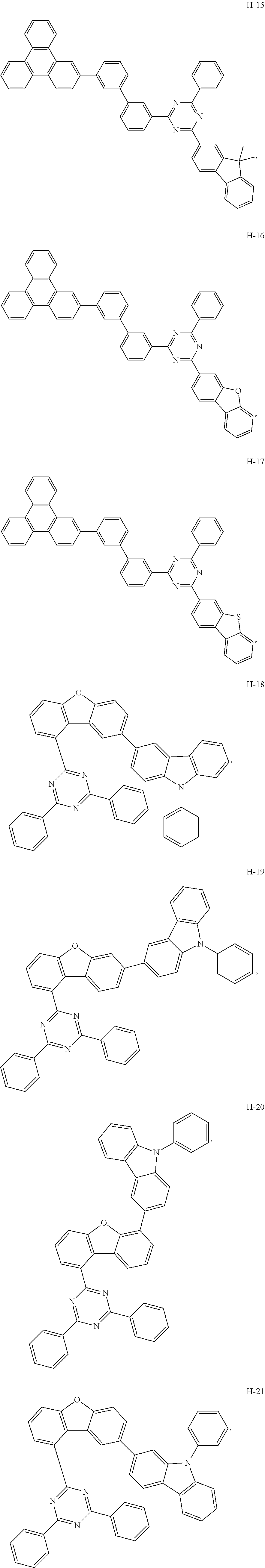

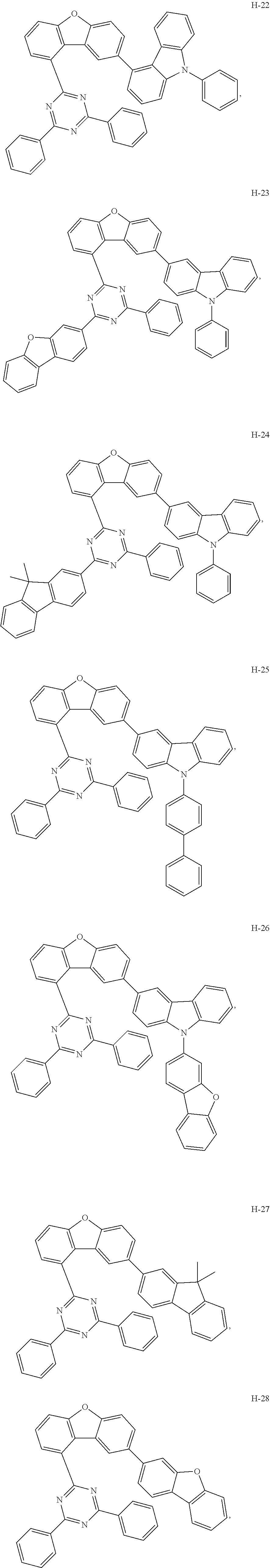

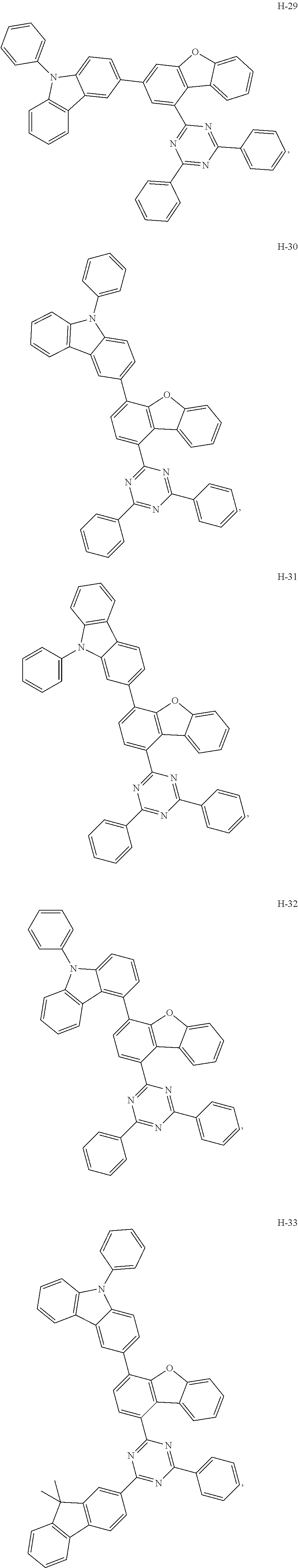

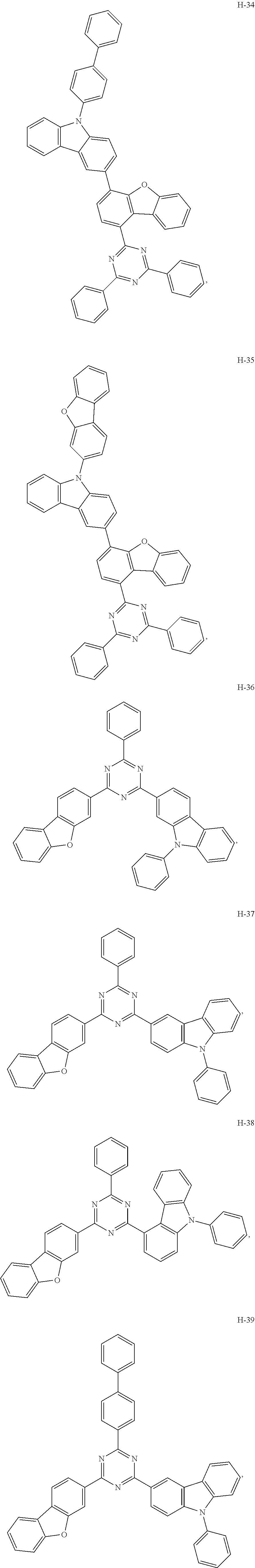

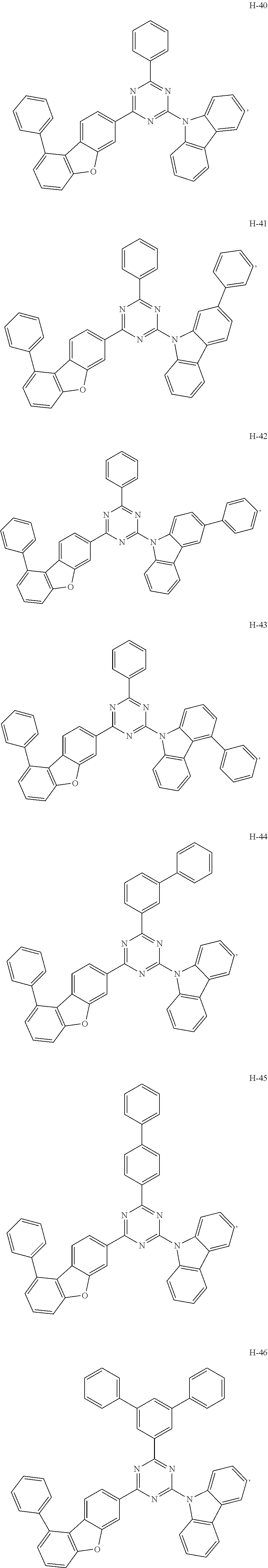

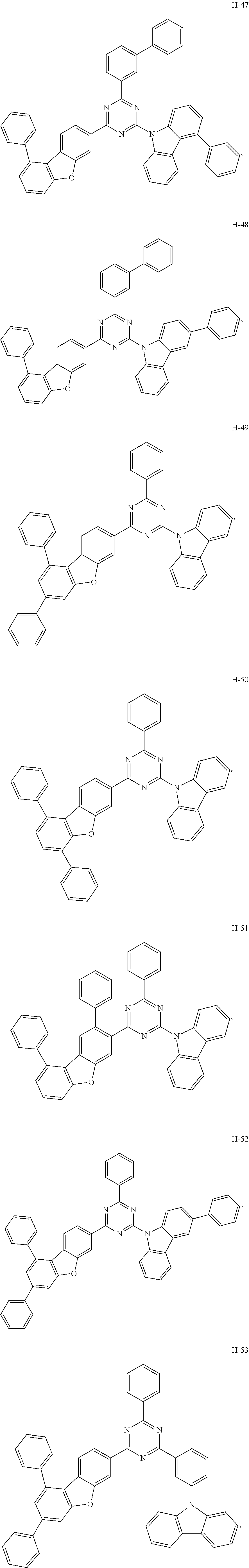

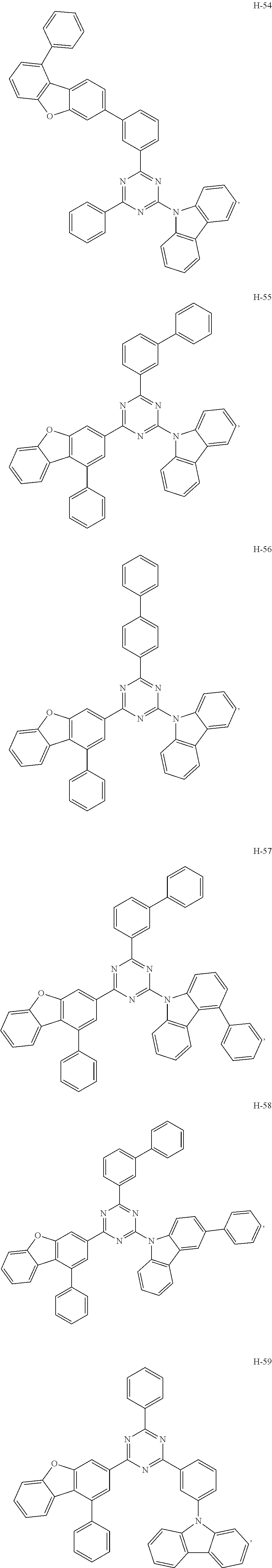

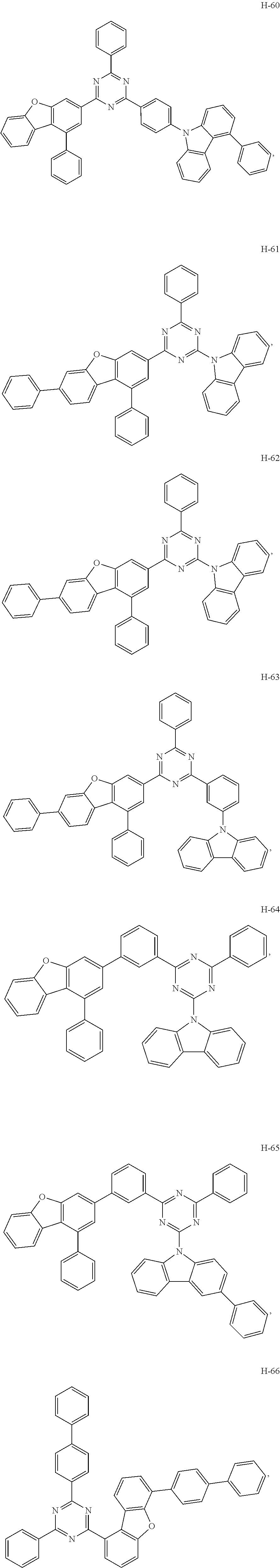

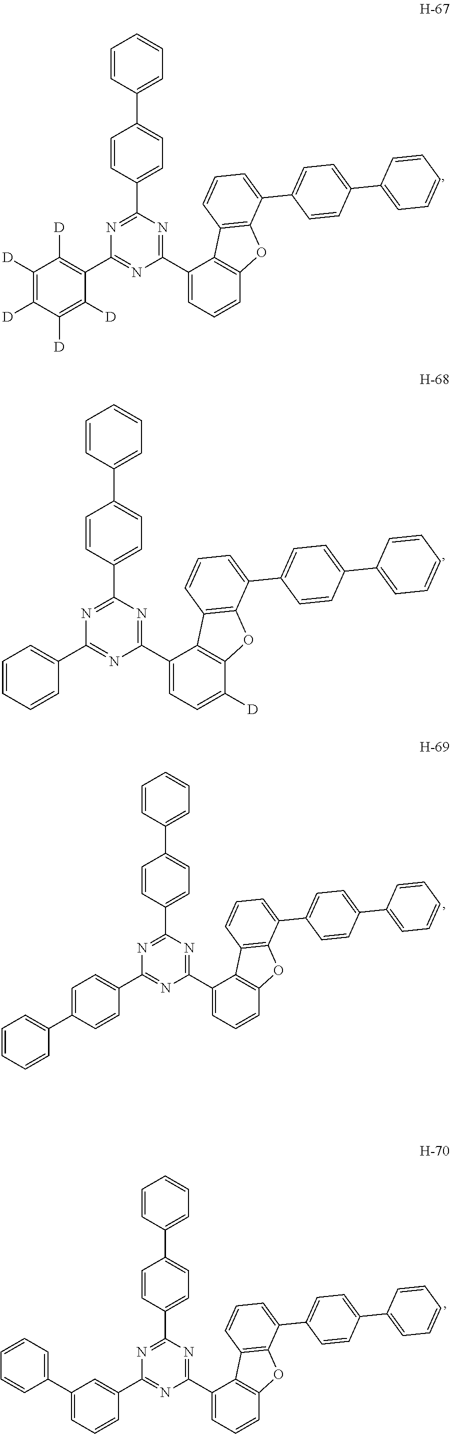 [SMILES: [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H] ; [2H]c1ccc(-c2nc(-c3ccccc3)nc(-c3ccc(-c4ccccc4)cc3)n2)c2c1oc1c(-c3ccc(-c4ccccc4)cc3)cccc12 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1]

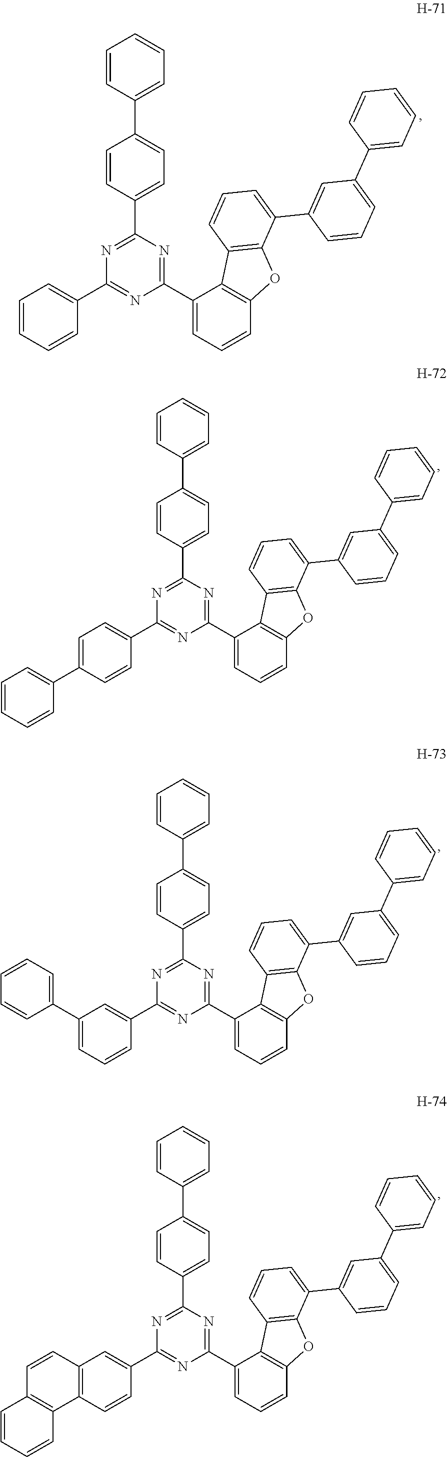 [SMILES: c1ccc(-c2ccc(-c3nc(-c4ccccc4)nc(-c4cccc5oc6c(-c7cccc(-c8ccccc8)c7)cccc6c45)n3)cc2)cc1 ; c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1]

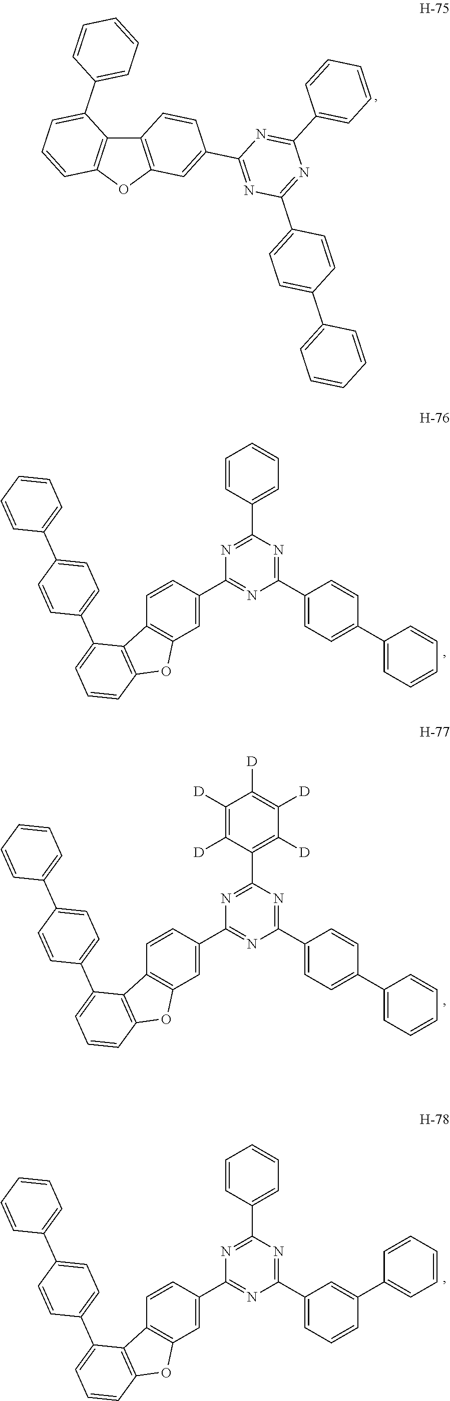 [SMILES: c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1]

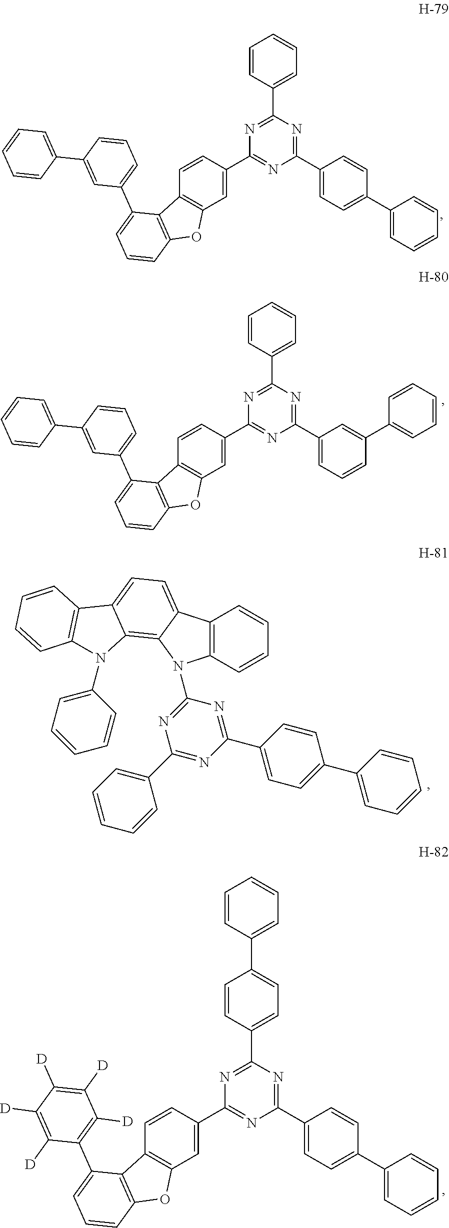 [SMILES: c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H]]

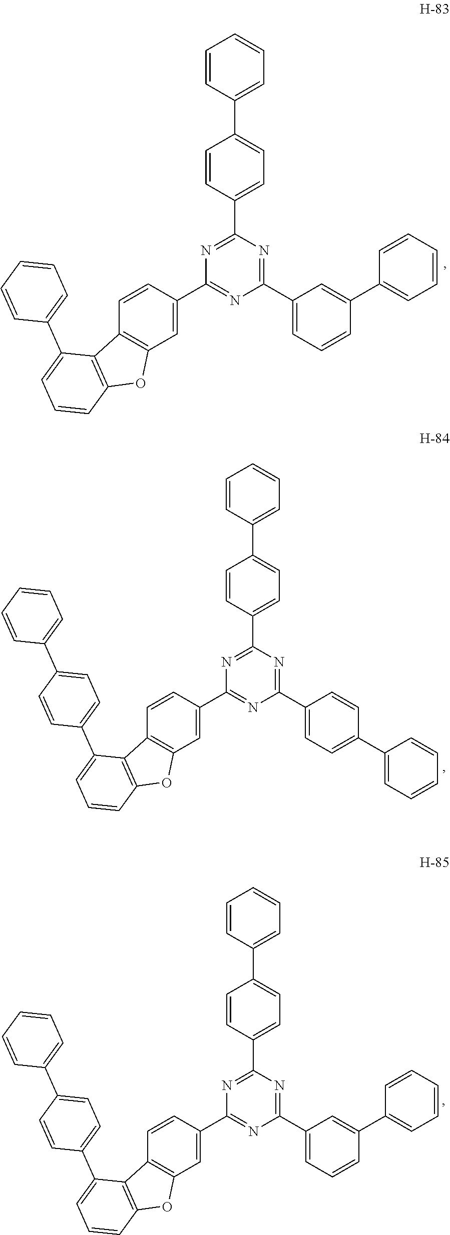 [SMILES: c1ccc(-c2ccc(-c3nc(-c4cccc(-c5ccccc5)c4)nc(-c4ccc5c(c4)oc4cccc(-c6ccccc6)c45)n3)cc2)cc1 ; c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1 ; c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1]

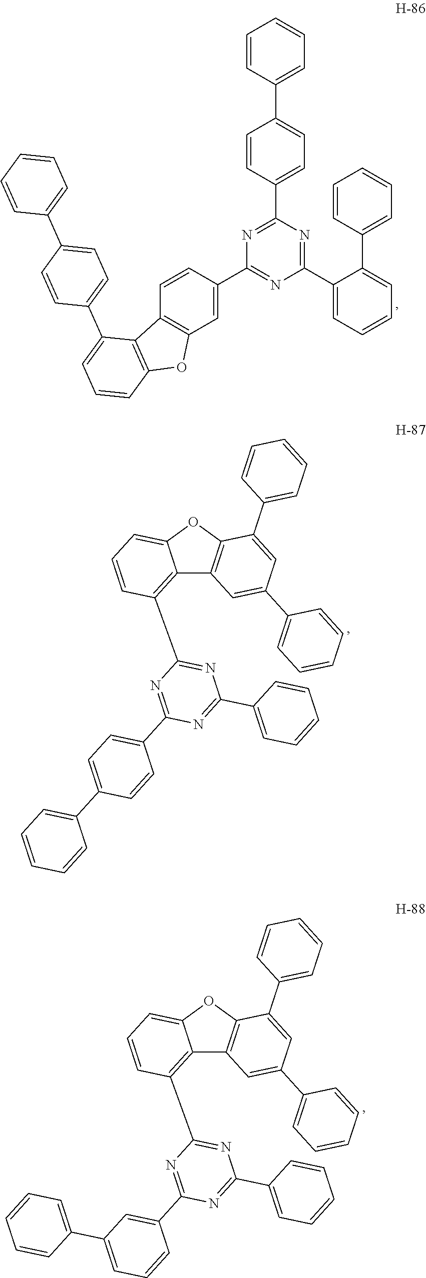 [SMILES: c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1]

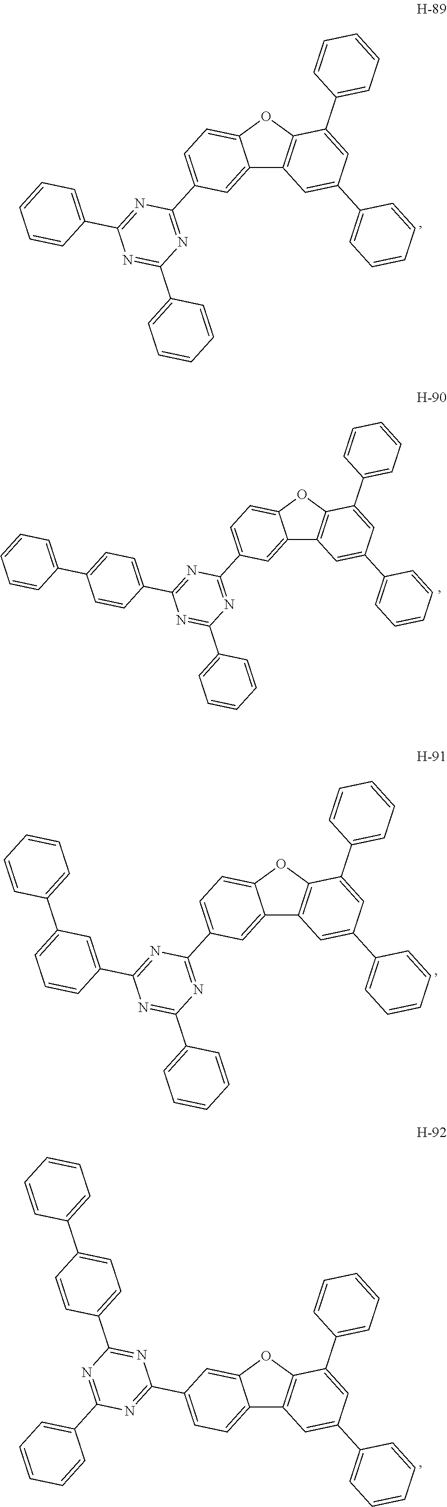 [SMILES: c1ccc(-c2cc(-c3ccccc3)c3oc4ccc(-c5nc(-c6ccccc6)nc(-c6ccccc6)n5)cc4c3c2)cc1 ; c1ccc(-c2ccc(-c3nc(-c4ccccc4)nc(-c4ccc5oc6c(-c7ccccc7)cc(-c7ccccc7)cc6c5c4)n3)cc2)cc1 ; c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1]

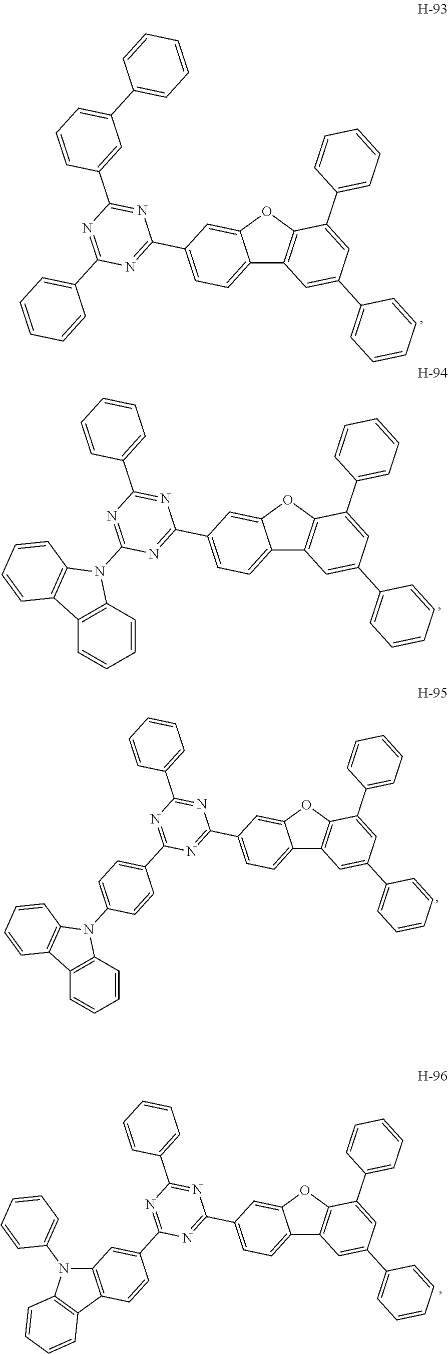 [SMILES: c1ccc(-c2cccc(-c3nc(-c4ccccc4)nc(-c4ccc5c(c4)oc4c(-c6ccccc6)cc(-c6ccccc6)cc45)n3)c2)cc1 ; c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1 ; c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1]

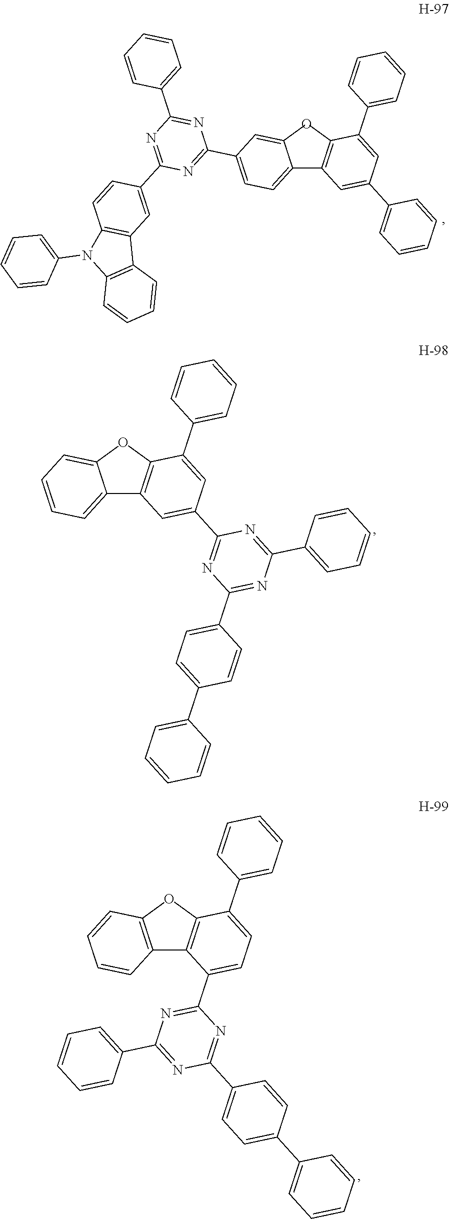 [SMILES: c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1]

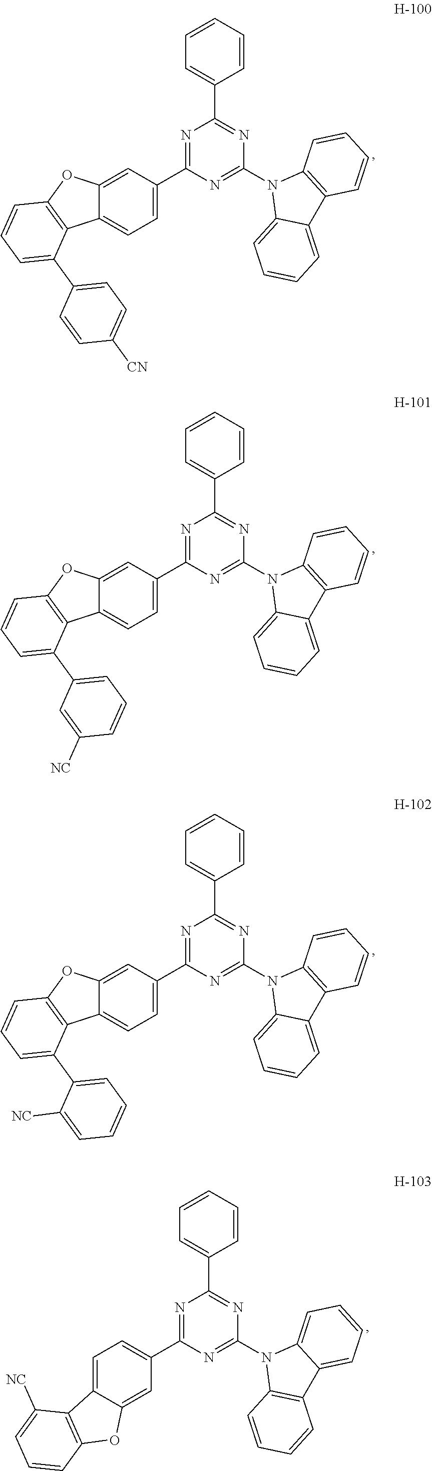 [SMILES: N#Cc1ccc(-c2cccc3oc4cc(-c5nc(-c6ccccc6)nc(-n6c7ccccc7c7ccccc76)n5)ccc4c23)cc1 ; N#Cc1cccc(-c2cccc3oc4cc(-c5nc(-c6ccccc6)nc(-n6c7ccccc7c7ccccc76)n5)ccc4c23)c1 ; N#Cc1ccccc1-c1cccc2oc3cc(-c4nc(-c5ccccc5)nc(-n5c6ccccc6c6ccccc65)n4)ccc3c12 ; N#Cc1cccc2oc3cc(-c4nc(-c5ccccc5)nc(-n5c6ccccc6c6ccccc65)n4)ccc3c12]

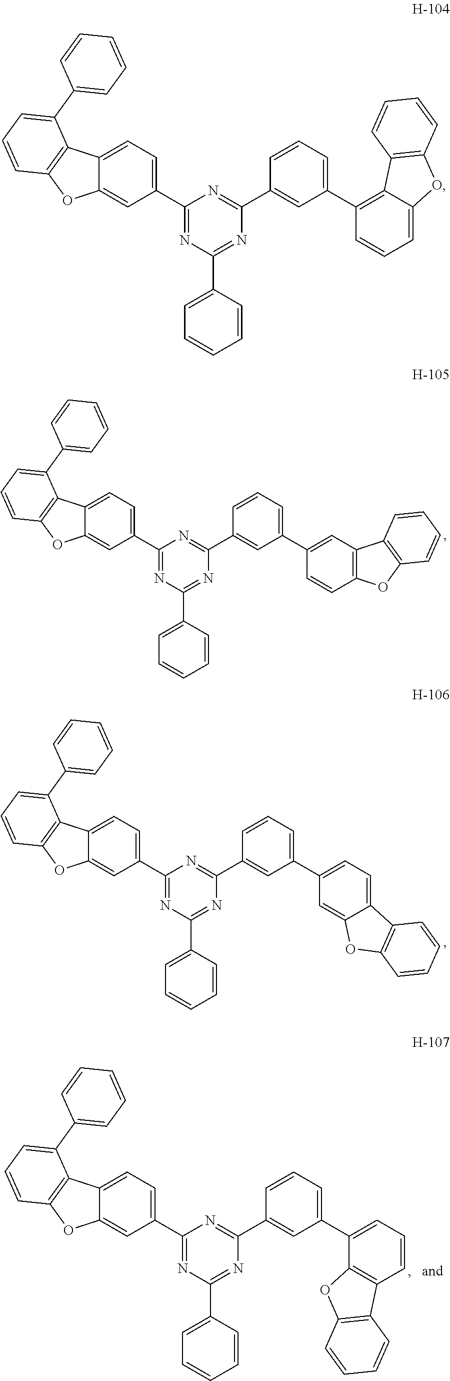 [SMILES: c1ccc(-c2nc(-c3cccc(-c4cccc5oc6ccccc6c45)c3)nc(-c3ccc4c(c3)oc3cccc(-c5ccccc5)c34)n2)cc1 ; c1ccc(-c2nc(-c3cccc(-c4ccc5oc6ccccc6c5c4)c3)nc(-c3ccc4c(c3)oc3cccc(-c5ccccc5)c34)n2)cc1 ; c1ccc(-c2nc(-c3cccc(-c4ccc5c(c4)oc4ccccc45)c3)nc(-c3ccc4c(c3)oc3cccc(-c5ccccc5)c34)n2)cc1 ; c1ccc(-c2nc(-c3cccc(-c4cccc5c4oc4ccccc45)c3)nc(-c3ccc4c(c3)oc3cccc(-c5ccccc5)c34)n2)cc1]

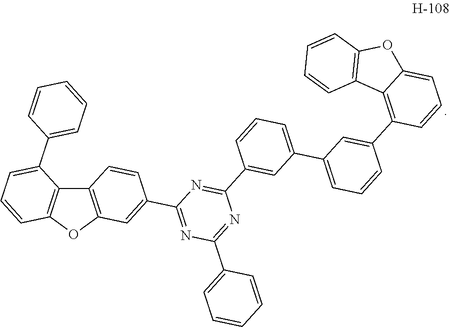 [SMILES: c1ccc(-c2nc(-c3cccc(-c4cccc(-c5cccc6oc7ccccc7c56)c4)c3)nc(-c3ccc4c(c3)oc3cccc(-c5ccccc5)c34)n2)cc1]

According to another embodiment of the present disclosure, further disclosed is a display device comprising the organic electroluminescent device described in any one of the preceding embodiments.

According to another embodiment of the present disclosure, further disclosed is an application of the organic electroluminescent device described in any one of the preceding embodiments in a display device.

Combination with Other Materials

The materials described in the present disclosure for a particular layer in an organic light emitting device can be used in combination with various other materials present in the device. The combinations of these materials are described in more detail in U.S. Pat. Pub. No. 20160359122 at paragraphs 0132-0161, which is incorporated by reference herein in its entirety. The materials described or referred to in the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, the compounds disclosed herein may be used in combination with a wide variety of emissive dopants, hosts, transport layers, blocking layers, injection layers, electrodes and other layers that may be present. The combination of these materials is described in detail in paragraphs 0080-0101 of U.S. Pat. Pub. No. 20150349273, which is incorporated by reference herein in its entirety. The materials described or referred to in the disclosure are non-limiting examples of materials that may be useful in combination with the compounds disclosed herein, and one of skill in the art can readily consult the literature to identify other materials that may be useful in combination.

With reference to preparation methods in the related art, the metal complex and the fluorescent emissive material that are used in the present disclosure can be easily obtained. For example, the metal complex can be prepared with reference to documents such as US20230309378A1 and CN116903666A, and the fluorescent emissive material can be prepared with reference to documents such as Angew. Chem. Int. Ed. 2023, 62, e202304104 (DOI: 10.1002/anie.202304104). Methods for preparing the metal complex and the fluorescent emissive material are not repeated here. The documents listed above are merely exemplary, and other documents can be easily obtained by those skilled in the art.

The method for preparing an electroluminescent device is not limited herein. The preparation methods in the following examples are merely examples and are not to be construed as limiting. Based on the related art, those skilled in the art can make reasonable improvements on the preparation methods in the following examples. For example, the proportions of various materials in an emissive layer are not particularly limited. Those skilled in the art can reasonably select the proportions within a certain range based on the related art. For example, taking the total weight of the materials in the emissive layer as a reference, a host material may account for 75% to 98%, a metal complex may account for 1% to 20%, and a fluorescent emissive material may account for 0.01% to 5%; or the host material may account for 88% to 98%, the metal complex may account for 0.05% to 3%, and the fluorescent emissive material may account for 0.1% to 1%. Further, the host material may be two materials, wherein the ratio of the two host materials in the host material may be 99:1 to 1:99, or, the ratio may be 80:20 to 20:80; or the ratio may be 70:30 to 30:70. In the examples of the device, the characteristics of the device were also tested using conventional equipment in the art (including, but not limited to, evaporation deposition system produced by ANGSTROM ENGINEERING, optical testing system produced by SUZHOU FSTAR, life testing system produced by SUZHOU FSTAR, ellipsometer produced by BEIJING ELLITOP, etc.) by methods well known to those skilled in the art.

In the present disclosure, a method for measuring a maximum emission wavelength λₘₐₓ in a photoluminescence spectrum of a compound includes the steps described below.

The photoluminescence (PL) spectrum data of a compound to be tested were measured using a fluorescence spectrophotometer F98 produced by SHANGHAI LENGGUANG TECHNOLOGY CO., LTD. The compound to be tested was dissolved in a toluene solvent to prepare a solution with a concentration of 1×10⁻⁶ mol/L, nitrogen was introduced into the prepared solution to be tested to remove oxygen for 5 min, the solution to be tested was placed in a quartz sample tube and was excited by light with a wavelength of 400 nm at room temperature (298 K), and an emission spectrum of the solution to be tested was measured. The emission spectrum has a maximum emission wavelength λₘₐₓ.

As an example, maximum emission wavelengths λₘₐₓ in photoluminescence spectra of the following metal complex and fluorescent emissive materials were measured through the above method. The specific results are shown in Table 1:

TABLE 1
Maximum emission wavelengths in photoluminescence
spectra of compounds

| | | Fluorescent | |
|---|---|---|---|
| Phosphorescent | λₘₐₓ₁ | Emissive | λₘₐₓ₂ |
| Emissive Material | (nm) | Material | (nm) |
| Metal Comp1ex | 525 nm | DF-70 | 545 |
| 575 | | DF-81 | 536 |

### DEVICE EXAMPLE

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2 to 2 Angstroms per second and a vacuum degree of about 10⁻⁸ Torr. Compound HT and Compound HT1 were co-deposited for use as a hole injection layer (HIL, with a weight ratio of 97:3). Compound HT was used as a hole transport layer (HTL). Compound PH-23 was used as an electron blocking layer (EBL). Then, Compound PH-1 as a first host material, Compound H-40 as a second host material, Metal Complex 575 as a phosphorescence sensitizer and DF-70 as a fluorescent emissive material were co-deposited for use as an emissive layer (EML, with a weight ratio of 65:28:6:1). On the EML, Compound HB was used as a hole blocking layer (HBL). On the HBL, Compound ET and 8-hydroxyquinolinolato-lithium (Liq) were co-deposited for use as an electron transport layer (ETL, with a weight ratio of 40:60). Finally, 8-hydroxyquinolinolato-lithium (Liq) was deposited for use as an electron injection layer with a thickness of 1 nm and Al was deposited for use as a cathode with a thickness of 120 nm. The device was transferred back to the glovebox and encapsulated with a glass lid and a moisture getter to complete the device.

### Device Comparative Example 1

The implementation mode in Device Comparative Example 1 was the same as that in Device Example 1, except that Compound PH-1 as the first host material, Compound H-40 as the second host material and DF-70 as the fluorescent emissive material were co-deposited for use as the emissive layer (EML) with a weight ratio of 69:30:1.

### Device Comparative Example 2

The implementation mode in Device Comparative Example 2 was the same as that in Device Example 1, except that Compound PH-1 as the first host material, Compound H-40 as the second host material and Metal Complex 575 were co-deposited for use as the emissive layer (EML) with a weight ratio of 66:28:6.

Detailed structures and thicknesses of layers of the devices are shown in the following table. A layer using more than one material is obtained by doping different compounds at their weight ratio as recorded.

TABLE 2
Part of device structures in Example 1 and Comparative Examples 1 and 2

| Device ID | HIL | HTL | EBL | EML | HBL | ETL |
|---|---|---|---|---|---|---|
| Example 1 | Compound | Compound | Compound | Compound PH- | Compound | Compound |
| | HT:Compound | HT | PH-23 | 1: Compound H- | HB | ET:Liq |
| | HT1 (97:3) | (350 Å) | (50 Å) | 40:Metal Complex | (50 Å) | (40:60) |
| | (100 Å) | | | 575:Compound DF- | | (350 Å) |
| | | | | 70 (65:28:6:1) | | |
| | | | | (400 Å) | | |
| Comparative | Compound | Compound | Compound | Compound PH- | Compound | Compound |
| Example 1 | HT:Compound | HT | PH-23 | 1:Compound | HB | ET:Liq |
| | HT1 (97:3) | (350 Å) | (50 Å) | H-40:Compound | (50 Å) | (40:60) |
| | (100 Å) | | | DF-70 (69:30:1) | | (350 Å) |
| | | | | (400 Å) | | |
| Comparative | Compound | Compound | Compound | Compound PH- | Compound | Compound |
| Example 2 | HT:Compound | HT | PH-23 | 1:Compound | HB | ET:Liq |
| | HT1 (97:3) | (350 Å) | (50 Å) | H-40:Metal | (50 Å) | (40:60) |
| | (100 Å) | | | Complex 575 | | (350 Å) |
| | | | | (66:28:6) | | |
| | | | | (400 Å) | | |

The materials used in the devices have the following structures:

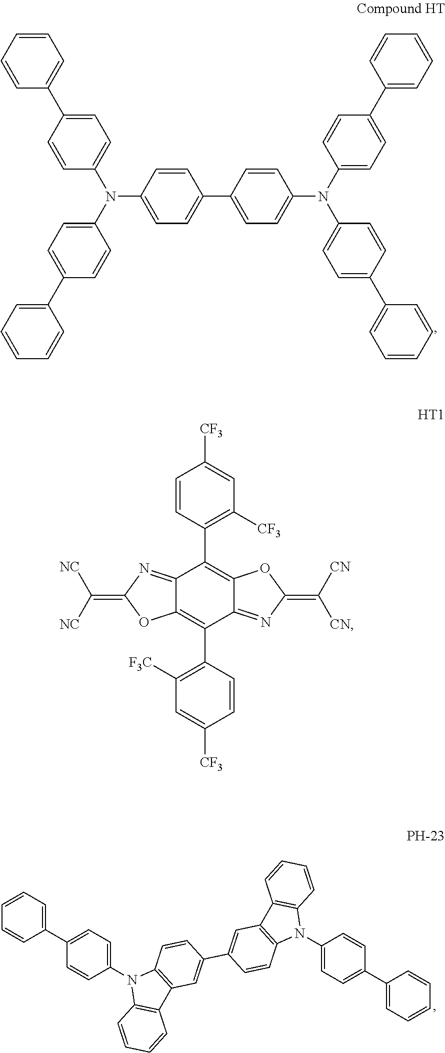 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(-n3c4ccccc4c4cc(-c5ccc6c(c5)c5ccccc5n6-c5ccc(-c6ccccc6)cc5)ccc43)cc2)cc1]

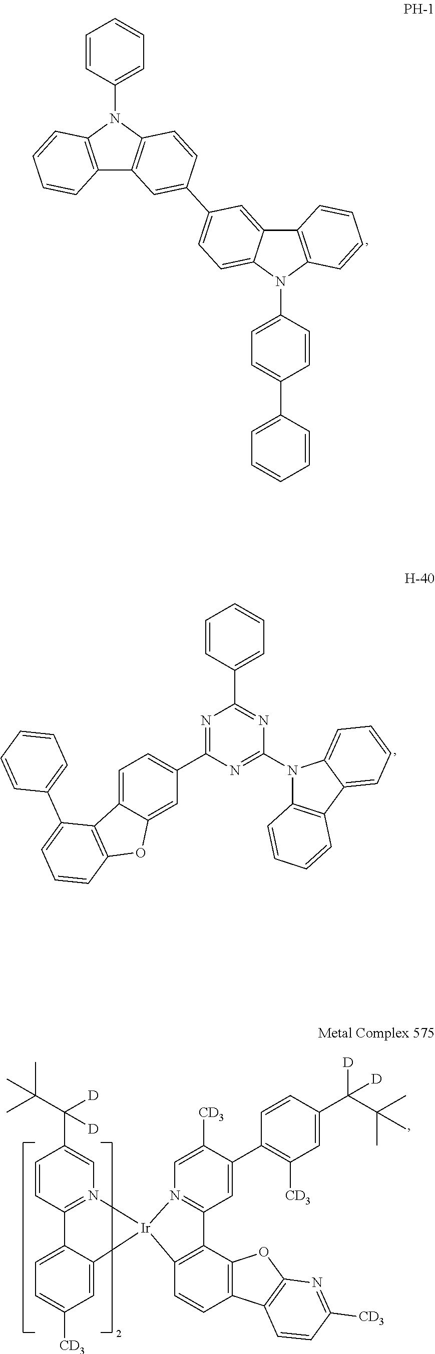

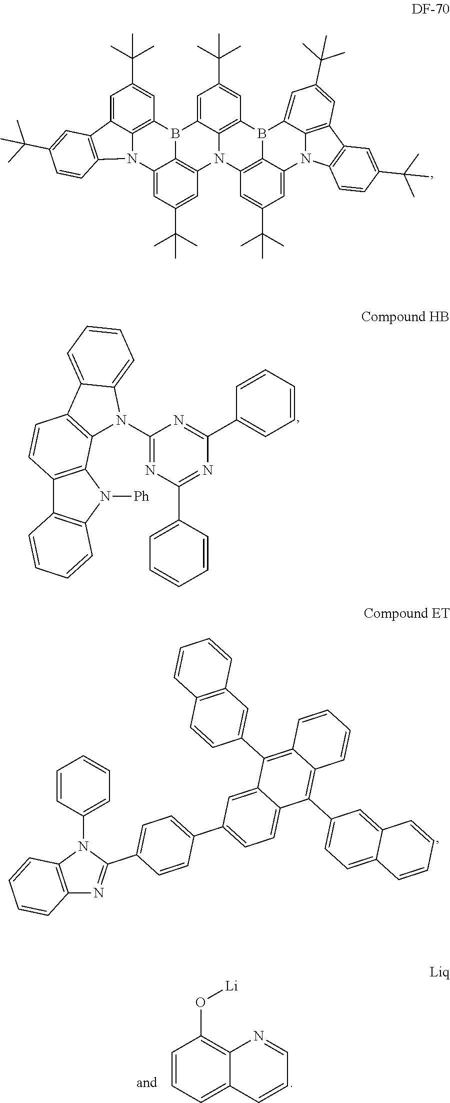

The CIE data, maximum emission wavelengths (λₘₐₓ), full widths at half maximum (FWHM), drive voltages (V), current efficiency (CE), power efficiency (PE) and external quantum efficiency (EQE) of the devices were measured at a constant current of 15 mA/cm², and the lifetimes LT97 of the devices were measured at initial brightness of 10000 cd/cm². These data are recorded and shown in Table 3.

TABLE 3
Device data in Example 1 and Comparative Examples 1 and 2

| | | λₘₐₓ | FWHM | Voltage | CE | PE | EQE | LT97 |
|---|---|---|---|---|---|---|---|---|
| Device ID | CIE (x, y) | (nm) | (nm) | (V) | (cd/A) | (lm/W) | (%) | (h) |
| Example 1 | (0.353, 0.636) | 548 | 34.4 | 4.10 | 119.7 | 91.8 | 27.4 | 1567 |
| Comparative | (0.349, 0.634) | 548 | 33.1 | 3.70 | 54.9 | 46.7 | 12.5 | 19 |
| Example 1 | | | | | | | | |
| Comparative | (0.339, 0.631) | 525 | 57.7 | 4.25 | 96.8 | 71.5 | 25.2 | 931 |
| Example 2 | | | | | | | | |

Example 1 differs from Comparative Example 1 only in that the metal complex comprising a ligand Lₐ which is represented by a structure of Formula 1 and has a particular substituent RA, on a particular ring is used in the emissive layer of Example 1 as a phosphorescence sensitizer for sensitizing the fluorescent emissive material, while no phosphorescence sensitizer is used in Comparative Example 1.

As can be seen from the data in Table 3, the maximum emission wavelength of Example 1 is consistent with that of Comparative Example 1, indicating that light emitted by the device of Example 1 comes from the fluorescent emissive material. However, compared with the common fluorescent light-emitting device of Comparative Example 1, Device Example 1 of the present disclosure can further achieve an unexpected significant improvement in device efficiency and lifetime on the basis of maintaining the narrow full width at half maximum and low voltage at basically equivalent levels of Comparative Example 1. Specifically, the CE, the PE and the EQE are significantly improved by 118.0%, 96.6% and 119.2%, respectively, and the lifetime is significantly improved by 81.5 times longer.

Example 1 differs from Comparative Example 2 only in that both the metal complex and the fluorescent emissive material of the present disclosure are used in Example 1 and the device emits fluorescence, while only the metal complex is used in Comparative Example 2 without a fluorescent emissive material and the device emits phosphorescence. Compared with the phosphorescent device of Comparative Example 2, the sensitized fluorescent device of Example 1 unexpectedly exhibits more excellent performance effects in various aspects: the sensitized fluorescent device of Example 1 has higher CE, PE and EQE and a narrower full width at half maximum, and in particular, the lifetime of the sensitized fluorescent device of Example 1 is 1.7 times the lifetime of the phosphorescent device of Comparative Example 2.

The above results indicate that compared with the common fluorescent light-emitting device without a phosphorescence sensitizer or the common phosphorescent device without a fluorescent emissive material, the sensitized fluorescent light-emitting device of the present disclosure can obtain more excellent device performance due to the fact that both the metal complex comprising the ligand Lₐ which is represented by the structure of Formula 1 and the fluorescent emissive material are comprised in the emissive layer.

### Device Example 2

The implementation mode in Device Comparative Example 2 was the same as that in Device Example 1, except that Compound PH-1 as the first host material, Compound H-40 as the second host material, Metal Complex 575 as the phosphorescence sensitizer and DF-81 as the fluorescent emissive material were co-deposited for use as the emissive layer (EML) with a weight ratio of 65:28:6:1.

### Device Comparative Example 3

The implementation mode in Device Comparative Example 3 was the same as that in Device Example 2, except that Compound PH-1 as the first host material, Compound H-40 as the second host material and DF-81 as the fluorescent emissive material were co-deposited for use as the emissive layer (EML) with a weight ratio of 69:30:1.

Detailed structures and thicknesses of layers of the devices are shown in the following table. A layer using more than one material is obtained by doping different compounds at their weight ratio as recorded.

TABLE 4
Device structures in Example 2 and Comparative Example 3

| Device ID | HIL | HTL | EBL | EML | HBL | ETL |
|---|---|---|---|---|---|---|
| Example 2 | Compound | Compound | Compound | Compound PH- | Compound | Compound |
| | HT:Compound | HT | PH-23 | 1:Compound H- | HB | ET:Liq |
| | HT1 (97:3) | (350 Å) | (50 Å) | 40:Metal Complex | (50 Å) | (40:60) |
| | (100 Å) | | | 575:Compound DF- | | (350 Å) |
| | | | | 81 (65:28:6:1) | | |
| | | | | (400 Å) | | |
| Comparative | Compound | Compound | Compound | Compound PH- | Compound | Compound |
| Example 3 | HT:Compound | HT | PH-23 | 1:Compound H- | HB | ET.Liq |
| | HT1 (97:3) | (350 Å) | (50 Å) | 40:Compound DF-81 | (50 Å) | (40:60) |
| | (100 Å) | | | (69:30:1) (400 Å) | | (350 Å) |

The new material used in the devices has the following structure:

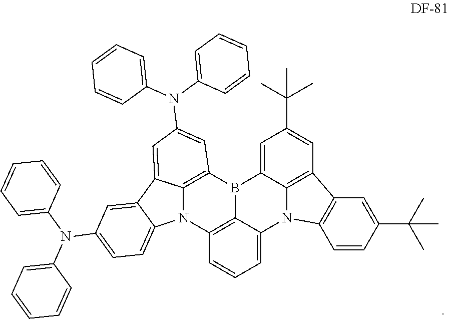 [SMILES: CC(C)(C)c1ccc2c(c1)c1cc(C(C)(C)C)cc3c1n2-c1cccc2c1B3c1cc(N(c3ccccc3)c3ccccc3)cc3c4cc(N(c5ccccc5)c5ccccc5)ccc4n-2c13]

The CIE data, maximum emission wavelengths (λₘₐₓ), full widths at half maximum (FWHM), drive voltages (V), current efficiency (CE), power efficiency (PE) and external quantum efficiency (EQE) of the devices were measured at constant brightness of 1000 cd/cm², and the lifetimes LT95 of the devices were measured at a constant current of 10 mA/cm². These data are recorded and shown in Table 5.

TABLE 5
Device data in Example 2 and Comparative Example 3

| | | λₘₐₓ | FWHM | Voltage | CE | PE | EQE | LT95 |
|---|---|---|---|---|---|---|---|---|
| Device ID | CIE (x, y) | (nm) | (nm) | (V) | (cd/A) | (lm/W) | (%) | (h) |
| Example 2 | (0.329, 0.651) | 539 | 43.4 | 2.95 | 110.3 | 117.5 | 26.6 | 237 |
| Comparative | (0.312, 0.659) | 539 | 41.3 | 3.22 | 42.8 | 41.8 | 10.6 | 100 |
| Example 3 | | | | | | | | |

Similarly, Example 2 differs from Comparative Example 3 only in that the metal complex of the present disclosure comprising a ligand La which is represented by a structure of Formula 1 and has a particular substituent R_{Ar} on a particular ring is used in the emissive layer of Example 2 as the phosphorescence sensitizer while no phosphorescence sensitizer is used in Comparative Example 3.

Similarly, as can be seen from the data in Table 5, the maximum emission wavelength of Example 2 is consistent with that of Comparative Example 3, indicating that light emitted by the device of Example 2 also comes from the fluorescent emissive material. Compared with Comparative Example 4, Examples 3 further achieves a significant improvement in device efficiency and lifetime on the basis of maintaining a narrow full width at half maximum and a low voltage that are basically equivalent to the full width at half maximum and the voltage of Comparative Example 4. Specifically, the CE, PE and EQE are significantly improved by 157.8%, 181.10% and 150.9%, respectively, and in particular, the lifetime is more than 2.3 times the lifetime of Comparative Example 3.

The above data indicate that compared with the common fluorescent device without a phosphorescence sensitizer, the sensitized fluorescent device of the present disclosure using the metal complex comprising the particular ligand La as a sensitizer in the emissive layer for sensitizing the fluorescent emissive material has very excellent performance; not only can a low drive voltage level and a narrow full width at half maximum be maintained but the device efficiency and the lifetime can also be significantly improved, well making up for shortcomings of the common fluorescent light-emitting device in efficiency and lifetime.

In conclusion, using the metal complex of the present disclosure comprising the ligand Lₐ which is represented by the structure of Formula 1 in the emissive layer of the device of the present disclosure can efficiently sensitize the fluorescent material to obtain a device with excellent performance; for example, a low drive voltage, high device efficiency (CE, PE and EQE) and a very excellent device lifetime can be obtained. Therefore, the device has an extremely high application prospect.

It is to be understood that various embodiments described herein are merely illustrative and not intended to limit the scope of the present disclosure. Therefore, it is apparent to the persons skilled in the art that the present disclosure as claimed may include variations of specific embodiments and preferred embodiments described herein. Many of the materials and structures described herein may be replaced with other materials and structures without departing from the spirit of the present disclosure. It is to be understood that various theories as to why the present disclosure works are not intended to be limiting.

What is claimed is:

1. An organic electroluminescent device, comprising:
an anode,
a cathode, and
an emissive layer disposed between the anode and the cathode, wherein the emissive layer comprises at least a metal complex and a fluorescent emissive material;
wherein the metal complex comprises a metal M and a ligand La coordinated to the metal M, the metal M is selected from a metal with a relative atomic mass greater than 40, and Lₐ has a structure represented by Formula 1: 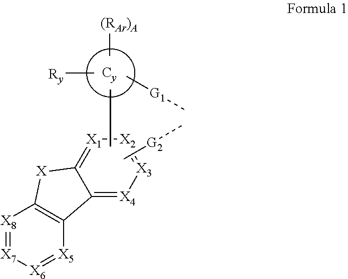
wherein
the ring C_{y} is, at each occurrence identically or differently, selected from an aromatic ring having 6 to 30 ring atoms, a heteroaromatic ring having 5 to 30 ring atoms or a combination thereof;
G₁ and G₂ are, at each occurrence identically or differently, selected from a single bond, O, S or NR′;
X is selected from the group consisting of O, S, Se, CR₁R₁, SiR₁R₁ and GeR₁R₁;
X₁ to X₄ are each independently selected from C, CRₓ or N, one of X₁ to X₄ is selected from C and joined to the ring C_{y}, and one of X₁ to X₄ is selected from C or N and joined to G₂;
X₅ to X₈ are, at each occurrence identically or differently, selected from CRₓ or N;
R_{Ar} is, at each occurrence identically or differently, selected from the group consisting of: substituted or unsubstituted aryl having 6 to 30 carbon atoms, substituted or unsubstituted heteroaryl having 3 to 30 carbon atoms and combinations thereof;
A is, at each occurrence identically or differently, selected from 1, 2, 3 or 4;
R_{y} represents, at each occurrence identically or differently, mono-substitution, multiple substitutions or non-substitution;
Rₓ, R_{y}, R′ and R₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ, R_{y}, R′, R_{Ar} and R₁ can be optionally joined to form a ring.

2. The organic electroluminescent device according to claim 1, wherein the metal complex has a structure of Formula M(Lₐ)ₘ(L_{b})ₙ(L_{c})_{q}, wherein the ligands Lₐ, L_{b} and L_{c} are a first ligand, a second ligand and a third ligand coordinated to the metal M, respectively, and the ligands Lₐ, L_{b} and L_{c} can be optionally joined to form a multidentate ligand:
the metal M is selected from a metal with a relative atomic mass greater than 40; preferably, the metal M is selected from the group consisting of Cu, Ag, Au, Ru, Rh, Pd, Os, Ir and Pt; more preferably, the metal M is selected from Pt or Ir;
m is selected from 1, 2 or 3, n is selected from 0, 1 or 2, q is selected from 0, 1 or 2, and m+n+q is equal to an oxidation state of the metal M; when m is greater than or equal to 2, multiple Lₐ are the same or different; when n is equal to 2, two L_{b} are the same or different; when q is equal to 2, two L_{c} are the same or different;
L_{b} and L_{c} are, at each occurrence identically or differently, selected from a structure represented by any one of the group consisting of the following: 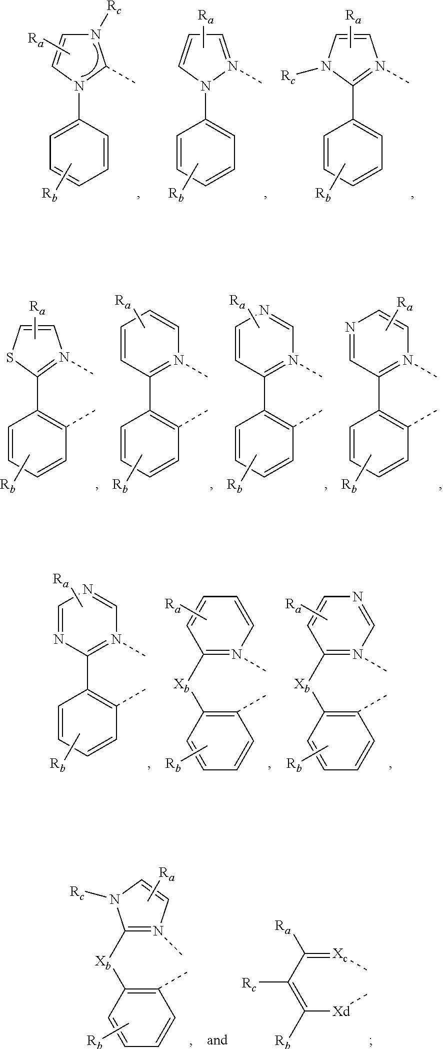
wherein,
Rₐ and R_{b} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₐ, R_{b}, R_{c}, R_{N1}, R_{N2}, R_{C1} and R_{C2} can be optionally joined to form a ring.

3. The organic electroluminescent device according to claim 1, wherein G₁ is a single bond, and the ring C_{y} is, at each occurrence identically or differently, selected from any one of the group consisting of the following structures: 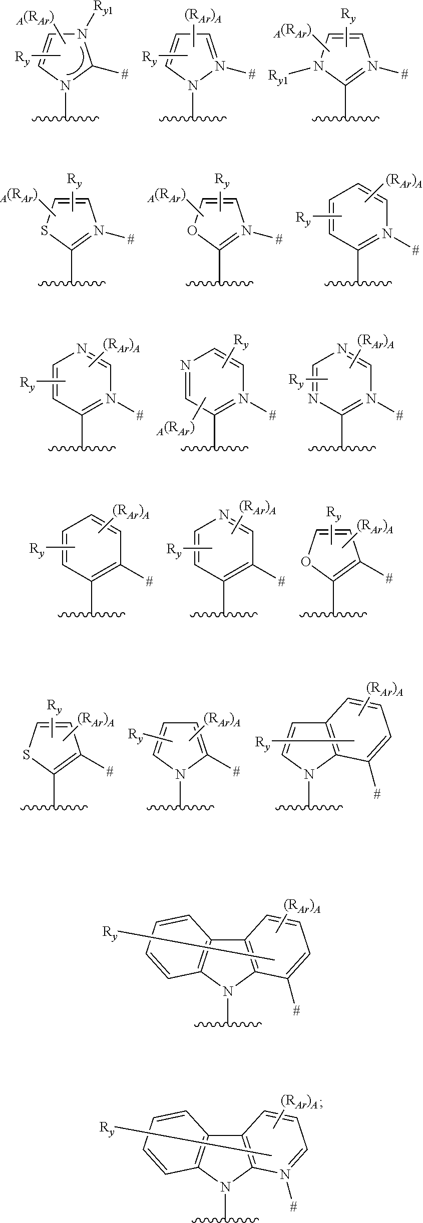
wherein,
R_{Ar} is, at each occurrence identically or differently, selected from the group consisting of: substituted or unsubstituted aryl having 6 to 30 carbon atoms, substituted or unsubstituted heteroaryl having 3 to 30 carbon atoms and combinations thereof;
A is, at each occurrence identically or differently, selected from 1, 2, 3 or 4;
R_{y} represents, at each occurrence identically or differently, mono-substitution, multiple substitutions or non-substitution;
R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{y} and R_{Ar} can be optionally joined to form a ring;
wherein “#” represents a position where C_{y} is joined to the metal M, and 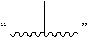
represents a position where Cy is joined to X₁, X₂, X₃ or X₄.

4. The organic electroluminescent device according to claim 1, wherein the metal complex has a structure of Formula Ir(Lₐ)ₘ(L_{b})₃₋ₘ and has a structure represented by Formula 2: 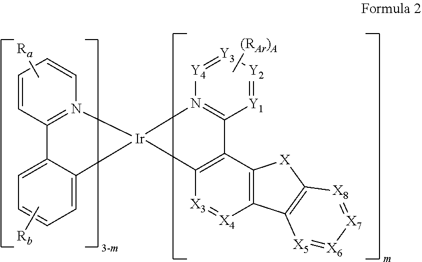
wherein,
m is selected from 1 or 2; when m is selected from 1, two L_{b} are the same or different; when m is selected from 2, two Lₐ are the same or different; preferably, m is 1;
X is selected from the group consisting of O, S, Se, CR₁R₁, SiR₁R₁ and GeR₁R₁;
X₃ to X₈ are each independently selected from CRₓ or N;
Y₁ to Y₄ are each independently selected from C, CR_{y} or N, and when Y₁ to Y₄ are selected from C, Y₁ to Y₄ are joined to R_{Ar};
A is, at each occurrence identically or differently, selected from 1, 2, 3 or 4;
R_{Ar} is, at each occurrence identically or differently, selected from the group consisting of: substituted or unsubstituted aryl having 6 to 30 carbon atoms, substituted or unsubstituted heteroaryl having 3 to 30 carbon atoms and combinations thereof;
Rₐ and R_{b} represent, at each occurrence identically or differently, mono-substitution, multiple substitutions or non-substitution;
Rₓ, R_{y}, R₁, Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁, Rₓ, R_{y}, R_{Ar}, Rₐ and R_{b} can be optionally joined to form a ring.

5. The organic electroluminescent device according to claim 1, wherein A is selected from 1 or 2; preferably, A is selected from 1.

6. The organic electroluminescent device according to claim 1, wherein X is selected from O, S, Se and CR₁R₁; preferably, X is selected from O or S.

7. The organic electroluminescent device according to claim 4, wherein Rₐ and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group and combinations thereof; and
preferably, at least one of R, and/or at least one of R_{b} is(are), at each occurrence identically or differently, selected from the group consisting of; deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, a hydroxyl group, a sulfanyl group and combinations thereof.

8. The organic electroluminescent device according to claim 4, wherein at least one of Y₁ to Y₄ is selected from CR_{y}, and R_{y} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
preferably, at least one of Y₁ or Y₄ is selected from CR_{y}, and R_{y} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof; and
more preferably, Y₂ or Y₃ is selected from CR_{y}, and R_{y} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms and combinations thereof.

9. The organic electroluminescent device according to claim 4, wherein Y₂ is selected from C and directly joined to R_{Ar}, or Y₃ is selected from C and directly joined to RU;
preferably, Y₂ is selected from C and directly joined to R_{Ar}, and Y₃ is selected from CR_{y}; or Y₃ is selected from C and directly joined to R_{Ar}, and Y₂ is selected from CR_{y}; R_{y} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, a hydroxyl group, a sulfanyl group and combinations thereof; and
more preferably, Y₂ is selected from C and directly joined to R_{Ar}, and Y₃ is selected from CR_{y}; or Y₃ is selected from C and directly joined to R_{Ar}, and Y₂ is selected from CR_{y}; R_{y} is, at each occurrence identically or differently, selected from substituted or unsubstituted alkyl having 1 to 20 carbon atoms, substituted or unsubstituted cycloalkyl having 3 to 20 ring carbon atoms or a combination thereof.

10. The organic electroluminescent device according to claim 1, wherein X₃ to X₈ are each independently selected from CRₓ;
preferably, X₃ to X₈ are each independently selected from CRₓ, and R, is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, a hydroxyl group, a sulfanyl group and combinations thereof; and
more preferably, R, is, at each occurrence identically or differently, selected from the group consisting of: hydrogen, deuterium, fluorine, cyano, hydroxyl, sulfanyl, methyl, deuterated methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, triphenylene, naphthyl, phenanthryl, anthryl, indenyl, fluorenyl, indolyl, carbazolyl, benzofuranyl, dibenzofuranyl, benzosilolyl, dibenzosilolyl, benzothienyl, dibenzothienyl, dibenzoselenophenyl and combinations thereof.

11. The organic electroluminescent device according to claim 1, wherein at least one of X₃ to X₈ is selected from N;
preferably, X₈ is selected from N; and
more preferably, X₈ is N, X₃ to X₇ are selected from CRₓ, and Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group and combinations thereof.

12. The organic electroluminescent device according to claim 1, wherein at least one of X₃ to X₈ is selected from CRₓ, and Rₓ is selected from cyano or fluorine; and
preferably, X₇ is selected from CRₓ, and R is cyano or fluorine; or X₈ is selected from CRₓ, and Rₓ is cyano.

13. The organic electroluminescent device according to claim 1, wherein R_{Ar} has a structure represented by any one of Ar-1 to Ar-86: 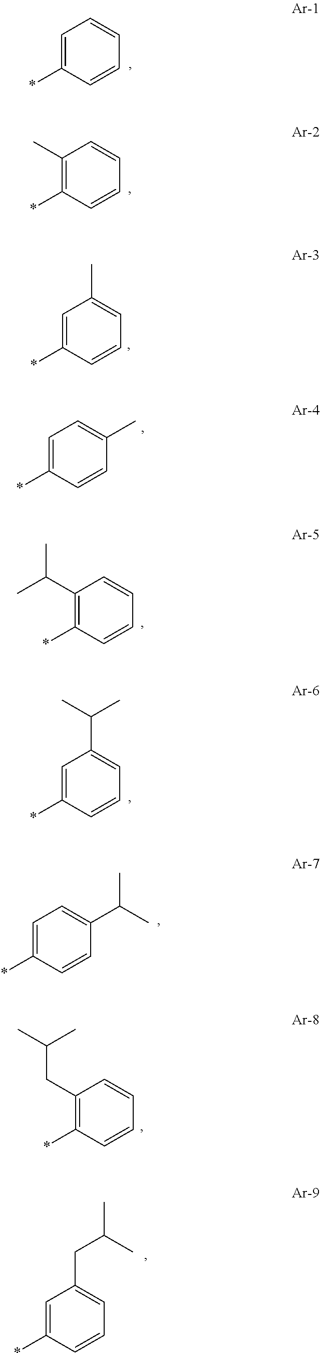 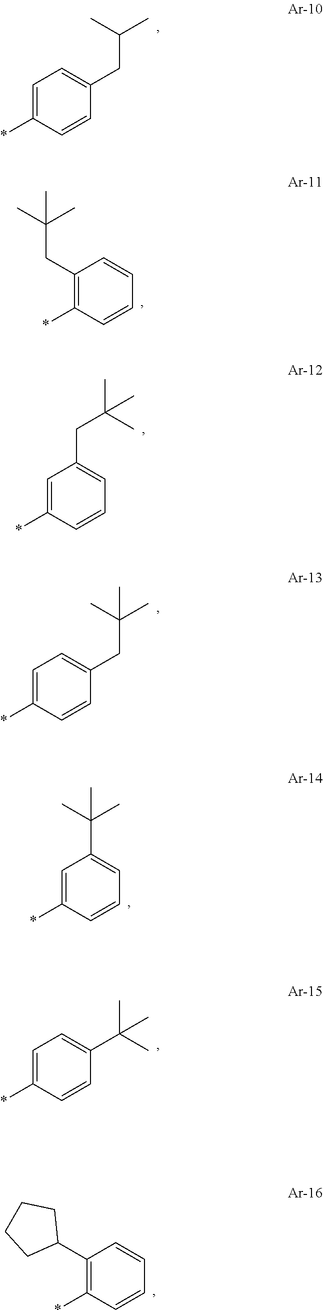 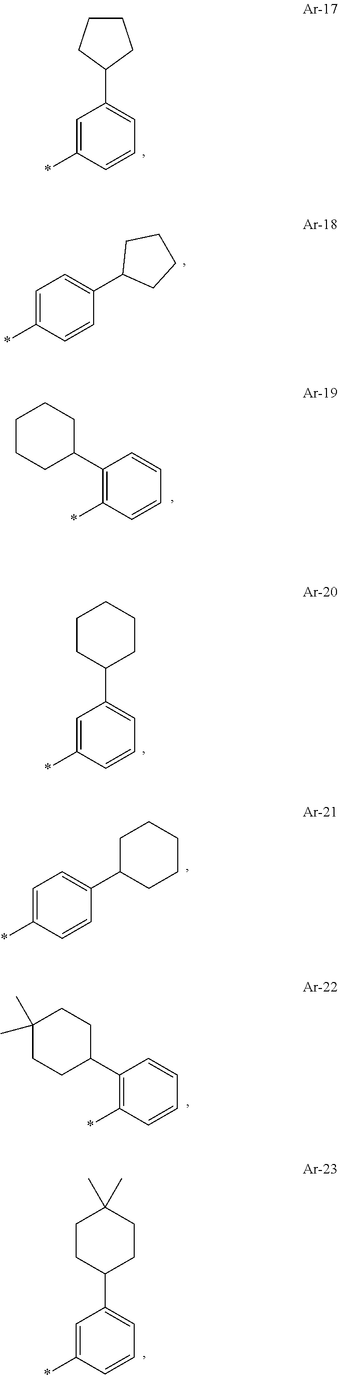 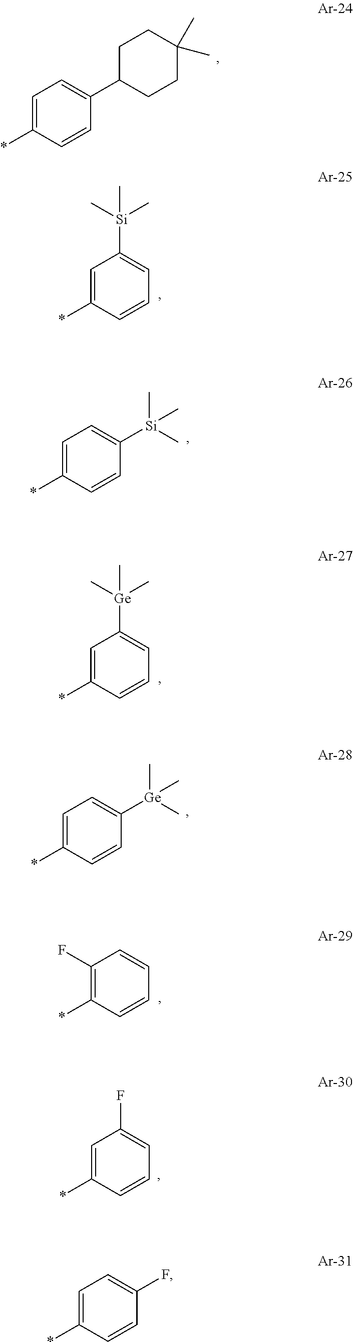 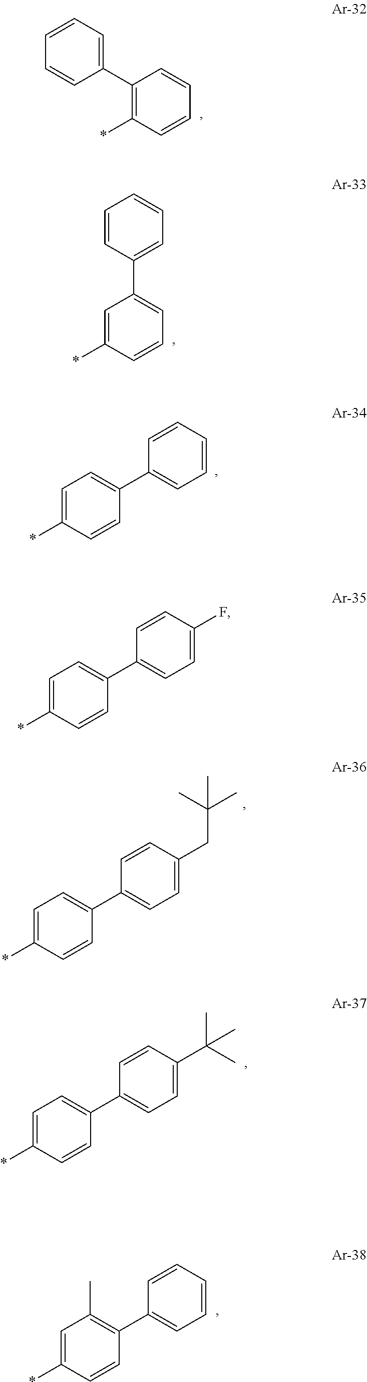 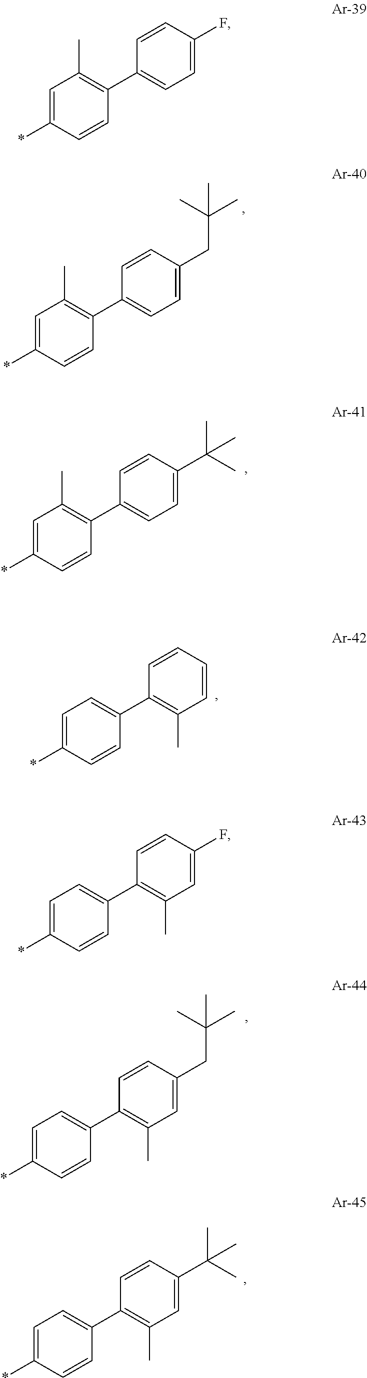 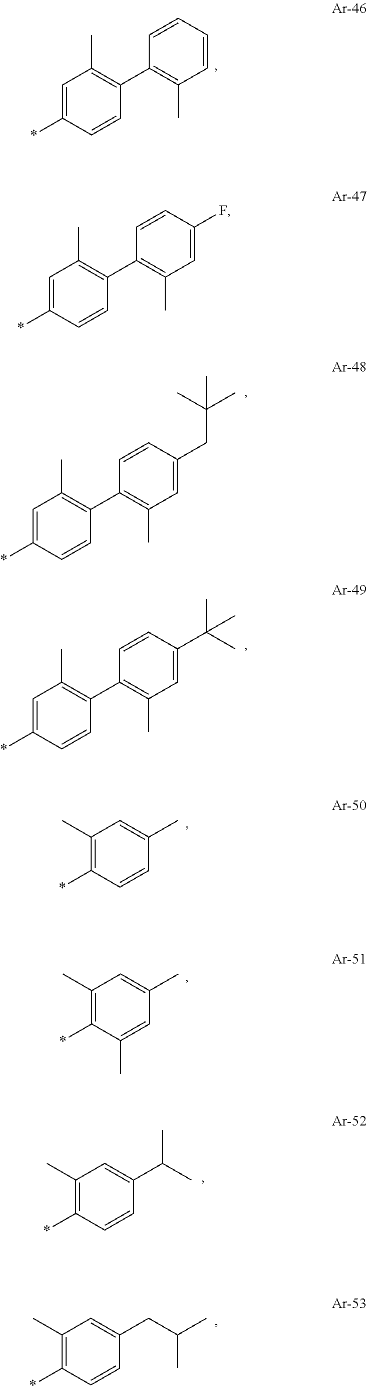 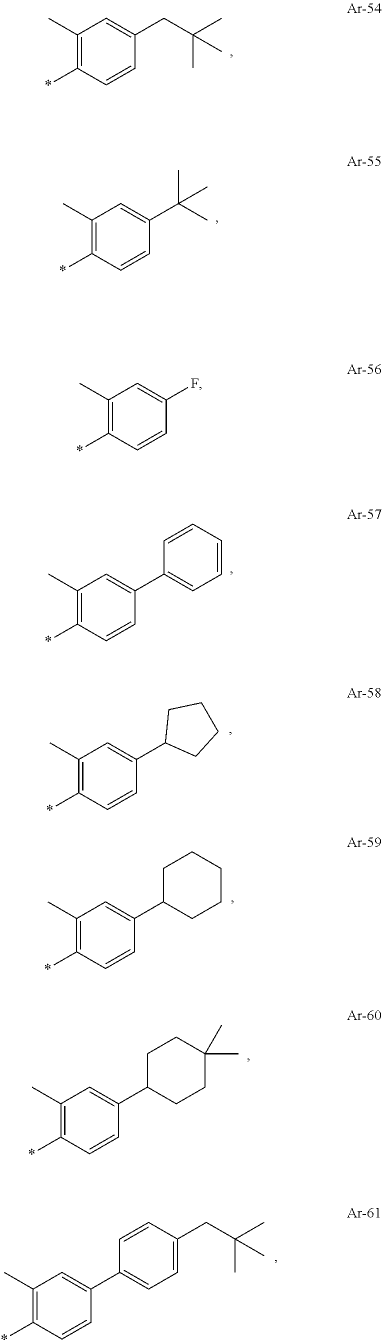 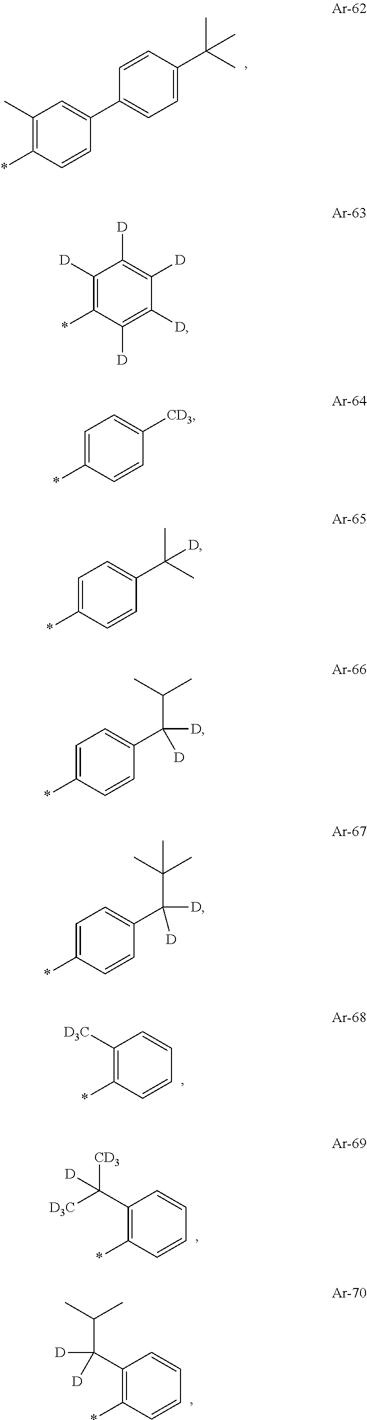 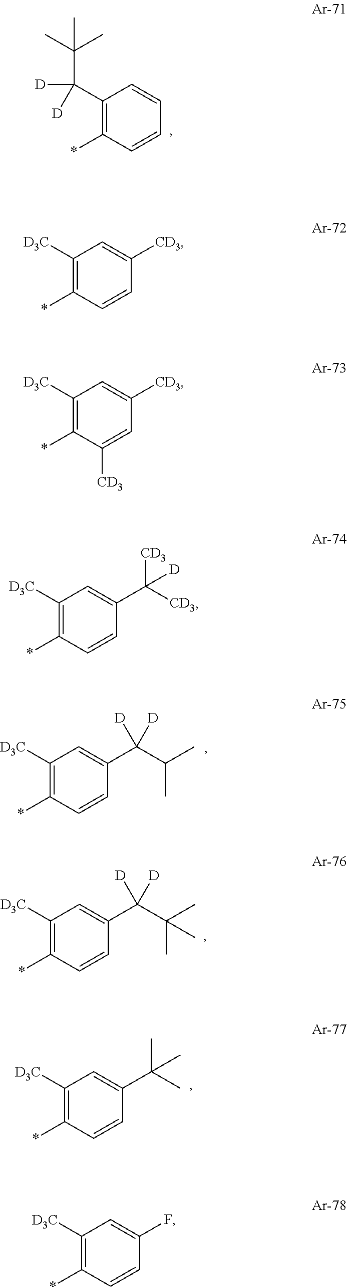 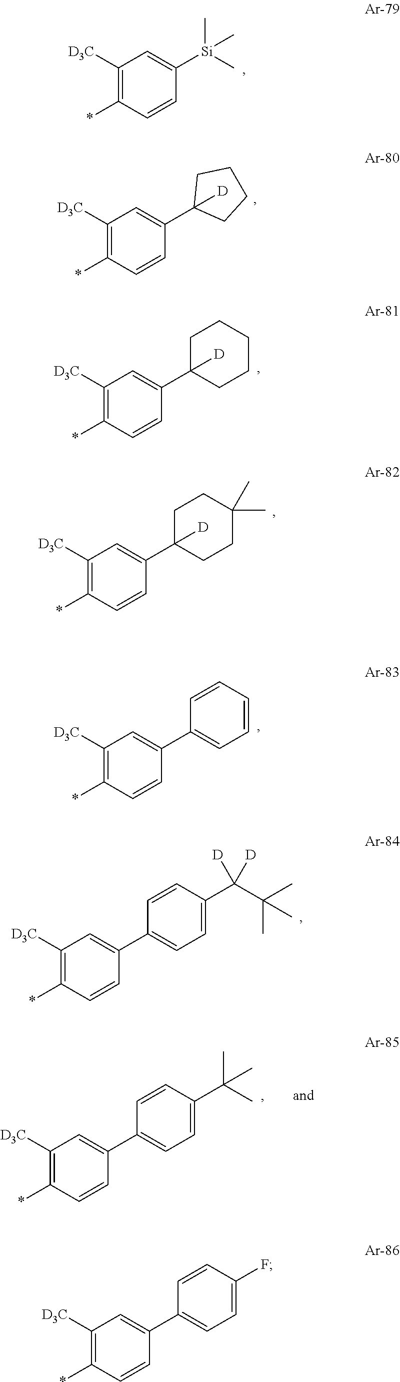
wherein * represents a position where Ar-1 to Ar-86 are joined to the ring C_{y};
optionally, hydrogen in Ar-1 to Ar-86 can be partially or fully substituted with deuterium; and preferably, R_{Ar} has a structure represented by Ar-68 to Ar-86.

14. The organic electroluminescent device according to claim 13, wherein Lₐ is, at each occurrence identically or differently, selected from the group consisting of Lₐ₁ to Lₐ₅₉₀;
wherein Lₐ₁ to Lₐ₂₃₀ have the following structure: 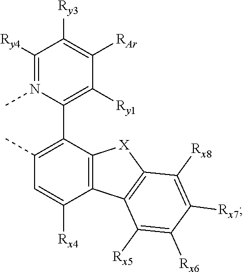
Rₓ₄ to Rₓ₈, R_{y1}, R_{y3}, R_{y4}, R_{Ar} and X are selected from the atoms or the groups in the following table, respectively;

| Lₐ | Rₓ₄ | Rₓ₅ | Rₓ₆ | Rₓ₇ | Rₓ₈ | R_{y1} | R_{Ar} | R_{y3} | R_{y4} | X |
|---|---|---|---|---|---|---|---|---|---|---|
| Lₐ₁ | H | H | H | H | H | H | Ar-1 | H | H | O |
| Lₐ₂ | H | H | H | H | H | H | Ar-15 | H | H | O |
| Lₐ₃ | H | H | H | H | H | H | Ar-31 | H | H | O |
| Lₐ₄ | H | H | H | H | H | H | Ar-34 | H | H | O |
| Lₐ₅ | H | H | H | H | H | H | Ar-68 | H | H | O |
| Lₐ₆ | H | H | H | H | H | H | Ar-76 | H | H | O |
| Lₐ₇ | H | H | H | H | H | H | Ar-77 | H | H | O |
| Lₐ₈ | H | H | H | H | H | H | Ar-78 | H | H | O |
| Lₐ₉ | H | H | H | H | H | H | Ar-83 | H | H | O |
| Lₐ₁₀ | H | H | H | H | H | H | Ar-85 | H | H | O |
| Lₐ₁₁ | H | H | H | H | H | H | Ar-1 | CD₃ | H | O |
| Lₐ₁₂ | H | H | H | H | H | H | Ar-15 | CD₃ | H | O |
| Lₐ₁₃ | H | H | H | H | H | H | Ar-31 | CD₃ | H | O |
| Lₐ₁₄ | H | H | H | H | H | H | Ar-34 | CD₃ | H | O |
| Lₐ₁₅ | H | H | H | H | H | H | Ar-68 | CD₃ | H | O |
| Lₐ₁₆ | H | H | H | H | H | H | Ar-76 | CD₃ | H | O |
| Lₐ₁₇ | H | H | H | H | H | H | Ar-77 | CD₃ | H | O |
| Lₐ₁₈ | H | H | H | H | H | H | Ar-78 | CD₃ | H | O |
| Lₐ₁₉ | H | H | H | H | H | H | Ar-83 | CD₃ | H | O |
| Lₐ₂₀ | H | H | H | H | H | H | Ar-85 | CD₃ | H | O |
| Lₐ₂₁ | P2 | H | H | H | H | H | Ar-1 | CD₃ | H | O |
| Lₐ₂₂ | P2 | H | H | H | H | H | Ar-15 | CD₃ | H | O |
| Lₐ₂₃ | P2 | H | H | H | H | H | Ar-31 | CD₃ | H | O |
| Lₐ₂₄ | P2 | H | H | H | H | H | Ar-34 | CD₃ | H | O |
| Lₐ₂₅ | P2 | H | H | H | H | H | Ar-68 | CD₃ | H | O |
| Lₐ₂₆ | P2 | H | H | H | H | H | Ar-76 | CD₃ | H | O |
| Lₐ₂₇ | P2 | H | H | H | H | H | Ar-77 | CD₃ | H | O |
| Lₐ₂₈ | P2 | H | H | H | H | H | Ar-78 | CD₃ | H | O |
| Lₐ₂₉ | P2 | H | H | H | H | H | Ar-83 | CD₃ | H | O |
| Lₐ₃₀ | P2 | H | H | H | H | H | Ar-85 | CD₃ | H | O |
| Lₐ₃₁ | P5 | H | H | H | H | H | Ar-1 | CD₃ | H | O |
| Lₐ₃₂ | P5 | H | H | H | H | H | Ar-15 | CD₃ | H | O |
| Lₐ₃₃ | P5 | H | H | H | H | H | Ar-31 | CD₃ | H | O |
| Lₐ₃₄ | P5 | H | H | H | H | H | Ar-34 | CD₃ | H | O |
| Lₐ₃₅ | P5 | H | H | H | H | H | Ar-68 | CD₃ | H | O |
| Lₐ₃₆ | P5 | H | H | H | H | H | Ar-76 | CD₃ | H | O |
| Lₐ₃₇ | P5 | H | H | H | H | H | Ar-77 | CD₃ | H | O |
| Lₐ₃₈ | P5 | H | H | H | H | H | Ar-78 | CD₃ | H | O |
| Lₐ₃₉ | P5 | H | H | H | H | H | Ar-83 | CD₃ | H | O |
| Lₐ₄₀ | P5 | H | H | H | H | H | Ar-85 | CD₃ | H | O |
| Lₐ₄₁ | P8 | H | H | H | H | H | Ar-1 | CD₃ | H | O |
| Lₐ₄₂ | P8 | H | H | H | H | H | Ar-15 | CD₃ | H | O |
| Lₐ₄₃ | P8 | H | H | H | H | H | Ar-31 | CD₃ | H | O |
| Lₐ₄₄ | P8 | H | H | H | H | H | Ar-34 | CD₃ | H | O |
| Lₐ₄₅ | P8 | H | H | H | H | H | Ar-68 | CD₃ | H | O |
| Lₐ₄₆ | P8 | H | H | H | H | H | Ar-76 | CD₃ | H | O |
| Lₐ₄₇ | P8 | H | H | H | H | H | Ar-77 | CD₃ | H | O |
| Lₐ₄₈ | P8 | H | H | H | H | H | Ar-78 | CD₃ | H | O |
| Lₐ₄₉ | P8 | H | H | H | H | H | Ar-83 | CD₃ | H | O |
| Lₐ₅₀ | P8 | H | H | H | H | H | Ar-85 | CD₃ | H | O |
| Lₐ₅₁ | H | H | H | F | H | H | Ar-1 | CD₃ | H | O |
| Lₐ₅₂ | H | H | H | F | D | H | Ar-15 | CD₃ | H | O |
| Lₐ₅₃ | H | H | H | F | D | H | Ar-31 | CD₃ | H | O |
| Lₐ₅₄ | H | H | H | F | D | H | Ar-34 | CD₃ | H | O |
| Lₐ₅₅ | H | H | H | F | D | H | Ar-68 | CD₃ | H | O |
| Lₐ₅₆ | H | H | H | F | D | H | Ar-76 | CD₃ | H | O |
| Lₐ₅₇ | H | H | H | F | D | H | Ar-77 | CD₃ | H | O |
| Lₐ₅₈ | H | H | H | F | D | H | Ar-78 | CD₃ | H | O |
| Lₐ₅₉ | H | H | H | F | D | H | Ar-83 | CD₃ | H | O |
| Lₐ₆₀ | H | H | H | F | D | H | Ar-85 | CD₃ | H | O |
| Lₐ₆₁ | P2 | H | H | F | D | H | Ar-1 | CD₃ | H | O |
| Lₐ₆₂ | P2 | H | H | F | D | H | Ar-15 | CD₃ | H | O |
| Lₐ₆₃ | P2 | H | H | F | D | H | Ar-31 | CD₃ | H | O |
| Lₐ₆₄ | P2 | H | H | F | D | H | Ar-34 | CD₃ | H | O |
| Lₐ₆₅ | P2 | H | H | F | D | H | Ar-68 | CD₃ | H | O |
| Lₐ₆₆ | P2 | H | H | F | D | H | Ar-76 | CD₃ | H | O |
| Lₐ₆₇ | P2 | H | H | F | D | H | Ar-77 | CD₃ | H | O |
| Lₐ₆₈ | P2 | H | H | F | D | H | Ar-78 | CD₃ | H | O |
| Lₐ₆₉ | P2 | H | H | F | D | H | Ar-83 | CD₃ | H | O |
| Lₐ₇₀ | P2 | H | H | F | D | H | Ar-85 | CD₃ | H | O |
| Lₐ₇₁ | P5 | H | H | F | D | H | Ar-1 | CD₃ | H | O |
| Lₐ₇₂ | P5 | H | H | F | D | H | Ar-15 | CD₃ | H | O |
| Lₐ₇₃ | P5 | H | H | F | D | H | Ar-31 | CD₃ | H | O |
| Lₐ₇₄ | P5 | H | H | F | D | H | Ar-34 | CD₃ | H | O |
| Lₐ₇₅ | P5 | H | H | F | D | H | Ar-68 | CD₃ | H | O |
| Lₐ₇₆ | P5 | H | H | F | D | H | Ar-76 | CD₃ | H | O |
| Lₐ₇₇ | P5 | H | H | F | D | H | Ar-77 | CD₃ | H | O |
| Lₐ₇₈ | P5 | H | H | F | D | H | Ar-78 | CD₃ | H | O |
| Lₐ₇₉ | P5 | H | H | F | D | H | Ar-83 | CD₃ | H | O |
| Lₐ₈₀ | P5 | H | H | F | D | H | Ar-85 | CD₃ | H | O |
| Lₐ₈₁ | P8 | H | H | F | D | H | Ar-1 | CD₃ | H | O |
| Lₐ₈₂ | P8 | H | H | F | D | H | Ar-15 | CD₃ | H | O |
| Lₐ₈₃ | P8 | H | H | F | D | H | Ar-31 | CD₃ | H | O |
| Lₐ₈₄ | P8 | H | H | F | D | H | Ar-34 | CD₃ | H | O |
| Lₐ₈₅ | P8 | H | H | F | D | H | Ar-68 | CD₃ | H | O |
| Lₐ₈₆ | P8 | H | H | F | D | H | Ar-76 | CD₃ | H | O |
| Lₐ₈₇ | P8 | H | H | F | D | H | Ar-77 | CD₃ | H | O |
| Lₐ₈₈ | P8 | H | H | F | D | H | Ar-78 | CD₃ | H | O |
| Lₐ₈₉ | P8 | H | H | F | D | H | Ar-83 | CD₃ | H | O |
| Lₐ₉₀ | P8 | H | H | F | D | H | Ar-85 | CD₃ | H | O |
| Lₐ₉₁ | H | H | H | CN | D | H | Ar-1 | CD₃ | H | O |
| Lₐ₉₂ | H | H | H | CN | D | H | Ar-15 | CD₃ | H | O |
| Lₐ₉₃ | H | H | H | CN | D | H | Ar-31 | CD₃ | H | O |
| Lₐ₉₄ | H | H | H | CN | D | H | Ar-34 | CD₃ | H | O |
| Lₐ₉₅ | H | H | H | CN | D | H | Ar-68 | CD₃ | H | O |
| Lₐ₉₆ | H | H | H | CN | D | H | Ar-76 | CD₃ | H | O |
| Lₐ₉₇ | H | H | H | CN | D | H | Ar-77 | CD₃ | H | O |
| Lₐ₉₈ | H | H | H | CN | D | H | Ar-78 | CD₃ | H | O |
| Lₐ₉₉ | H | H | H | CN | D | H | Ar-83 | CD₃ | H | O |
| Lₐ₁₀₀ | H | H | H | CN | D | H | Ar-85 | CD₃ | H | O |
| Lₐ₁₀₁ | P2 | H | H | CN | D | H | Ar-1 | CD₃ | H | O |
| Lₐ₁₀₂ | P2 | H | H | CN | D | H | Ar-15 | CD₃ | H | O |
| Lₐ₁₀₃ | P2 | H | H | CN | D | H | Ar-31 | CD₃ | H | O |
| Lₐ₁₀₄ | P2 | H | H | CN | D | H | Ar-34 | CD₃ | H | O |
| Lₐ₁₀₅ | P2 | H | H | CN | D | H | Ar-68 | CD₃ | H | O |
| Lₐ₁₀₆ | P2 | H | H | CN | D | H | Ar-76 | CD₃ | H | O |
| Lₐ₁₀₇ | P2 | H | H | CN | D | H | Ar-77 | CD₃ | H | O |
| Lₐ₁₀₈ | P2 | H | H | CN | D | H | Ar-78 | CD₃ | H | O |
| Lₐ₁₀₉ | P2 | H | H | CN | D | H | Ar-83 | CD₃ | H | O |
| Lₐ₁₁₀ | P2 | H | H | CN | D | H | Ar-85 | CD₃ | H | O |
| Lₐ₁₁₁ | P5 | H | H | CN | D | H | Ar-1 | CD₃ | H | O |
| Lₐ₁₁₂ | P5 | H | H | CN | D | H | Ar-15 | CD₃ | H | O |
| Lₐ₁₁₃ | P5 | H | H | CN | D | H | Ar-31 | CD₃ | H | O |
| Lₐ₁₁₄ | P5 | H | H | CN | D | H | Ar-34 | CD₃ | H | O |
| Lₐ₁₁₅ | P5 | H | H | CN | D | H | Ar-68 | CD₃ | H | O |
| Lₐ₁₁₆ | P5 | H | H | CN | D | H | Ar-76 | CD₃ | H | O |
| Lₐ₁₁₇ | P5 | H | H | CN | D | H | Ar-77 | CD₃ | H | O |
| Lₐ₁₁₈ | P5 | H | H | CN | D | H | Ar-78 | CD₃ | H | O |
| Lₐ₁₁₉ | P5 | H | H | CN | D | H | Ar-83 | CD₃ | H | O |
| Lₐ₁₂₀ | P5 | H | H | CN | D | H | Ar-85 | CD₃ | H | O |
| Lₐ₁₂₁ | P9 | H | H | CN | D | H | Ar-1 | CD₃ | H | O |
| Lₐ₁₂₂ | P9 | H | H | CN | D | H | Ar-15 | CD₃ | H | O |
| Lₐ₁₂₃ | P9 | H | H | CN | D | H | Ar-31 | CD₃ | H | O |
| Lₐ₁₂₄ | P9 | H | H | CN | D | H | Ar-34 | CD₃ | H | O |
| Lₐ₁₂₅ | P9 | H | H | CN | D | H | Ar-68 | CD₃ | H | O |
| Lₐ₁₂₆ | P9 | H | H | CN | D | H | Ar-76 | CD₃ | H | O |
| Lₐ₁₂₇ | P9 | H | H | CN | D | H | Ar-77 | CD₃ | H | O |
| Lₐ₁₂₈ | P9 | H | H | CN | D | H | Ar-78 | CD₃ | H | O |
| Lₐ₁₂₉ | P9 | H | H | CN | D | H | Ar-83 | CD₃ | H | O |
| Lₐ₁₃₀ | P9 | H | H | CN | D | H | Ar-85 | CD₃ | H | O |
| Lₐ₁₃₁ | H | CN | H | H | H | H | Ar-68 | CD₃ | H | O |
| Lₐ₁₃₂ | H | CN | H | H | H | H | Ar-76 | CD₃ | H | O |
| Lₐ₁₃₃ | H | CN | H | H | H | H | Ar-77 | CD₃ | H | O |
| Lₐ₁₃₄ | H | H | CN | H | H | H | Ar-68 | CD₃ | H | O |
| Lₐ₁₃₅ | H | H | CN | H | H | H | Ar-76 | CD₃ | H | O |
| Lₐ₁₃₆ | H | H | CN | H | H | H | Ar-77 | CD₃ | H | O |
| Lₐ₁₃₇ | H | H | H | H | CN | H | Ar-68 | CD₃ | H | O |
| Lₐ₁₃₈ | H | H | H | H | CN | H | Ar-76 | CD₃ | H | O |
| Lₐ₁₃₉ | H | H | H | H | CN | H | Ar-77 | CD₃ | H | O |
| Lₐ₁₄₀ | H | H | H | H | P10 | H | Ar-68 | CD₃ | H | O |
| Lₐ₁₄₁ | H | H | H | H | P10 | H | Ar-76 | CD₃ | H | O |
| Lₐ₁₄₂ | H | H | H | H | P10 | H | Ar-77 | CD₃ | H | O |
| Lₐ₁₄₃ | H | H | H | H | P11 | H | Ar-68 | CD₃ | H | O |
| Lₐ₁₄₄ | H | H | H | H | P11 | H | Ar-76 | CD₃ | H | O |
| Lₐ₁₄₅ | H | H | H | H | P11 | H | Ar-77 | CD₃ | H | O |
| Lₐ₁₄₆ | H | H | H | H | P12 | H | Ar-68 | CD₃ | H | O |
| Lₐ₁₄₇ | H | H | H | H | P12 | H | Ar-76 | CD₃ | H | O |
| Lₐ₁₄₈ | H | H | H | H | P12 | H | Ar-77 | CD₃ | H | O |
| Lₐ₁₄₉ | H | H | H | H | P13 | H | Ar-68 | CD₃ | H | O |
| Lₐ₁₅₀ | H | H | H | H | P13 | H | Ar-76 | CD₃ | H | O |
| Lₐ₁₅₁ | H | H | H | H | P13 | H | Ar-77 | CD₃ | H | O |
| Lₐ₁₅₂ | H | H | H | H | P14 | H | Ar-68 | CD₃ | H | O |
| Lₐ₁₅₃ | H | H | H | H | P14 | H | Ar-76 | CD₃ | H | O |
| Lₐ₁₅₄ | H | H | H | H | P14 | H | Ar-77 | CD₃ | H | O |
| Lₐ₁₅₅ | H | H | H | H | P15 | H | Ar-68 | CD₃ | H | O |
| Lₐ₁₅₆ | H | H | H | H | P15 | H | Ar-76 | CD₃ | H | O |
| Lₐ₁₅₇ | H | H | H | H | P15 | H | Ar-77 | CD₃ | H | O |
| Lₐ₁₅₈ | H | H | H | H | P16 | H | Ar-68 | CD₃ | H | O |
| Lₐ₁₅₉ | H | H | H | H | P16 | H | Ar-76 | CD₃ | H | O |
| Lₐ₁₆₀ | H | H | H | H | P16 | H | Ar-77 | CD₃ | H | O |
| Lₐ₁₆₁ | H | H | H | H | P17 | H | Ar-68 | CD₃ | H | O |
| Lₐ₁₆₂ | H | H | H | H | P17 | H | Ar-76 | CD₃ | H | O |
| Lₐ₁₆₃ | H | H | H | H | P17 | H | Ar-77 | CD₃ | H | O |
| Lₐ₁₆₄ | H | H | H | H | P18 | H | Ar-68 | CD₃ | H | O |
| Lₐ₁₆₅ | H | H | H | H | P18 | H | Ar-76 | CD₃ | H | O |
| Lₐ₁₆₆ | H | H | H | H | P18 | H | Ar-77 | CD₃ | H | O |
| Lₐ₁₆₇ | H | H | H | H | P19 | H | Ar-68 | CD₃ | H | O |
| Lₐ₁₆₈ | H | H | H | H | P19 | H | Ar-76 | CD₃ | H | O |
| Lₐ₁₆₉ | H | H | H | H | P19 | H | Ar-77 | CD₃ | H | O |
| Lₐ₁₇₀ | H | H | H | H | P20 | H | Ar-68 | CD₃ | H | O |
| Lₐ₁₇₁ | H | H | H | H | P20 | H | Ar-76 | CD₃ | H | O |
| Lₐ₁₇₂ | H | H | H | H | P20 | H | Ar-77 | CD₃ | H | O |
| Lₐ₁₇₃ | H | H | H | CN | P10 | H | Ar-76 | CD₃ | H | O |
| Lₐ₁₇₄ | H | H | H | CN | P11 | H | Ar-76 | CD₃ | H | O |
| Lₐ₁₇₅ | H | H | H | CN | P12 | H | Ar-76 | CD₃ | H | O |
| Lₐ₁₇₆ | H | H | H | CN | P13 | H | Ar-76 | CD₃ | H | O |
| Lₐ₁₇₇ | H | H | H | CN | P14 | H | Ar-76 | CD₃ | H | O |
| Lₐ₁₇₈ | H | H | H | CN | P15 | H | Ar-76 | CD₃ | H | O |
| Lₐ₁₇₉ | H | H | H | CN | P16 | H | Ar-76 | CD₃ | H | O |
| Lₐ₁₈₀ | H | H | H | CN | P17 | H | Ar-76 | CD₃ | H | O |
| Lₐ₁₈₁ | H | H | H | CN | P18 | H | Ar-76 | CD₃ | H | O |
| Lₐ₁₈₂ | H | H | H | CN | P19 | H | Ar-76 | CD₃ | H | O |
| Lₐ₁₈₃ | H | H | H | CN | P20 | H | Ar-76 | CD₃ | H | O |
| Lₐ₁₈₄ | H | H | H | F | P10 | H | Ar-76 | CD₃ | H | O |
| Lₐ₁₈₅ | H | H | H | F | P11 | H | Ar-76 | CD₃ | H | O |
| Lₐ₁₈₆ | H | H | H | F | P12 | H | Ar-76 | CD₃ | H | O |
| Lₐ₁₈₇ | H | H | H | F | P13 | H | Ar-76 | CD₃ | H | O |
| Lₐ₁₈₈ | H | H | H | F | P14 | H | Ar-76 | CD₃ | H | O |
| Lₐ₁₈₉ | H | H | H | F | P15 | H | Ar-76 | CD₃ | H | O |
| Lₐ₁₉₀ | H | H | H | F | P16 | H | Ar-76 | CD₃ | H | O |
| Lₐ₁₉₁ | H | H | H | F | P17 | H | Ar-76 | CD₃ | H | O |
| Lₐ₁₉₂ | H | H | H | F | P18 | H | Ar-76 | CD₃ | H | O |
| Lₐ₁₉₃ | H | H | H | F | P19 | H | Ar-76 | CD₃ | H | O |
| Lₐ₁₉₄ | H | H | H | F | P20 | H | Ar-76 | CD₃ | H | O |
| Lₐ₁₉₅ | P5 | H | H | CN | P10 | H | Ar-76 | CD₃ | H | O |
| Lₐ₁₉₆ | P5 | H | H | CN | P11 | H | Ar-76 | CD₃ | H | O |
| Lₐ₁₉₇ | P5 | H | H | CN | P12 | H | Ar-76 | CD₃ | H | O |
| Lₐ₁₉₈ | P5 | H | H | CN | P13 | H | Ar-76 | CD₃ | H | O |
| Lₐ₁₉₉ | P5 | H | H | CN | P14 | H | Ar-76 | CD₃ | H | O |
| Lₐ₂₀₀ | P5 | H | H | CN | P15 | H | Ar-76 | CD₃ | H | O |
| Lₐ₂₀₁ | P5 | H | H | CN | P16 | H | Ar-76 | CD₃ | H | O |
| Lₐ₂₀₂ | P5 | H | H | CN | P12 | H | Ar-76 | CD₃ | H | O |
| Lₐ₂₀₃ | P5 | H | H | CN | P18 | H | Ar-76 | CD₃ | H | O |
| Lₐ₂₀₄ | P5 | H | H | CN | P19 | H | Ar-76 | CD₃ | H | O |
| Lₐ₂₀₅ | P5 | H | H | CN | P20 | H | Ar-76 | CD₃ | H | O |
| Lₐ₂₀₆ | P9 | H | H | CN | P10 | H | Ar-76 | CD₃ | H | O |
| Lₐ₂₀₇ | P9 | H | H | CN | P11 | H | Ar-76 | CD₃ | H | O |
| Lₐ₂₀₈ | P9 | H | H | CN | P12 | H | Ar-76 | CD₃ | H | O |
| Lₐ₂₀₉ | P9 | H | H | CN | P13 | H | Ar-76 | CD₃ | H | O |
| Lₐ₂₁₀ | P9 | H | H | CN | P14 | H | Ar-76 | CD₃ | H | O |
| Lₐ₂₁₁ | P9 | H | H | CN | P15 | H | Ar-76 | CD₃ | H | O |
| Lₐ₂₁₂ | P9 | H | H | CN | P16 | H | Ar-76 | CD₃ | H | O |
| Lₐ₂₁₃ | P9 | H | H | CN | P17 | H | Ar-76 | CD₃ | H | O |
| Lₐ₂₁₄ | P9 | H | H | CN | P18 | H | Ar-76 | CD₃ | H | O |
| Lₐ₂₁₅ | P9 | H | H | CN | P19 | H | Ar-76 | CD₃ | H | O |
| Lₐ₂₁₆ | P9 | H | H | CN | P20 | H | Ar-76 | CD₃ | H | O |
| Lₐ₂₁₇ | P1 | H | H | CN | D | H | Ar-76 | CD₃ | H | O |
| Lₐ₂₁₈ | P3 | H | H | CN | D | H | Ar-76 | CD₃ | H | O |
| Lₐ₂₁₉ | P4 | H | H | CN | D | H | Ar-76 | CD₃ | H | O |
| Lₐ₂₂₀ | P6 | H | H | CN | D | H | Ar-76 | CD₃ | H | O |
| Lₐ₂₂₁ | P7 | H | H | CN | D | H | Ar-76 | CD₃ | H | O |
| Lₐ₂₂₂ | D | H | H | CN | D | H | Ar-76 | CD₃ | H | O |
| Lₐ₂₂₃ | H | H | H | CN | D | D | Ar-76 | CD₃ | H | O |
| Lₐ₂₂₄ | H | H | H | CN | D | H | Ar-76 | CD₃ | D | O |
| Lₐ₂₂₅ | H | H | H | CN | D | H | Ar-76 | CD₃ | D | O |
| Lₐ₂₂₆ | H | H | H | H | H | H | Ar-76 | CD₃ | H | S |
| Lₐ₂₂₇ | H | H | H | CN | D | H | Ar-76 | CD₃ | H | S |
| Lₐ₂₂₈ | P2 | H | H | CN | D | H | Ar-76 | CD₃ | H | S |
| Lₐ₂₂₉ | P5 | H | H | CN | D | H | Ar-76 | CD₃ | H | S |
| Lₐ₂₃₀ | P9 | H | H | CN | D | H | Ar-76 | CD₃ | H | S |

Lₐ₂₃₁ to Lₐ₄₆₀ have the following structure: 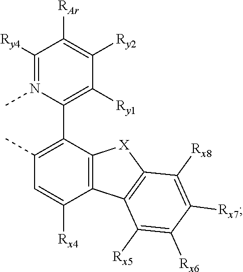
Rₓ₄ to Rₓ₅, R_{y1}, R_{y2}, R_{y4}, R_{Ar} and X are selected from the atoms or the groups in the following table, respectively;

| Lₐ | Rₓ₄ | Rₓ₅ | Rₓ₆ | Rₓ₇ | Rₓ₈ | R_{y1} | R_{y2} | R_{Ar} | R_{y4} | X |
|---|---|---|---|---|---|---|---|---|---|---|
| Lₐ₂₃₁ | H | H | H | H | H | H | H | Ar-1 | H | O |
| Lₐ₂₃₂ | H | H | H | H | H | H | H | Ar-15 | H | O |
| Lₐ₂₃₃ | H | H | H | H | H | H | H | Ar-31 | H | O |
| Lₐ₂₃₄ | H | H | H | H | H | H | H | Ar-34 | H | O |
| Lₐ₂₃₅ | H | H | H | H | H | H | H | Ar-68 | H | O |
| Lₐ₂₃₆ | H | H | H | H | H | H | H | Ar-76 | H | O |
| Lₐ₂₃₇ | H | H | H | H | H | H | H | Ar-77 | H | O |
| Lₐ₂₃₈ | H | H | H | H | H | H | H | Ar-78 | H | O |
| Lₐ₂₃₉ | H | H | H | H | H | H | H | Ar-83 | H | O |
| Lₐ₂₄₀ | H | H | H | H | H | H | H | Ar-85 | H | O |
| Lₐ₂₄₁ | H | H | H | H | H | H | CD₃ | Ar-1 | H | O |
| Lₐ₂₄₂ | H | H | H | H | H | H | CD₃ | Ar-15 | H | O |
| Lₐ₂₄₃ | H | H | H | H | H | H | CD₃ | Ar-31 | H | O |
| Lₐ₂₄₄ | H | H | H | H | H | H | CD₃ | Ar-34 | H | O |
| Lₐ₂₄₅ | H | H | H | H | H | H | CD₃ | Ar-68 | H | O |
| Lₐ₂₄₆ | H | H | H | H | H | H | CD₃ | Ar-76 | H | O |
| Lₐ₂₄₇ | H | H | H | H | H | H | CD₃ | Ar-77 | H | O |
| Lₐ₂₄₈ | H | H | H | H | H | H | CD₃ | Ar-78 | H | O |
| Lₐ₂₄₉ | H | H | H | H | H | H | CD₃ | Ar-83 | H | O |
| Lₐ₂₅₀ | H | H | H | H | H | H | CD₃ | Ar-85 | H | O |
| Lₐ₂₅₁ | P2 | H | H | H | H | H | CD₃ | Ar-1 | H | O |
| Lₐ₂₅₂ | P2 | H | H | H | H | H | CD₃ | Ar-15 | H | O |
| Lₐ₂₅₃ | P2 | H | H | H | H | H | CD₃ | Ar-31 | H | O |
| Lₐ₂₅₄ | P2 | H | H | H | H | H | CD₃ | Ar-34 | H | O |
| Lₐ₂₅₅ | P2 | H | H | H | H | H | CD₃ | Ar-68 | H | O |
| Lₐ₂₅₆ | P2 | H | H | H | H | H | CD₃ | Ar-76 | H | O |
| Lₐ₂₅₇ | P2 | H | H | H | H | H | CD₃ | Ar-77 | H | O |
| Lₐ₂₅₈ | P2 | H | H | H | H | H | CD₃ | Ar-78 | H | O |
| Lₐ₂₅₉ | P2 | H | H | H | H | H | CD₃ | Ar-83 | H | O |
| Lₐ₂₆₀ | P2 | H | H | H | H | H | CD₃ | Ar-85 | H | O |
| Lₐ₂₆₁ | P5 | H | H | H | H | H | CD₃ | Ar-1 | H | O |
| Lₐ₂₆₂ | P5 | H | H | H | H | H | CD₃ | Ar-15 | H | O |
| Lₐ₂₆₃ | P5 | H | H | H | H | H | CD₃ | Ar-31 | H | O |
| Lₐ₂₆₄ | P5 | H | H | H | H | H | CD₃ | Ar-34 | H | O |
| Lₐ₂₆₅ | P5 | H | H | H | H | H | CD₃ | Ar-68 | H | O |
| Lₐ₂₆₆ | P5 | H | H | H | H | H | CD₃ | Ar-76 | H | O |
| Lₐ₂₆₇ | P5 | H | H | H | H | H | CD₃ | Ar-77 | H | O |
| Lₐ₂₆₈ | P5 | H | H | H | H | H | CD₃ | Ar-78 | H | O |
| Lₐ₂₆₉ | P5 | H | H | H | H | H | CD₃ | Ar-83 | H | O |
| Lₐ₂₇₀ | P5 | H | H | H | H | H | CD₃ | Ar-85 | H | O |
| Lₐ₂₇₁ | P8 | H | H | H | H | H | CD₃ | Ar-1 | H | O |
| Lₐ₂₇₂ | P8 | H | H | H | H | H | CD₃ | Ar-15 | H | O |
| Lₐ₂₇₃ | P8 | H | H | H | H | H | CD₃ | Ar-31 | H | O |
| Lₐ₂₇₄ | P8 | H | H | H | H | H | CD₃ | Ar-34 | H | O |
| Lₐ₂₇₅ | P8 | H | H | H | H | H | CD₃ | Ar-68 | H | O |
| Lₐ₂₇₆ | P8 | H | H | H | H | H | CD₃ | Ar-76 | H | O |
| Lₐ₂₇₇ | P8 | H | H | H | H | H | CD₃ | Ar-77 | H | O |
| Lₐ₂₇₈ | P8 | H | H | H | H | H | CD₃ | Ar-78 | H | O |
| Lₐ₂₇₉ | P8 | H | H | H | H | H | CD₃ | Ar-83 | H | O |
| Lₐ₂₈₀ | P8 | H | H | H | H | H | CD₃ | Ar-85 | H | O |
| Lₐ₂₈₁ | H | H | H | F | H | H | CD₃ | Ar-1 | H | O |
| Lₐ₂₈₂ | H | H | H | F | D | H | CD₃ | Ar-15 | H | O |
| Lₐ₂₈₃ | H | H | H | F | D | H | CD₃ | Ar-31 | H | O |
| Lₐ₂₈₄ | H | H | H | F | D | H | CD₃ | Ar-34 | H | O |
| Lₐ₂₈₅ | H | H | H | F | D | H | CD₃ | Ar-68 | H | O |
| Lₐ₂₈₆ | H | H | H | F | D | H | CD₃ | Ar-76 | H | O |
| Lₐ₂₈₇ | H | H | H | F | D | H | CD₃ | Ar-77 | H | O |
| Lₐ₂₈₈ | H | H | H | F | D | H | CD₃ | Ar-78 | H | O |
| Lₐ₂₈₉ | H | H | H | F | D | H | CD₃ | Ar-83 | H | O |
| Lₐ₂₉₀ | H | H | H | F | D | H | CD₃ | Ar-85 | H | O |
| Lₐ₂₉₁ | P2 | H | H | F | D | H | CD₃ | Ar-1 | H | O |
| Lₐ₂₉₂ | P2 | H | H | F | D | H | CD₃ | Ar-15 | H | O |
| Lₐ₂₉₃ | P2 | H | H | F | D | H | CD₃ | Ar-31 | H | O |
| Lₐ₂₉₄ | P2 | H | H | F | D | H | CD₃ | Ar-34 | H | O |
| Lₐ₂₉₅ | P2 | H | H | F | D | H | CD₃ | Ar-68 | H | O |
| Lₐ₂₉₆ | P2 | H | H | F | D | H | CD₃ | Ar-76 | H | O |
| Lₐ₂₉₇ | P2 | H | H | F | D | H | CD₃ | Ar-77 | H | O |
| Lₐ₂₉₈ | P2 | H | H | F | D | H | CD₃ | Ar-78 | H | O |
| Lₐ₂₉₉ | P2 | H | H | F | D | H | CD₃ | Ar-83 | H | O |
| Lₐ₃₀₀ | P2 | H | H | F | D | H | CD₃ | Ar-85 | H | O |
| Lₐ₃₀₁ | P5 | H | H | F | D | H | CD₃ | Ar-1 | H | O |
| Lₐ₃₀₂ | P5 | H | H | F | D | H | CD₃ | Ar-15 | H | O |
| Lₐ₃₀₃ | P5 | H | H | F | D | H | CD₃ | Ar-31 | H | O |
| Lₐ₃₀₄ | P5 | H | H | F | D | H | CD₃ | Ar-34 | H | O |
| Lₐ₃₀₅ | P5 | H | H | F | D | H | CD₃ | Ar-68 | H | O |
| Lₐ₃₀₆ | P5 | H | H | F | D | H | CD₃ | Ar-76 | H | O |
| Lₐ₃₀₇ | P5 | H | H | F | D | H | CD₃ | Ar-77 | H | O |
| Lₐ₃₀₈ | P5 | H | H | F | D | H | CD₃ | Ar-78 | H | O |
| Lₐ₃₀₉ | P5 | H | H | F | D | H | CD₃ | Ar-83 | H | O |
| Lₐ₃₁₀ | P5 | H | H | F | D | H | CD₃ | Ar-85 | H | O |
| Lₐ₃₁₁ | P8 | H | H | F | D | H | CD₃ | Ar-1 | H | O |
| Lₐ₃₁₂ | P8 | H | H | F | D | H | CD₃ | Ar-15 | H | O |
| Lₐ₃₁₃ | P8 | H | H | F | D | H | CD₃ | Ar-31 | H | O |
| Lₐ₃₁₄ | P8 | H | H | F | D | H | CD₃ | Ar-34 | H | O |
| Lₐ₃₁₅ | P8 | H | H | F | D | H | CD₃ | Ar-68 | H | O |
| Lₐ₃₁₆ | P8 | H | H | F | D | H | CD₃ | Ar-76 | H | O |
| Lₐ₃₁₇ | P8 | H | H | F | D | H | CD₃ | Ar-77 | H | O |
| Lₐ₃₁₈ | P8 | H | H | F | D | H | CD₃ | Ar-78 | H | O |
| Lₐ₃₁₉ | P8 | H | H | F | D | H | CD₃ | Ar-83 | H | O |
| Lₐ₃₂₀ | P8 | H | H | F | D | H | CD₃ | Ar-85 | H | O |
| Lₐ₃₂₁ | H | H | H | CN | D | H | CD₃ | Ar-1 | H | O |
| Lₐ₃₂₂ | H | H | H | CN | D | H | CD₃ | Ar-15 | H | O |
| Lₐ₃₂₃ | H | H | H | CN | D | H | CD₃ | Ar-31 | H | O |
| Lₐ₃₂₄ | H | H | H | CN | D | H | CD₃ | Ar-34 | H | O |
| Lₐ₃₂₅ | H | H | H | CN | D | H | CD₃ | Ar-68 | H | O |
| Lₐ₃₂₆ | H | H | H | CN | D | H | CD₃ | Ar-76 | H | O |
| Lₐ₃₂₇ | H | H | H | CN | D | H | CD₃ | Ar-77 | H | O |
| Lₐ₃₂₈ | H | H | H | CN | D | H | CD₃ | Ar-78 | H | O |
| Lₐ₃₂₉ | H | H | H | CN | D | H | CD₃ | Ar-83 | H | O |
| Lₐ₃₃₀ | H | H | H | CN | D | H | CD₃ | Ar-85 | H | O |
| Lₐ₃₃₁ | P2 | H | H | CN | D | H | CD₃ | Ar-1 | H | O |
| Lₐ₃₃₂ | P2 | H | H | CN | D | H | CD₃ | Ar-15 | H | O |
| Lₐ₃₃₃ | P2 | H | H | CN | D | H | CD₃ | Ar-31 | H | O |
| Lₐ₃₃₄ | P2 | H | H | CN | D | H | CD₃ | Ar-34 | H | O |
| Lₐ₃₃₅ | P2 | H | H | CN | D | H | CD₃ | Ar-68 | H | O |
| Lₐ₃₃₆ | P2 | H | H | CN | D | H | CD₃ | Ar-76 | H | O |
| Lₐ₃₃₇ | P2 | H | H | CN | D | H | CD₃ | Ar-77 | H | O |
| Lₐ₃₃₈ | P2 | H | H | CN | D | H | CD₃ | Ar-78 | H | O |
| Lₐ₃₃₉ | P2 | H | H | CN | D | H | CD₃ | Ar-83 | H | O |
| Lₐ₃₄₀ | P2 | H | H | CN | D | H | CD₃ | Ar-85 | H | O |
| Lₐ₃₄₁ | P5 | H | H | CN | D | H | CD₃ | Ar-1 | H | O |
| Lₐ₃₄₂ | P5 | H | H | CN | D | H | CD₃ | Ar-15 | H | O |
| Lₐ₃₄₃ | P5 | H | H | CN | D | H | CD₃ | Ar-31 | H | O |
| Lₐ₃₄₄ | P5 | H | H | CN | D | H | CD₃ | Ar-34 | H | O |
| Lₐ₃₄₅ | P5 | H | H | CN | D | H | CD₃ | Ar-68 | H | O |
| Lₐ₃₄₆ | P5 | H | H | CN | D | H | CD₃ | Ar-76 | H | O |
| Lₐ₃₄₇ | P5 | H | H | CN | D | H | CD₃ | Ar-77 | H | O |
| Lₐ₃₄₈ | P5 | H | H | CN | D | H | CD₃ | Ar-78 | H | O |
| Lₐ₃₄₉ | P5 | H | H | CN | D | H | CD₃ | Ar-83 | H | O |
| Lₐ₃₅₀ | P5 | H | H | CN | D | H | CD₃ | Ar-85 | H | O |
| Lₐ₃₅₁ | P9 | H | H | CN | D | H | CD₃ | Ar-1 | H | O |
| Lₐ₃₅₂ | P9 | H | H | CN | D | H | CD₃ | Ar-15 | H | O |
| Lₐ₃₅₃ | P9 | H | H | CN | D | H | CD₃ | Ar-31 | H | O |
| Lₐ₃₅₄ | P9 | H | H | CN | D | H | CD₃ | Ar-34 | H | O |
| Lₐ₃₅₅ | P9 | H | H | CN | D | H | CD₃ | Ar-68 | H | O |
| Lₐ₃₅₆ | P9 | H | H | CN | D | H | CD₃ | Ar-76 | H | O |
| Lₐ₃₅₇ | P9 | H | H | CN | D | H | CD₃ | Ar-77 | H | O |
| Lₐ₃₅₈ | P9 | H | H | CN | D | H | CD₃ | Ar-78 | H | O |
| Lₐ₃₅₉ | P9 | H | H | CN | D | H | CD₃ | Ar-83 | H | O |
| Lₐ₃₆₀ | P9 | H | H | CN | D | H | CD₃ | Ar-85 | H | O |
| Lₐ₃₆₁ | H | CN | H | H | H | H | CD₃ | Ar-68 | H | O |
| Lₐ₃₆₂ | H | CN | H | H | H | H | CD₃ | Ar-76 | H | O |
| Lₐ₃₆₃ | H | CN | H | H | H | H | CD₃ | Ar-77 | H | O |
| Lₐ₃₆₄ | H | H | CN | H | H | H | CD₃ | Ar-68 | H | O |
| Lₐ₃₆₅ | H | H | CN | H | H | H | CD₃ | Ar-76 | H | O |
| Lₐ₃₆₆ | H | H | CN | H | H | H | CD₃ | Ar-77 | H | O |
| Lₐ₃₆₇ | H | H | H | H | CN | H | CD₃ | Ar-68 | H | O |
| Lₐ₃₆₈ | H | H | H | H | CN | H | CD₃ | Ar-76 | H | O |
| Lₐ₃₆₉ | H | H | H | H | CN | H | CD₃ | Ar-77 | H | O |
| Lₐ₃₇₀ | H | H | H | H | P10 | H | CD₃ | Ar-68 | H | O |
| Lₐ₃₇₁ | H | H | H | H | P10 | H | CD₃ | Ar-76 | H | O |
| Lₐ₃₇₂ | H | H | H | H | P10 | H | CD₃ | Ar-77 | H | O |
| Lₐ₃₇₃ | H | H | H | H | P11 | H | CD₃ | Ar-68 | H | O |
| Lₐ₃₇₄ | H | H | H | H | P11 | H | CD₃ | Ar-76 | H | O |
| Lₐ₃₇₅ | H | H | H | H | P11 | H | CD₃ | Ar-77 | H | O |
| Lₐ₃₇₆ | H | H | H | H | P12 | H | CD₃ | Ar-68 | H | O |
| Lₐ₃₇₇ | H | H | H | H | P12 | H | CD₃ | Ar-76 | H | O |
| Lₐ₃₇₈ | H | H | H | H | P12 | H | CD₃ | Ar-77 | H | O |
| Lₐ₃₇₉ | H | H | H | H | P13 | H | CD₃ | Ar-68 | H | O |
| Lₐ₃₈₀ | H | H | H | H | P13 | H | CD₃ | Ar-76 | H | O |
| Lₐ₃₈₁ | H | H | H | H | P13 | H | CD₃ | Ar-77 | H | O |
| Lₐ₃₈₂ | H | H | H | H | P14 | H | CD₃ | Ar-68 | H | O |
| Lₐ₃₈₃ | H | H | H | H | P14 | H | CD₃ | Ar-76 | H | O |
| Lₐ₃₈₄ | H | H | H | H | P14 | H | CD₃ | Ar-77 | H | O |
| Lₐ₃₈₅ | H | H | H | H | P15 | H | CD₃ | Ar-68 | H | O |
| Lₐ₃₈₆ | H | H | H | H | P15 | H | CD₃ | Ar-76 | H | O |
| Lₐ₃₈₇ | H | H | H | H | P15 | H | CD₃ | Ar-77 | H | O |
| Lₐ₃₈₈ | H | H | H | H | P16 | H | CD₃ | Ar-68 | H | O |
| Lₐ₃₈₉ | H | H | H | H | P16 | H | CD₃ | Ar-76 | H | O |
| Lₐ₃₉₀ | H | H | H | H | P16 | H | CD₃ | Ar-77 | H | O |
| Lₐ₃₉₁ | H | H | H | H | P17 | H | CD₃ | Ar-68 | H | O |
| Lₐ₃₉₂ | H | H | H | H | P17 | H | CD₃ | Ar-76 | H | O |
| Lₐ₃₉₃ | H | H | H | H | P17 | H | CD₃ | Ar-77 | H | O |
| Lₐ₃₉₄ | H | H | H | H | P18 | H | CD₃ | Ar-68 | H | O |
| Lₐ₃₉₅ | H | H | H | H | P18 | H | CD₃ | Ar-76 | H | O |
| Lₐ₃₉₆ | H | H | H | H | P18 | H | CD₃ | Ar-77 | H | O |
| Lₐ₃₉₇ | H | H | H | H | P19 | H | CD₃ | Ar-68 | H | O |
| Lₐ₃₉₈ | H | H | H | H | P19 | H | CD₃ | Ar-76 | H | O |
| Lₐ₃₉₉ | H | H | H | H | P19 | H | CD₃ | Ar-77 | H | O |
| Lₐ₄₀₀ | H | H | H | H | P20 | H | CD₃ | Ar-68 | H | O |
| Lₐ₄₀₁ | H | H | H | H | P20 | H | CD₃ | Ar-76 | H | O |
| Lₐ₄₀₂ | H | H | H | H | P20 | H | CD₃ | Ar-77 | H | O |
| Lₐ₄₀₃ | H | H | H | CN | P10 | H | CD₃ | Ar-76 | H | O |
| Lₐ₄₀₄ | H | H | H | CN | P11 | H | CD₃ | Ar-76 | H | O |
| Lₐ₄₀₅ | H | H | H | CN | P12 | H | CD₃ | Ar-76 | H | O |
| Lₐ₄₀₆ | H | H | H | CN | P13 | H | CD₃ | Ar-76 | H | O |
| Lₐ₄₀₇ | H | H | H | CN | P14 | H | CD₃ | Ar-76 | H | O |
| Lₐ₄₀₈ | H | H | H | CN | P15 | H | CD₃ | Ar-76 | H | O |
| Lₐ₄₀₉ | H | H | H | CN | P16 | H | CD₃ | Ar-76 | H | O |
| Lₐ₄₁₀ | H | H | H | CN | P17 | H | CD₃ | Ar-76 | H | O |
| Lₐ₄₁₁ | H | H | H | CN | P18 | H | CD₃ | Ar-76 | H | O |
| Lₐ₄₁₂ | H | H | H | CN | P19 | H | CD₃ | Ar-76 | H | O |
| Lₐ₄₁₃ | H | H | H | CN | P20 | H | CD₃ | Ar-76 | H | O |
| Lₐ₄₁₄ | H | H | H | F | P10 | H | CD₃ | Ar-76 | H | O |
| Lₐ₄₁₅ | H | H | H | F | P11 | H | CD₃ | Ar-76 | H | O |
| Lₐ₄₁₆ | H | H | H | F | P12 | H | CD₃ | Ar-76 | H | O |
| Lₐ₄₁₇ | H | H | H | F | P13 | H | CD₃ | Ar-76 | H | O |
| Lₐ₄₁₈ | H | H | H | F | P14 | H | CD₃ | Ar-76 | H | O |
| Lₐ₄₁₉ | H | H | H | F | P15 | H | CD₃ | Ar-76 | H | O |
| Lₐ₄₂₀ | H | H | H | F | P16 | H | CD₃ | Ar-76 | H | O |
| Lₐ₄₂₁ | H | H | H | F | P17 | H | CD₃ | Ar-76 | H | O |
| Lₐ₄₂₂ | H | H | H | F | P18 | H | CD₃ | Ar-76 | H | O |
| Lₐ₄₂₃ | H | H | H | F | P19 | H | CD₃ | Ar-76 | H | O |
| Lₐ₄₂₄ | H | H | H | F | P20 | H | CD₃ | Ar-76 | H | O |
| Lₐ₄₂₅ | P5 | H | H | CN | P10 | H | CD₃ | Ar-76 | H | O |
| Lₐ₄₂₆ | P5 | H | H | CN | P11 | H | CD₃ | Ar-76 | H | O |
| Lₐ₄₂₇ | P5 | H | H | CN | P12 | H | CD₃ | Ar-76 | H | O |
| Lₐ₄₂₈ | P5 | H | H | CN | P13 | H | CD₃ | Ar-76 | H | O |
| Lₐ₄₂₉ | P5 | H | H | CN | P14 | H | CD₃ | Ar-76 | H | O |
| Lₐ₄₃₀ | P5 | H | H | CN | P15 | H | CD₃ | Ar-76 | H | O |
| Lₐ₄₃₁ | P5 | H | H | CN | P16 | H | CD₃ | Ar-76 | H | O |
| Lₐ₄₃₂ | P5 | H | H | CN | P17 | H | CD₃ | Ar-76 | H | O |
| Lₐ₄₃₃ | P5 | H | H | CN | P18 | H | CD₃ | Ar-76 | H | O |
| Lₐ₄₃₄ | P5 | H | H | CN | P19 | H | CD₃ | Ar-76 | H | O |
| Lₐ₄₃₅ | P5 | H | H | CN | P20 | H | CD₃ | Ar-76 | H | O |
| Lₐ₄₃₆ | P9 | H | H | CN | PIC | H | CD₃ | Ar-76 | H | O |
| Lₐ₄₃₇ | P9 | H | H | CN | P11 | H | CD₃ | Ar-76 | H | O |
| Lₐ₄₃₈ | P9 | H | H | CN | P12 | H | CD₃ | Ar-76 | H | O |
| Lₐ₄₃₉ | P9 | H | H | CN | P13 | H | CD₃ | Ar-76 | H | O |
| Lₐ₄₄₀ | P9 | H | H | CN | P14 | H | CD₃ | Ar-76 | H | O |
| Lₐ₄₄₁ | P9 | H | H | CN | P15 | H | CD₃ | Ar-76 | H | O |
| Lₐ₄₄₂ | P9 | H | H | CN | P16 | H | CD₃ | Ar-76 | H | O |
| Lₐ₄₄₃ | P9 | H | H | CN | P17 | H | CD₃ | Ar-76 | H | O |
| Lₐ₄₄₄ | P9 | H | H | CN | P18 | H | CD₃ | Ar-76 | H | O |
| Lₐ₄₄₅ | P9 | H | H | CN | P19 | H | CD₃ | Ar-76 | H | O |
| Lₐ₄₄₆ | P9 | H | H | CN | P20 | H | CD₃ | Ar-76 | H | O |
| Lₐ₄₄₇ | P1 | H | H | CN | D | H | CD₃ | Ar-76 | H | O |
| Lₐ₄₄₈ | P3 | H | H | CN | D | H | CD₃ | Ar-76 | H | O |
| Lₐ₄₄₉ | P4 | H | H | CN | D | H | CD₃ | Ar-76 | H | O |
| Lₐ₄₅₀ | P6 | H | H | CN | D | H | CD₃ | Ar-76 | H | O |
| Lₐ₄₅₁ | P7 | H | H | CN | D | H | CD₃ | Ar-76 | H | O |
| Lₐ₄₅₂ | D | H | H | CN | D | H | CD₃ | Ar-76 | H | O |
| Lₐ₄₅₃ | H | H | H | CN | D | D | CD₃ | Ar-76 | H | O |
| Lₐ₄₅₄ | H | H | H | CN | D | H | CD₃ | Ar-76 | D | O |
| Lₐ₄₅₅ | H | H | H | CN | D | H | CD₃ | Ar-76 | D | O |
| Lₐ₄₅₆ | H | H | H | H | H | H | CD₃ | Ar-76 | H | S |
| Lₐ₄₅₇ | H | H | H | CN | D | H | CD₃ | Ar-76 | H | S |
| Lₐ₄₅₈ | P2 | H | H | CN | D | H | CD₃ | Ar-76 | H | S |
| Lₐ₄₅₉ | P5 | H | H | CN | D | H | CD₃ | Ar-76 | H | S |
| Lₐ₄₆₀ | P9 | H | H | CN | D | H | CD₃ | Ar-76 | H | S |

Lₐ₄₆₁ to Lₐ₅₂₅ have the following structure: 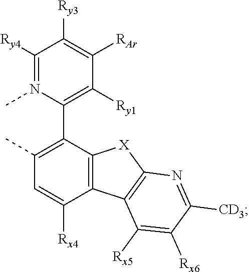
Rₓ₄ to Rₓ₆, R_{y1}, R_{y3}, R_{y4}, R_{Ar} and X are selected from the atoms or the groups in the following table, respectively;

| Lₐ | Rₓ₄ | Rₓ₅ | Rₓ₆ | R_{y1} | R_{Ar} | R_{y3} | R_{y4} | X |
|---|---|---|---|---|---|---|---|---|
| Lₐ₄₆₁ | H | H | H | H | Ar-1 | CD₃ | H | O |
| Lₐ₄₆₂ | H | H | H | H | Ar-15 | CD₃ | H | O |
| Lₐ₄₆₃ | H | H | H | H | Ar-31 | CD₃ | H | O |
| Lₐ₄₆₄ | H | H | H | H | Ar-34 | CD₃ | H | O |
| Lₐ₄₆₅ | H | H | H | H | Ar-68 | CD₃ | H | O |
| Lₐ₄₆₆ | H | H | H | H | Ar-76 | CD₃ | H | O |
| Lₐ₄₆₇ | H | H | H | H | Ar-77 | CD₃ | H | O |
| Lₐ₄₆₈ | H | H | H | H | Ar-78 | CD₃ | H | O |
| Lₐ₄₆₉ | H | H | H | H | Ar-83 | CD₃ | H | O |
| Lₐ₄₇₀ | H | H | H | H | Ar-85 | CD₃ | H | O |
| Lₐ₄₇₁ | P2 | H | H | H | Ar-1 | CD₃ | H | O |
| Lₐ₄₇₂ | P2 | H | H | H | Ar-15 | CD₃ | H | O |
| Lₐ₄₇₃ | P2 | H | H | H | Ar-31 | CD₃ | H | O |
| Lₐ₄₇₄ | P2 | H | H | H | Ar-34 | CD₃ | H | O |
| Lₐ₄₇₅ | P2 | H | H | H | Ar-68 | CD₃ | H | O |
| Lₐ₄₇₆ | P2 | H | H | H | Ar-76 | CD₃ | H | O |
| Lₐ₄₇₇ | P2 | H | H | H | Ar-77 | CD₃ | H | O |
| Lₐ₄₇₈ | P2 | H | H | H | Ar-78 | CD₃ | H | O |
| Lₐ₄₇₉ | P2 | H | H | H | Ar-83 | CD₃ | H | O |
| Lₐ₄₈₀ | P2 | H | H | H | Ar-85 | CD₃ | H | O |
| Lₐ₄₈₁ | P4 | H | H | H | Ar-1 | CD₃ | H | O |
| Lₐ₄₈₂ | P4 | H | H | H | Ar-15 | CD₃ | H | O |
| Lₐ₄₈₃ | P4 | H | H | H | Ar-31 | CD₃ | H | O |
| Lₐ₄₈₄ | P4 | H | H | H | Ar-34 | CD₃ | H | O |
| Lₐ₄₈₅ | P4 | H | H | H | Ar-68 | CD₃ | H | O |
| Lₐ₄₈₆ | P4 | H | H | H | Ar-76 | CD₃ | H | O |
| Lₐ₄₈₇ | P4 | H | H | H | Ar-77 | CD₃ | H | O |
| Lₐ₄₈₈ | P4 | H | H | H | Ar-78 | CD₃ | H | O |
| Lₐ₄₈₉ | P4 | H | H | H | Ar-83 | CD₃ | H | O |
| Lₐ₄₉₀ | P4 | H | H | H | Ar-85 | CD₃ | H | O |
| Lₐ₄₉₁ | P5 | H | H | H | Ar-1 | CD₃ | H | O |
| Lₐ₄₉₂ | P5 | H | H | H | Ar-15 | CD₃ | H | O |
| Lₐ₄₉₃ | P5 | H | H | H | Ar-31 | CD₃ | H | O |
| Lₐ₄₉₄ | P5 | H | H | H | Ar-34 | CD₃ | H | O |
| Lₐ₄₉₅ | P5 | H | H | H | Ar-68 | CD₃ | H | O |
| Lₐ₄₉₆ | P5 | H | H | H | Ar-76 | CD₃ | H | O |
| Lₐ₄₉₇ | P5 | H | H | H | Ar-77 | CD₃ | H | O |
| Lₐ₄₉₈ | P5 | H | H | H | Ar-78 | CD₃ | H | O |
| Lₐ₄₉₉ | P5 | H | H | H | Ar-83 | CD₃ | H | O |
| Lₐ₅₀₀ | P5 | H | H | H | Ar-85 | CD₃ | H | O |
| Lₐ₅₀₁ | P7 | H | H | H | Ar-1 | CD₃ | H | O |
| Lₐ₅₀₂ | P7 | H | H | H | Ar-15 | CD₃ | H | O |
| Lₐ₅₀₃ | P7 | H | H | H | Ar-31 | CD₃ | H | O |
| Lₐ₅₀₄ | P7 | H | H | H | Ar-34 | CD₃ | H | O |
| Lₐ₅₀₅ | P7 | H | H | H | Ar-68 | CD₃ | H | O |
| Lₐ₅₀₆ | P7 | H | H | H | Ar-76 | CD₃ | H | O |
| Lₐ₅₀₇ | P7 | H | H | H | Ar-77 | CD₃ | H | O |
| Lₐ₅₀₈ | P7 | H | H | H | Ar-78 | CD₃ | H | O |
| Lₐ₅₀₉ | P7 | H | H | H | Ar-83 | CD₃ | H | O |
| Lₐ₅₁₀ | P7 | H | H | H | Ar-85 | CD₃ | H | O |
| Lₐ₅₁₁ | P9 | H | H | H | Ar-1 | CD₃ | H | O |
| Lₐ₅₁₂ | P9 | H | H | H | Ar-15 | CD₃ | H | O |
| Lₐ₅₁₃ | P9 | H | H | H | Ar-31 | CD₃ | H | O |
| Lₐ₅₁₄ | P9 | H | H | H | Ar-34 | CD₃ | H | O |
| Lₐ₅₁₅ | P9 | H | H | H | Ar-68 | CD₃ | H | O |
| Lₐ₅₁₆ | P9 | H | H | H | Ar-76 | CD₃ | H | O |
| Lₐ₅₁₇ | P9 | H | H | H | Ar-77 | CD₃ | H | O |
| Lₐ₅₁₈ | P9 | H | H | H | Ar-78 | CD₃ | H | O |
| Lₐ₅₁₉ | P9 | H | H | H | Ar-83 | CD₃ | H | O |
| Lₐ₅₂₀ | P9 | H | H | H | Ar-85 | CD₃ | H | O |
| Lₐ₅₂₁ | H | H | H | D | Ar-76 | CD₃ | D | O |
| Lₐ₅₂₂ | H | H | H | H | Ar-76 | CD₃ | H | S |
| Lₐ₅₂₃ | P2 | H | H | H | Ar-76 | CD₃ | H | S |
| Lₐ₅₂₄ | P5 | H | H | H | Ar-76 | CD₃ | H | S |
| Lₐ₅₂₅ | P9 | H | H | H | Ar-76 | CD₃ | H | S |

Lₐ₅₂₆ to Lₐ₅₉₀ have the following structure: 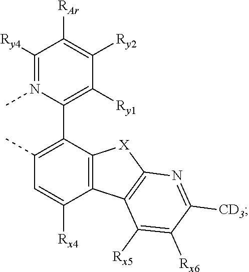
Rₓ₄ to Rₓ₆, R_{y1}, R_{y2}, R_{y4}, R_{Ar} and X are selected from the atoms or the groups in the following table, respectively;

| Lₐ | Rₓ₄ | Rₓ₅ | Rₓ₆ | R_{y1} | R_{y2} | R_{Ar} | R_{y4} | X |
|---|---|---|---|---|---|---|---|---|
| Lₐ₅₂₆ | H | H | H | H | CD₃ | Ar-1 | H | O |
| Lₐ₅₂₇ | H | H | H | H | CD₃ | Ar-15 | H | O |
| Lₐ₅₂₈ | H | H | H | H | CD₃ | Ar-31 | H | O |
| Lₐ₅₂₉ | H | H | H | H | CD₃ | Ar-34 | H | O |
| Lₐ₅₃₀ | H | H | H | H | CD₃ | Ar-68 | H | O |
| Lₐ₅₃₁ | H | H | H | H | CD₃ | Ar-76 | H | O |
| Lₐ₅₃₂ | H | H | H | H | CD₃ | Ar-77 | H | O |
| Lₐ₅₃₃ | H | H | H | H | CD₃ | Ar-78 | H | O |
| Lₐ₅₃₄ | H | H | H | H | CD₃ | Ar-83 | H | O |
| Lₐ₅₃₅ | H | H | H | H | CD₃ | Ar-85 | H | O |
| Lₐ₅₃₆ | P2 | H | H | H | CD₃ | Ar-1 | H | O |
| Lₐ₅₃₇ | P2 | H | H | H | CD₃ | Ar-15 | H | O |
| Lₐ₅₃₈ | P2 | H | H | H | CD₃ | Ar-31 | H | O |
| Lₐ₅₃₉ | P2 | H | H | H | CD₃ | Ar-34 | H | O |
| Lₐ₅₄₀ | P2 | H | H | H | CD₃ | Ar-68 | H | O |
| Lₐ₅₄₁ | P2 | H | H | H | CD₃ | Ar-76 | H | O |
| Lₐ₅₄₂ | P2 | H | H | H | CD₃ | Ar-77 | H | O |
| Lₐ₅₄₃ | P2 | H | H | H | CD₃ | Ar-78 | H | O |
| Lₐ₅₄₄ | P2 | H | H | H | CD₃ | Ar-83 | H | O |
| Lₐ₅₄₅ | P2 | H | H | H | CD₃ | Ar-85 | H | O |
| Lₐ₅₄₆ | P4 | H | H | H | CD₃ | Ar-1 | H | O |
| Lₐ₅₄₇ | P4 | H | H | H | CD₃ | Ar-15 | H | O |
| Lₐ₅₄₈ | P4 | H | H | H | CD₃ | Ar-31 | H | O |
| Lₐ₅₄₉ | P4 | H | H | H | CD₃ | Ar-34 | H | O |
| Lₐ₅₅₀ | P4 | H | H | H | CD₃ | Ar-68 | H | O |
| Lₐ₅₅₁ | P4 | H | H | H | CD₃ | Ar-76 | H | O |
| Lₐ₅₅₂ | P4 | H | H | H | CD₃ | Ar-77 | H | O |
| Lₐ₅₅₃ | P4 | H | H | H | CD₃ | Ar-78 | H | O |
| Lₐ₅₅₄ | P4 | H | H | H | CD₃ | Ar-83 | H | O |
| Lₐ₅₅₅ | P4 | H | H | H | CD₃ | Ar-85 | H | O |
| Lₐ₅₅₆ | P5 | H | H | H | CD₃ | Ar-1 | H | O |
| Lₐ₅₅₇ | P5 | H | H | H | CD₃ | Ar-15 | H | O |
| Lₐ₅₅₈ | P5 | H | H | H | CD₃ | Ar-31 | H | O |
| Lₐ₅₅₉ | P5 | H | H | H | CD₃ | Ar-34 | H | O |
| Lₐ₅₆₀ | P5 | H | H | H | CD₃ | Ar-68 | H | O |
| Lₐ₅₆₁ | P5 | H | H | H | CD₃ | Ar-76 | H | O |
| Lₐ₅₆₂ | P5 | H | H | H | CD₃ | Ar-77 | H | O |
| Lₐ₅₆₃ | P5 | H | H | H | CD₃ | Ar-78 | H | O |
| Lₐ₅₆₄ | P5 | H | H | H | CD₃ | Ar-83 | H | O |
| Lₐ₅₆₅ | P5 | H | H | H | CD₃ | Ar-85 | H | O |
| Lₐ₅₆₆ | P7 | H | H | H | CD₃ | Ar-1 | H | O |
| Lₐ₅₆₇ | P7 | H | H | H | CD₃ | Ar-15 | H | O |
| Lₐ₅₆₈ | P7 | H | H | H | CD₃ | Ar-31 | H | O |
| Lₐ₅₆₉ | P7 | H | H | H | CD₃ | Ar-34 | H | O |
| Lₐ₅₇₀ | P7 | H | H | H | CD₃ | Ar-68 | H | O |
| Lₐ₅₇₁ | P7 | H | H | H | CD₃ | Ar-76 | H | O |
| Lₐ₅₇₂ | P7 | H | H | H | CD₃ | Ar-77 | H | O |
| Lₐ₅₇₃ | P7 | H | H | H | CD₃ | Ar-78 | H | O |
| Lₐ₅₇₄ | P7 | H | H | H | CD₃ | Ar-83 | H | O |
| Lₐ₅₇₅ | P7 | H | H | H | CD₃ | Ar-85 | H | O |
| Lₐ₅₇₆ | P9 | H | H | H | CD₃ | Ar-1 | H | O |
| Lₐ₅₇₇ | P9 | H | H | H | CD₃ | Ar-15 | H | O |
| Lₐ₅₇₈ | P9 | H | H | H | CD₃ | Ar-31 | H | O |
| Lₐ₅₇₉ | P9 | H | H | H | CD₃ | Ar-34 | H | O |
| Lₐ₅₈₀ | P9 | H | H | H | CD₃ | Ar-68 | H | O |
| Lₐ₅₈₁ | P9 | H | H | H | CD₃ | Ar-76 | H | O |
| Lₐ₅₈₂ | P9 | H | H | H | CD₃ | Ar-77 | H | O |
| Lₐ₅₈₃ | P9 | H | H | H | CD₃ | Ar-78 | H | O |
| Lₐ₅₈₄ | P9 | H | H | H | CD₃ | Ar-83 | H | O |
| Lₐ₅₈₅ | P9 | H | H | H | CD₃ | Ar-85 | H | O |
| Lₐ₅₈₆ | H | H | H | D | CD₃ | Ar-76 | D | O |
| Lₐ₅₈₇ | H | H | H | H | CD₃ | Ar-76 | H | S |
| Lₐ₅₈₈ | P2 | H | H | H | CD₃ | Ar-76 | H | S |
| Lₐ₅₈₉ | P5 | H | H | H | CD₃ | Ar-76 | H | S |
| Lₐ₅₉₀ | P9 | H | H | H | CD₃ | Ar-76 | H | S |

wherein P1 to P20 have the following structures: 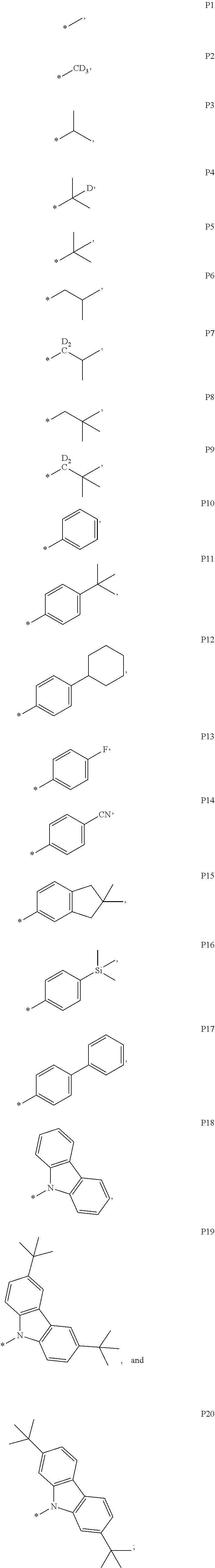
optionally, hydrogen in Lₐ₁ to Lₐ₅₉₀ can be partially or fully substituted with deuterium.

15. The organic electroluminescent device according to claim 14, wherein L_{b} is, at each occurrence identically or differently, selected from the group consisting of L_{b1} to L_{b162}: 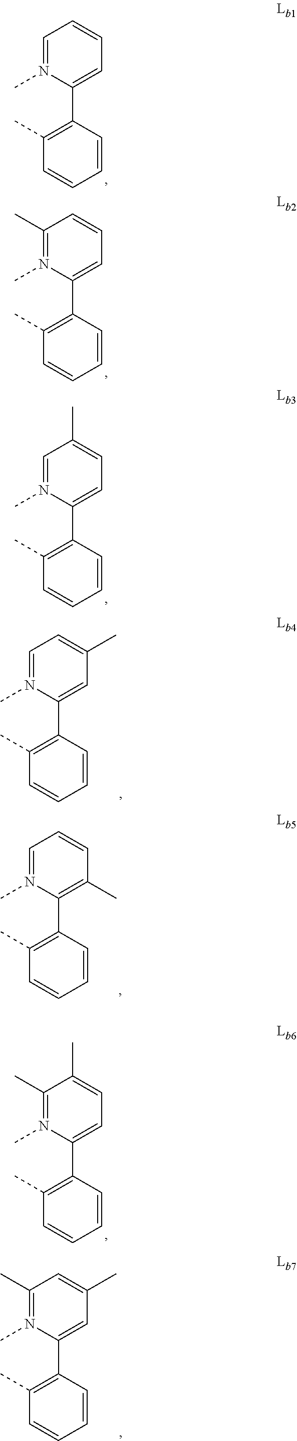 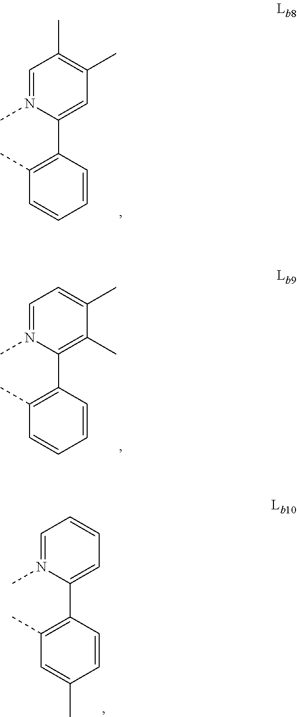 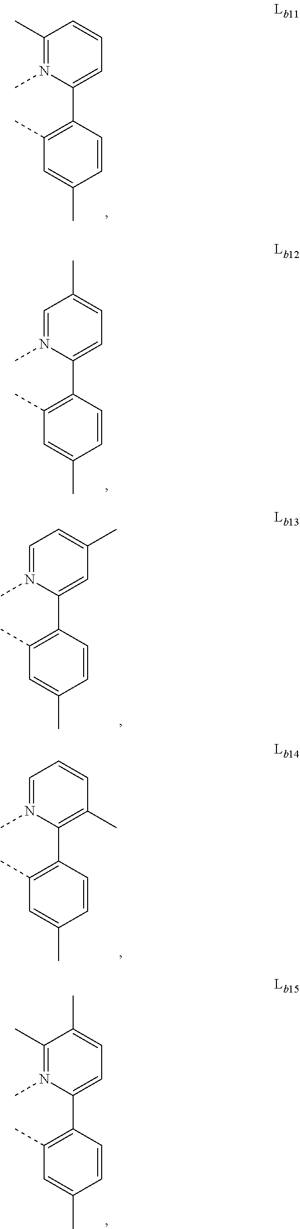 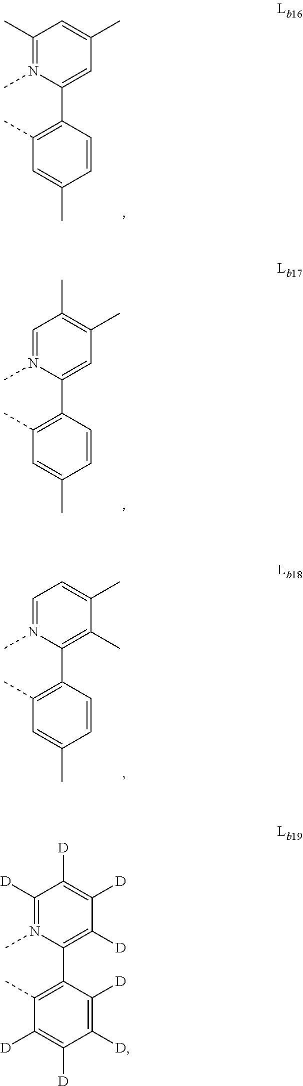 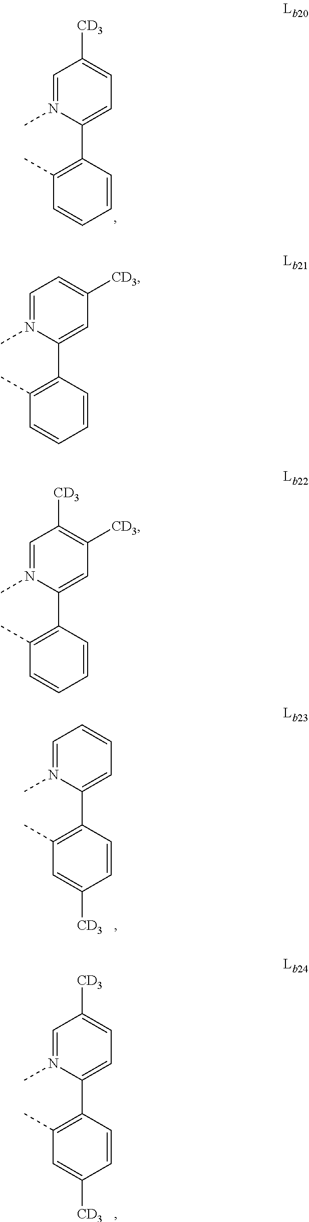 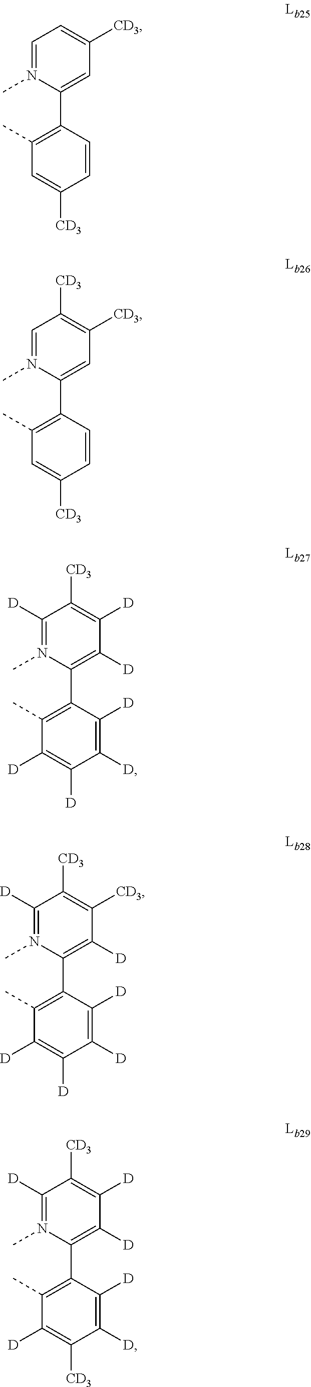 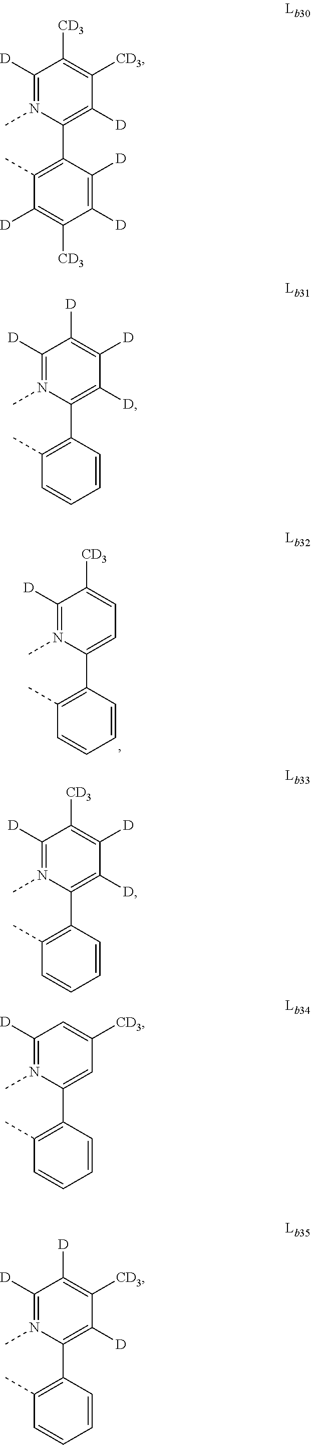 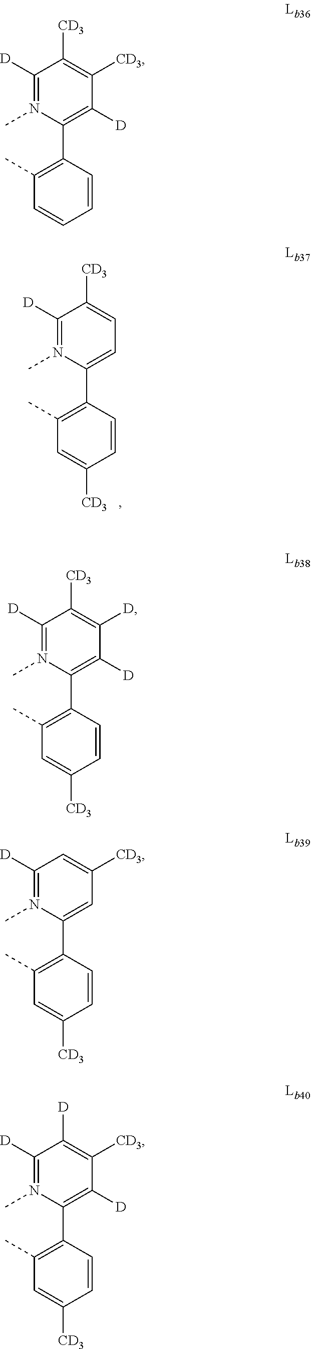 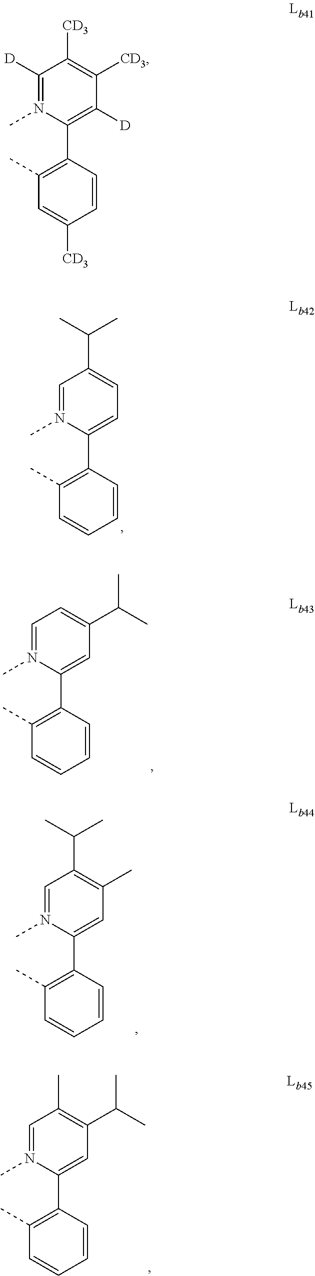 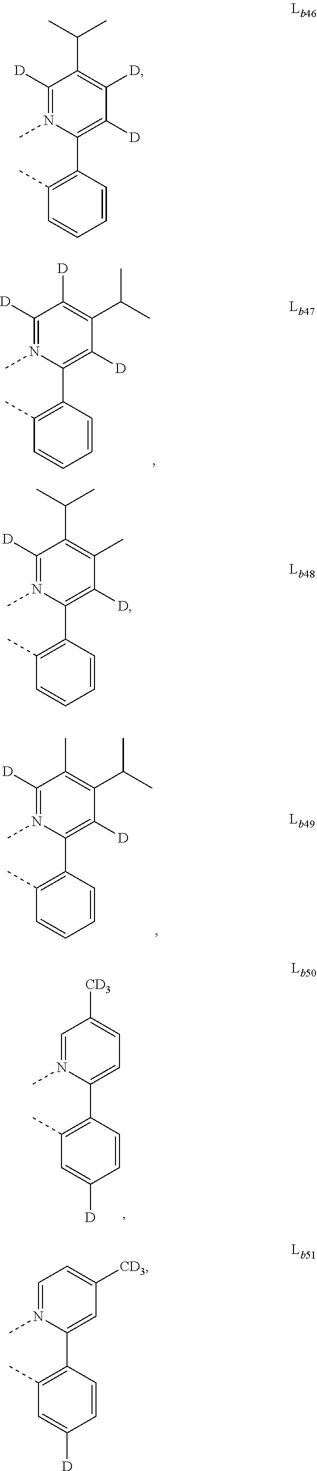 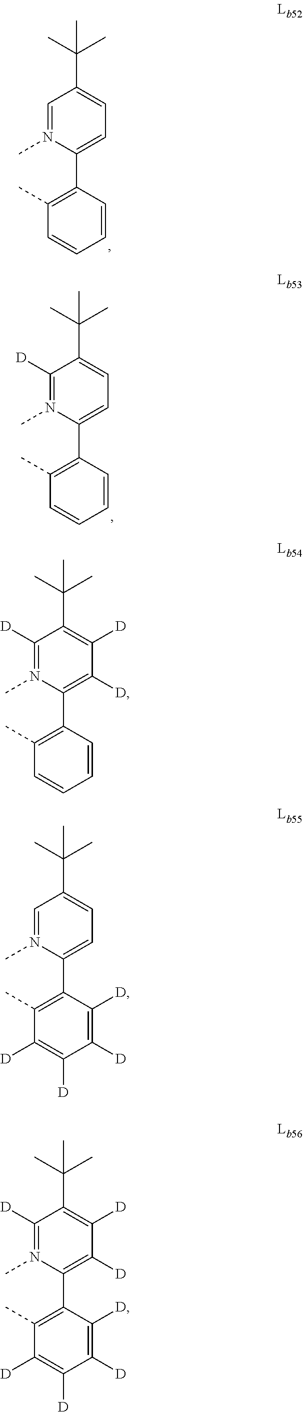 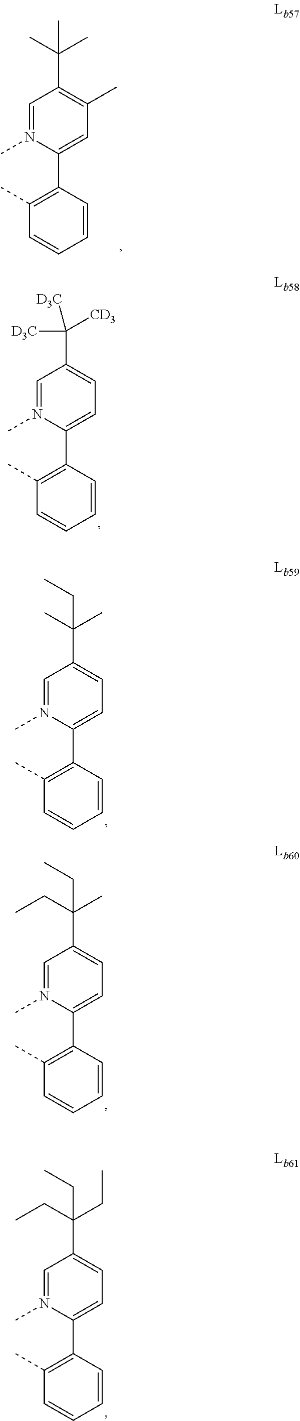 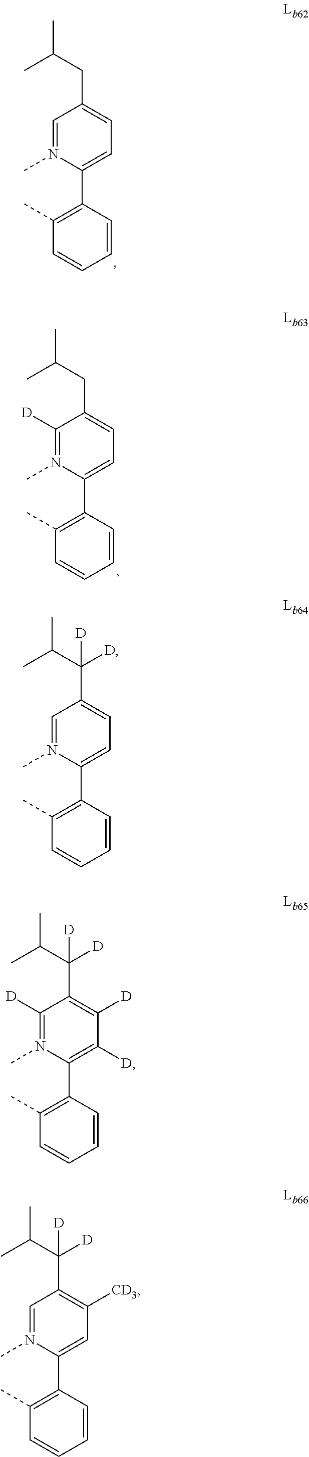 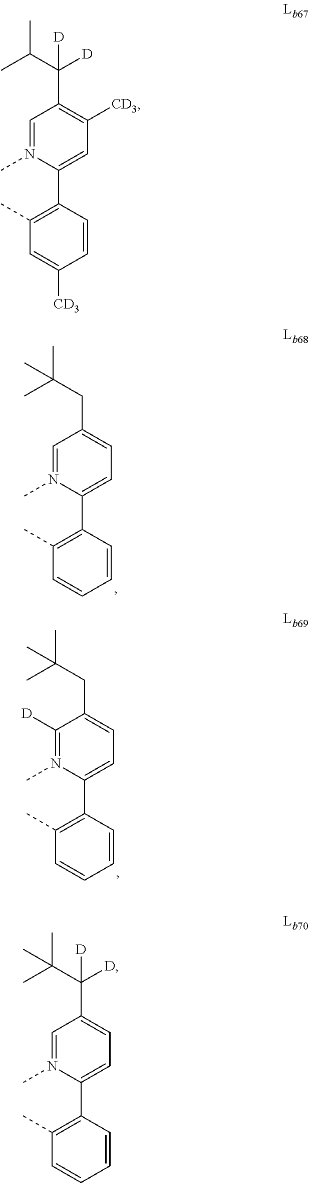 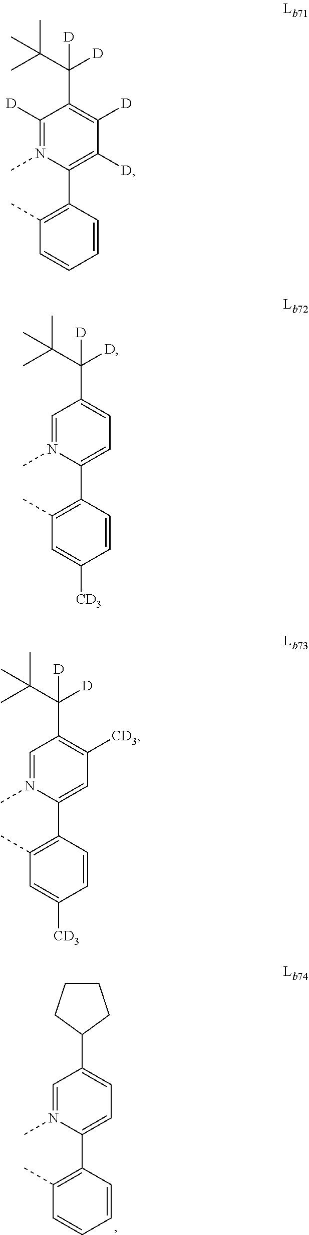 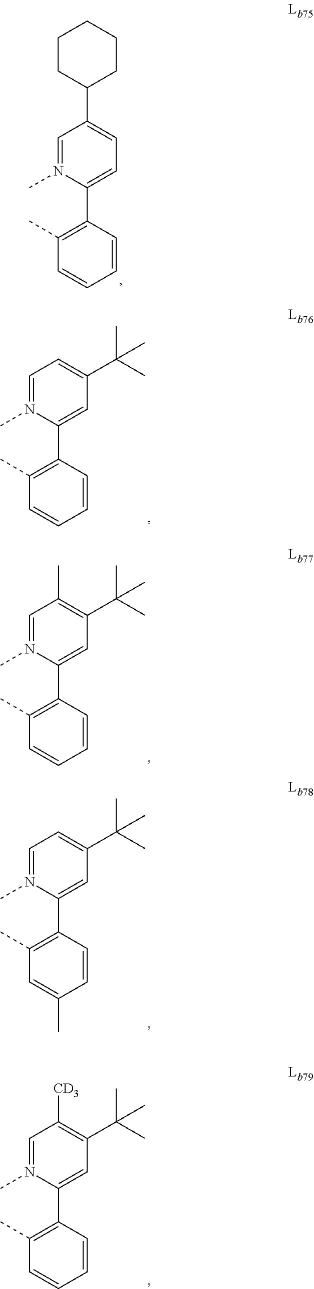 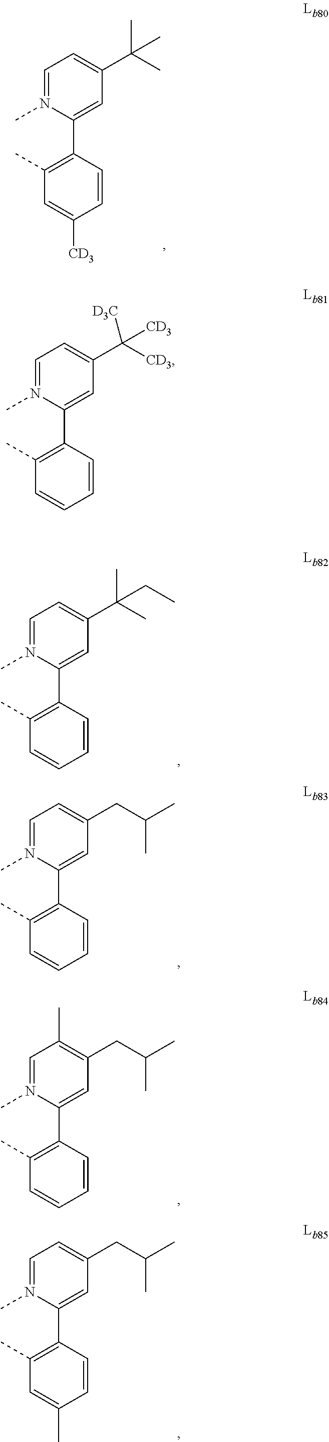 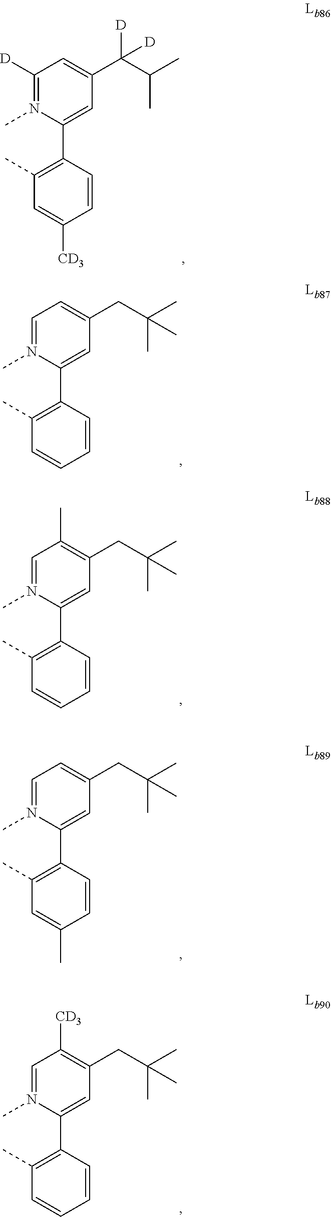 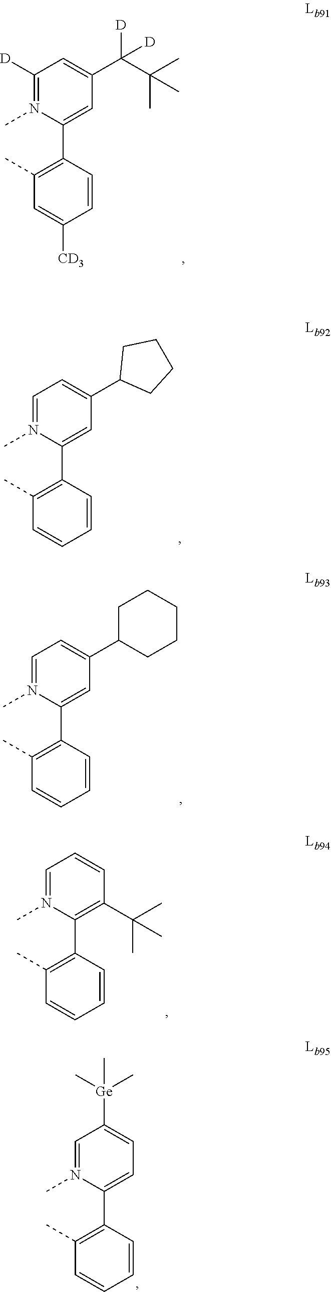 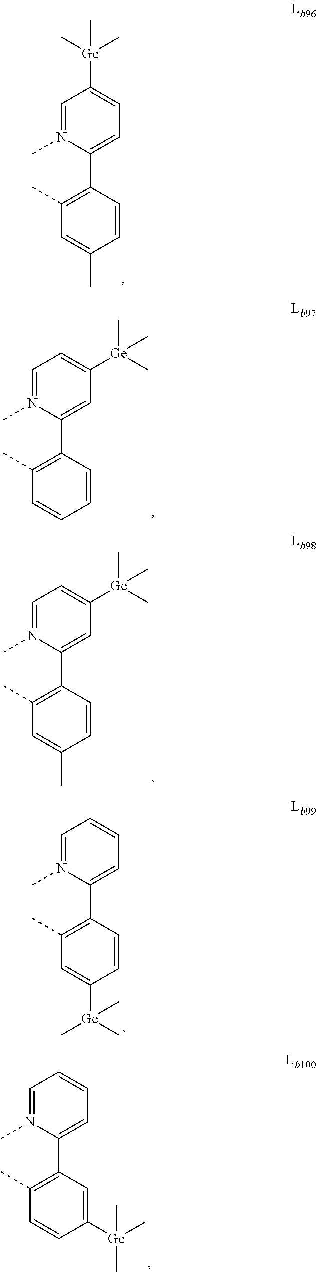 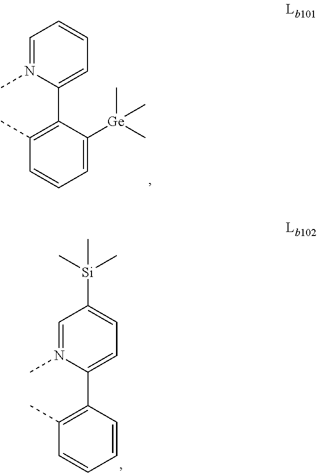 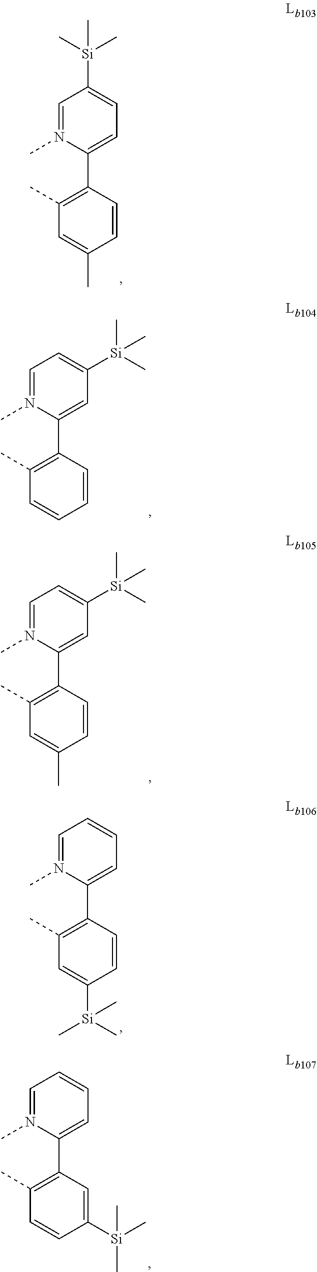 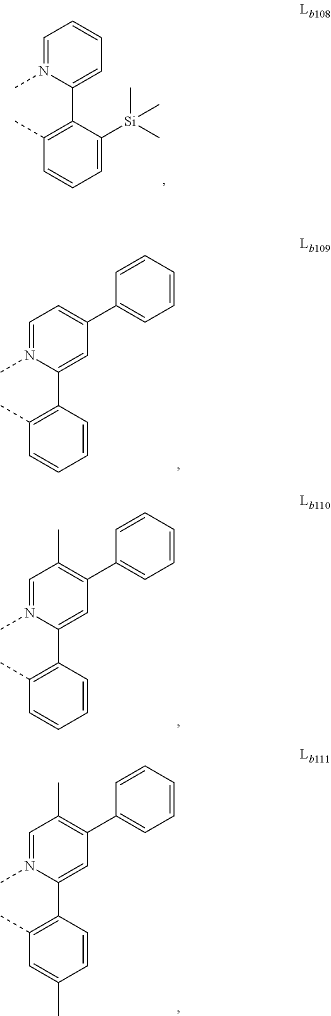 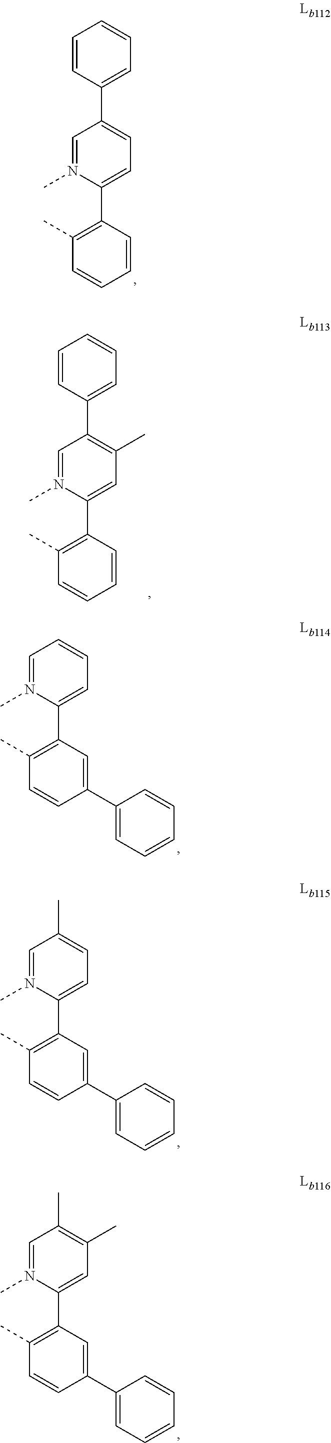 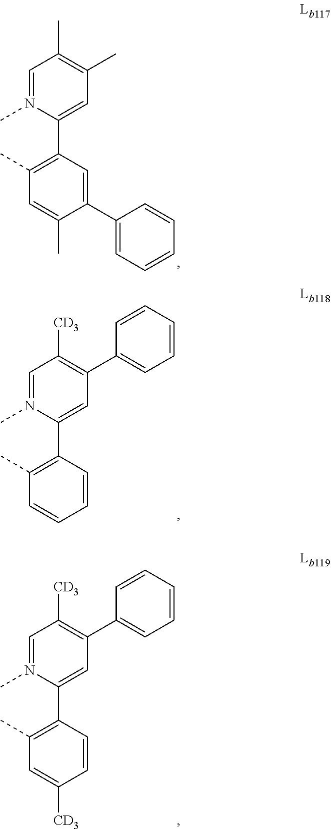 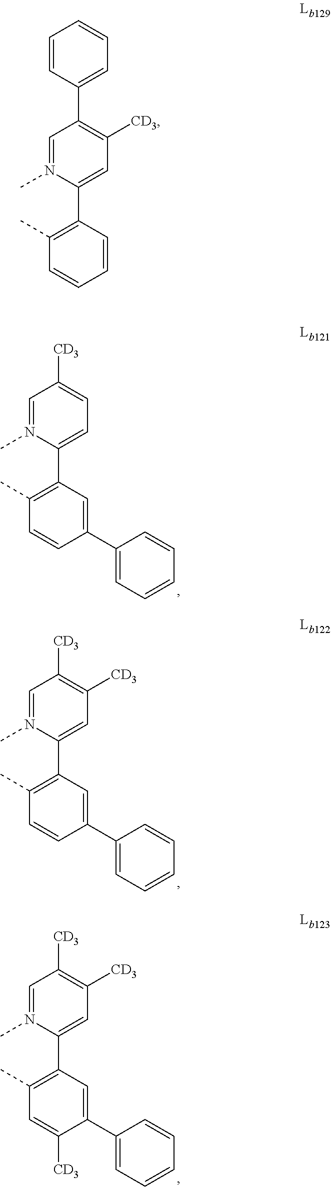 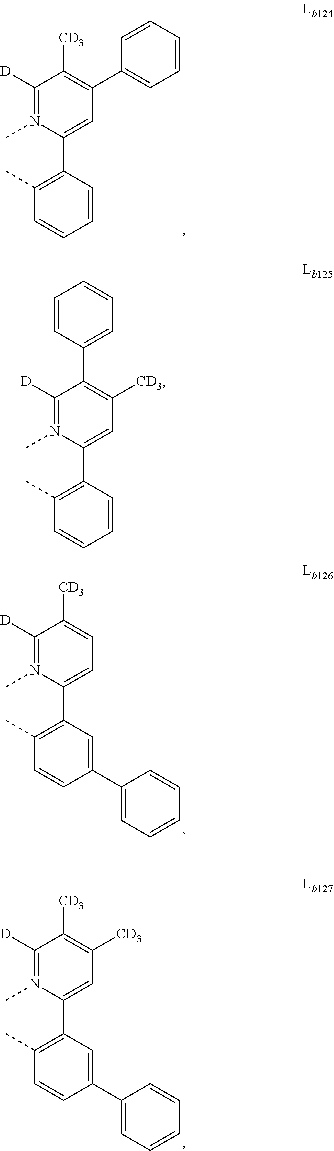 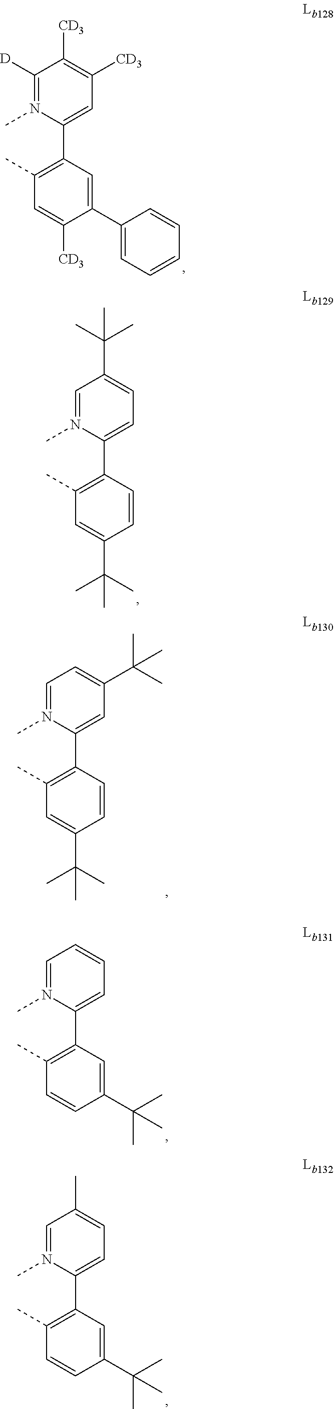 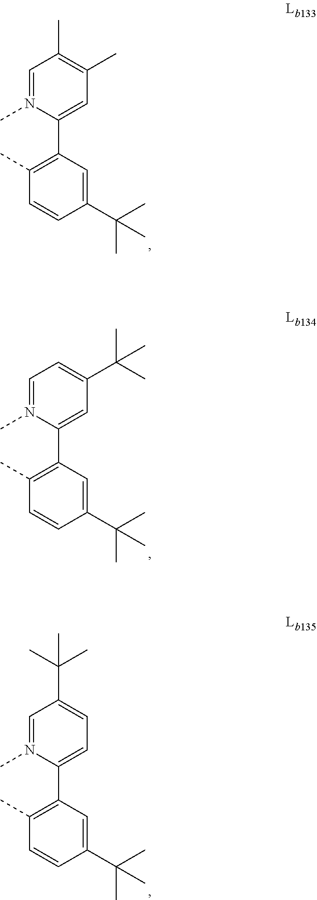 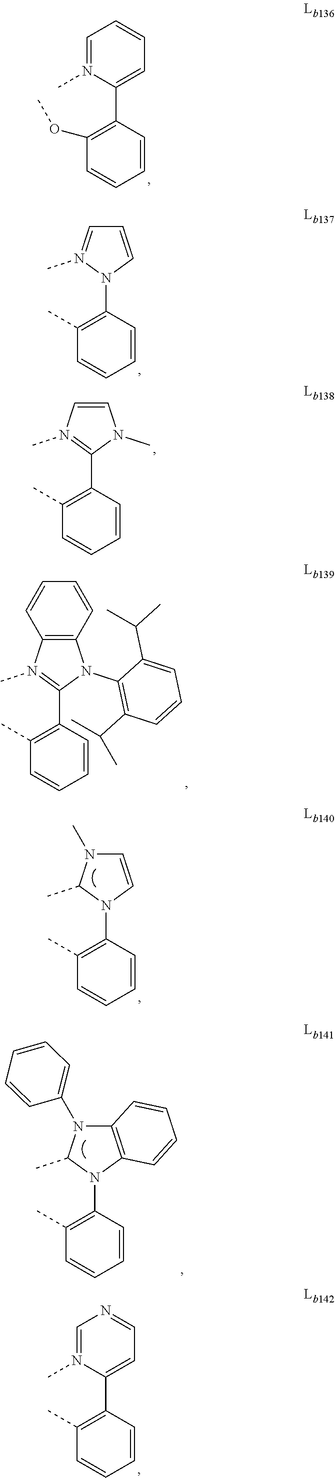 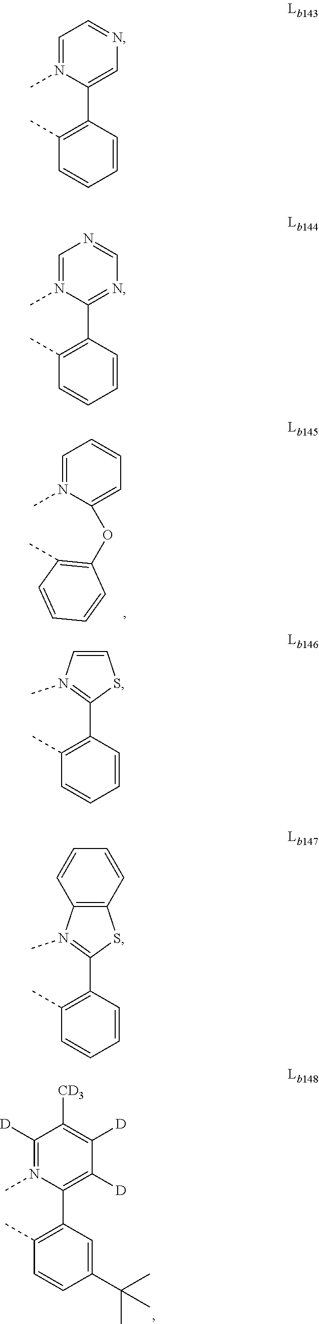 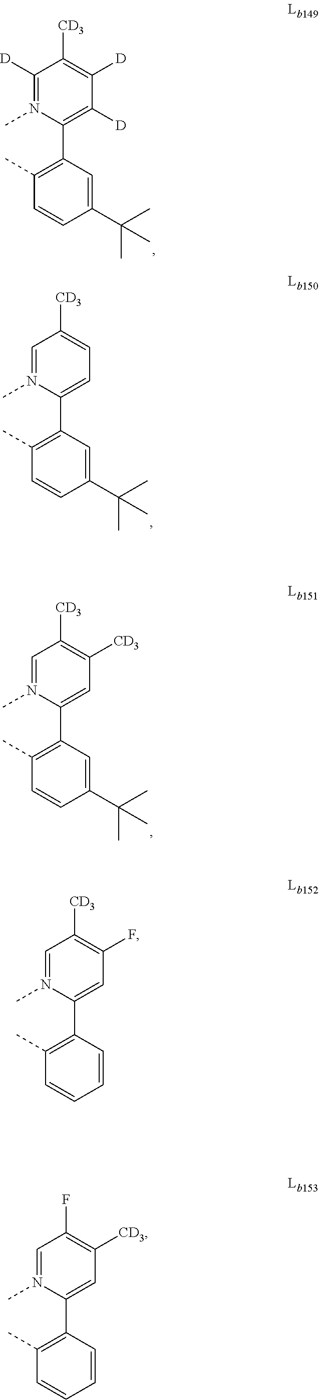 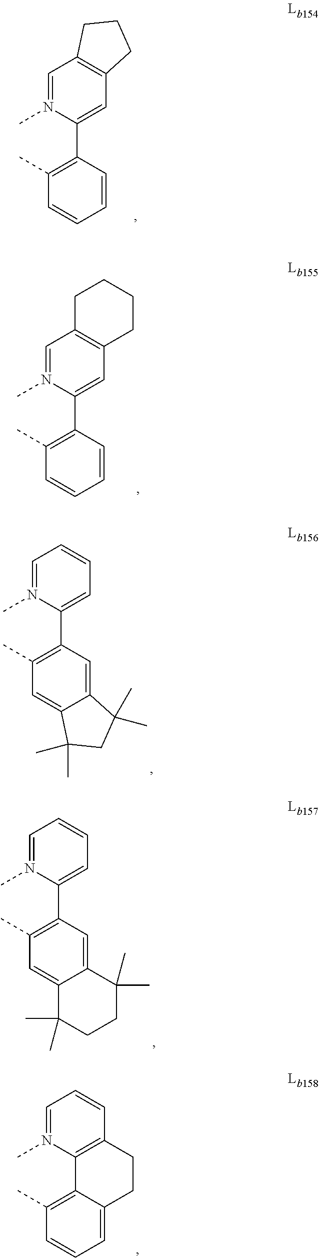 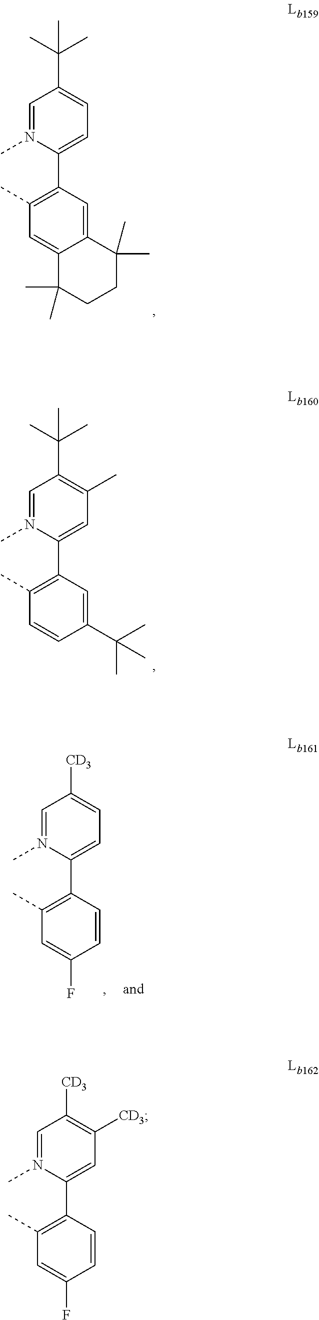
optionally, hydrogen in L_{b1} to L_{b18}, L_{b20} to L_{b26} and L_{b31} to L_{b162} can be partially or fully substituted with deuterium.

16. The organic electroluminescent device according to claim 15, wherein the metal complex has a structure of Ir(Lₐ)(L_{b})₂, wherein the two L_{b} are the same or different, Lₐ is, at each occurrence identically or differently, selected from any one of the group consisting of Lₐ₁ to Lₐ₅₉₀, and L_{b} is, at each occurrence identically or differently, selected from any two of the group consisting of L_{b1} to L_{b162}:
preferably, the metal complex is selected from the group consisting of Metal Complex 1 to Metal Complex 688, and Metal Complex 1 to Metal Complex 688 each have a structure of Ir(Lₐ)(L_{b})₂, wherein the two L_{b} are the same, and Lₐ and L_{b} correspond to the structures in the following table, respectively:

| Metal | | | Metal | | |
|---|---|---|---|---|---|
| Complex | Lₐ | L_{b} | Complex | Lₐ | L_{b} |
| 1 | Lₐ₁₁ | L_{b1} | 2 | Lₐ₁₁ | L_{b3} |
| 3 | Lₐ₁₁ | L_{b8} | 4 | Lₐ₁₁ | L_{b33} |
| 5 | Lₐ₁₁ | L_{b36} | 6 | Lₐ₁₁ | L_{b52} |
| 7 | Lₐ₁₁ | L_{b57} | 8 | Lₐ₁₁ | L_{b123} |
| 9 | Lₐ₁₁ | L_{b132} | 10 | Lₐ₁₁ | L_{b133} |
| 11 | Lₐ₁₁ | L_{b135} | 12 | Lₐ₁₁ | L_{b162} |
| 13 | Lₐ₁₂ | L_{b1} | 14 | Lₐ₁₂ | L_{b3} |
| 15 | Lₐ₁₂ | L_{b8} | 16 | Lₐ₁₂ | L_{b33} |
| 17 | Lₐ₁₂ | L_{b36} | 18 | Lₐ₁₂ | L_{b52} |
| 19 | Lₐ₁₂ | L_{b57} | 20 | Lₐ₁₂ | L_{b123} |
| 21 | Lₐ₁₂ | L_{b132} | 22 | Lₐ₁₂ | L_{b133} |
| 23 | Lₐ₁₂ | L_{b135} | 24 | Lₐ₁₂ | L_{b162} |
| 25 | Lₐ₁₄ | L_{b1} | 26 | Lₐ₁₄ | L_{b3} |
| 27 | Lₐ₁₄ | L_{b8} | 28 | Lₐ₁₄ | L_{b33} |
| 29 | Lₐ₁₄ | Lₐ₃₆ | 30 | Lₐ₁₄ | L_{b52} |
| 31 | Lₐ₁₄ | L_{b57} | 32 | Lₐ₁₄ | L_{b123} |
| 33 | Lₐ₁₄ | L_{b132} | 34 | Lₐ₁₄ | L_{b133} |
| 35 | Lₐ₁₄ | L_{b135} | 36 | Lₐ₁₄ | L_{b162} |
| 37 | Dₐ₁₅ | L_{b1} | 38 | Lₐ₁₅ | L_{b3} |
| 39 | Lₐ₁₅ | L_{b8} | 40 | Lₐ₁₅ | L_{b33} |
| 41 | Lₐ₁₅ | L_{b36} | 42 | Lₐ₁₅ | L_{b52} |
| 43 | Lₐ₁₅ | L_{b57} | 44 | Lₐ₁₅ | L_{b123} |
| 45 | Lₐ₁₅ | L_{b132} | 46 | Lₐ₁₅ | L_{b133} |
| 47 | Lₐ₁₅ | L_{b135} | 48 | Lₐ₁₅ | L_{b162} |
| 49 | Lₐ₁₆ | L_{b1} | 50 | Lₐ₁₆ | L_{b3} |
| 51 | Lₐ₁₆ | L_{b8} | 52 | Lₐ₁₆ | L_{b33} |
| 53 | Lₐ₁₆ | L_{b36} | 54 | Lₐ₁₆ | L_{b52} |
| 55 | Lₐ₁₆ | L_{b57} | 56 | Lₐ₁₆ | L_{b123} |
| 57 | Lₐ₁₆ | L_{b132} | 58 | Lₐ₁₆ | L_{b133} |
| 59 | Lₐ₁₆ | L_{b135} | 60 | Lₐ₁₆ | L_{b162} |
| 61 | Lₐ₁₇ | L_{b1} | 62 | Lₐ₁₇ | L_{b3} |
| 63 | Lₐ₁₇ | L_{b8} | 64 | Lₐ₁₇ | L_{b33} |
| 65 | Lₐ₁₇ | L_{b36} | 66 | Lₐ₁₇ | L_{b52} |
| 67 | Lₐ₁₇ | L_{b57} | 68 | Lₐ₁₇ | L_{b123} |
| 69 | Lₐ₁₇ | L_{b132} | 70 | Lₐ₁₇ | L_{b133} |
| 71 | Lₐ₁₇ | L_{b135} | 72 | Lₐ₁₇ | L_{b162} |
| 73 | Lₐ₃₁ | L_{b1} | 74 | Lₐ₃₁ | L_{b3} |
| 75 | Lₐ₃₁ | L_{b8} | 76 | Lₐ₃₁ | L_{b33} |
| 77 | Lₐ₃₁ | L_{b36} | 78 | Lₐ₃₁ | L_{b52} |
| 79 | Lₐ₃₁ | L_{b57} | 80 | Lₐ₃₁ | L_{b123} |
| 81 | Lₐ₃₁ | L_{b132} | 82 | Lₐ₃₁ | L_{b133} |
| 83 | Lₐ₃₁ | L_{b135} | 84 | Lₐ₃₁ | L_{b162} |
| 85 | Lₐ₃₂ | L_{b1} | 86 | Lₐ₃₂ | L_{b3} |
| 87 | Lₐ₃₂ | L_{b8} | 88 | Lₐ₃₂ | L_{b33} |
| 89 | Lₐ₃₂ | L_{b36} | 90 | Lₐ₃₂ | L_{b52} |
| 91 | Lₐ₃₂ | L_{b57} | 92 | Lₐ₃₂ | L_{b123} |
| 93 | Lₐ₃₂ | L_{b132} | 94 | Lₐ₃₂ | L_{b133} |
| 95 | Lₐ₃₂ | L_{b135} | 96 | Lₐ₃₂ | L_{b162} |
| 97 | Lₐ₃₄ | L_{b1} | 98 | Lₐ₃₄ | L_{b3} |
| 99 | Lₐ₃₄ | L_{b8} | 100 | Lₐ₃₄ | L_{b33} |
| 101 | Lₐ₃₄ | L_{b36} | 102 | Lₐ₃₄ | L_{b52} |
| 103 | Lₐ₃₄ | L_{b57} | 104 | Lₐ₃₄ | L_{b123} |
| 105 | Lₐ₃₄ | L_{b132} | 106 | Lₐ₃₄ | L_{b133} |
| 107 | Lₐ₃₄ | L_{b135} | 108 | Lₐ₃₄ | L_{b162} |
| 109 | Lₐ₃₅ | L_{b1} | 110 | Lₐ₃₅ | L_{b3} |
| 111 | Lₐ₃₅ | L_{b8} | 112 | Lₐ₃₅ | L_{b33} |
| 113 | Lₐ₃₅ | L_{b36} | 114 | Lₐ₃₅ | L_{b52} |
| 115 | Lₐ₃₅ | L_{b57} | 116 | Lₐ₃₅ | L_{b123} |
| 117 | Lₐ₃₅ | L_{b132} | 118 | Lₐ₃₅ | L_{b133} |
| 119 | Lₐ₃₅ | L_{b135} | 120 | Lₐ₃₅ | L_{b162} |
| 121 | Lₐ₃₆ | L_{b1} | 122 | Lₐ₃₆ | L_{b3} |
| 123 | Lₐ₃₆ | L_{b8} | 124 | Lₐ₃₆ | L_{b33} |
| 125 | Lₐ₃₆ | L_{b36} | 126 | Lₐ₃₆ | L_{b52} |
| 127 | Lₐ₃₆ | L_{b57} | 128 | Lₐ₃₆ | L_{b123} |
| 129 | Lₐ₃₆ | L_{b132} | 130 | Lₐ₃₆ | L_{b133} |
| 131 | Lₐ₃₆ | L_{b135} | 132 | Lₐ₃₆ | L_{b162} |
| 133 | Lₐ₃₇ | L_{b1} | 134 | Lₐ₃₇ | L_{b3} |
| 135 | Lₐ₃₇ | L_{b8} | 136 | Lₐ₃₇ | L_{b33} |
| 137 | Lₐ₃₇ | L_{b36} | 138 | Lₐ₃₇ | L_{b52} |
| 139 | Lₐ₃₇ | L_{b57} | 140 | Lₐ₃₇ | L_{b123} |
| 141 | Lₐ₃₇ | L_{b132} | 142 | Lₐ₃₇ | L_{b133} |
| 143 | Lₐ₃₇ | L_{b135} | 144 | Lₐ₃₇ | L_{b162} |
| 145 | Lₐ₉₁ | L_{b1} | 146 | L_{ab1} | L_{b3} |
| 147 | Lₐ₉₁ | L_{b8} | 148 | Lₐ₉₁ | L_{b33} |
| 149 | Lₐ₉₁ | L_{b36} | 150 | Lₐ₉₁ | L_{b52} |
| 151 | Lₐ₉₁ | L_{b57} | 152 | Lₐ₉₁ | L_{b123} |
| 153 | Lₐ₉₁ | L_{b132} | 154 | Lₐ₉₁ | L_{b133} |
| 155 | Lₐ₉₁ | L_{b135} | 156 | Lₐ₉₁ | L_{b162} |
| 157 | Lₐ₉₂ | L_{b1} | 158 | Lₐ₉₂ | L_{b3} |
| 159 | Lₐ₉₂ | L_{b8} | 160 | Lₐ₉₂ | L_{b33} |
| 161 | Lₐ₉₂ | L_{b36} | 162 | Lₐ₉₂ | L_{b52} |
| 163 | Lₐ₉₂ | L_{b57} | 164 | Lₐ₉₂ | L_{b123} |
| 165 | Lₐ₉₂ | L_{b132} | 166 | Lₐ₉₂ | L_{b133} |
| 167 | Lₐ₉₂ | L_{b135} | 168 | Lₐ₉₂ | L_{b162} |
| 169 | Lₐ₉₄ | L_{b1} | 170 | Lₐ₉₄ | L_{b3} |
| 171 | Lₐ₉₄ | L_{b8} | 172 | Lₐ₉₄ | L_{b33} |
| 173 | Lₐ₉₄ | L_{b36} | 174 | Lₐ₉₄ | L_{b52} |
| 175 | Lₐ₉₄ | L_{b57} | 176 | Lₐ₉₄ | L_{b123} |
| 177 | Lₐ₉₄ | L_{b132} | 178 | Lₐ₉₄ | L_{b133} |
| 179 | Lₐ₉₄ | L_{b135} | 180 | Lₐ₉₄ | L_{b162} |
| 181 | Lₐ₉₅ | L_{b1} | 182 | Lₐ₉₅ | L_{b3} |
| 183 | Lₐ₉₅ | L_{b8} | 184 | Lₐ₉₅ | L_{b33} |
| 185 | Lₐ₉₅ | L_{b36} | 186 | Lₐ₉₅ | L_{b52} |
| 187 | Lₐ₉₅ | L_{b57} | 188 | Lₐ₉₅ | L_{b123} |
| 189 | Lₐ₉₅ | L_{b132} | 190 | Lₐ₉₅ | L_{b133} |
| 191 | Lₐ₉₅ | L_{b135} | 192 | Lₐ₉₅ | L_{b162} |
| 193 | Lₐ₉₆ | L_{b1} | 194 | Lₐ₉₆ | L_{b3} |
| 195 | Lₐ₉₆ | L_{b8} | 196 | Lₐ₉₆ | L_{b33} |
| 197 | Lₐ₉₆ | L_{b36} | 198 | Lₐ₉₆ | L_{b52} |
| 199 | Lₐ₉₆ | L_{b57} | 200 | Lₐ₉₆ | L_{b123} |
| 201 | Lₐ₉₆ | L_{b132} | 202 | Lₐ₉₆ | L_{b133} |
| 203 | Lₐ₉₆ | L_{b135} | 204 | Lₐ₉₆ | L_{b162} |
| 205 | Lₐ₉₇ | L_{b1} | 206 | Lₐ₉₇ | L_{b3} |
| 207 | Lₐ₉₇ | L_{b8} | 208 | Lₐ₉₇ | L_{b33} |
| 209 | Lₐ₉₇ | L_{b36} | 210 | Lₐ₉₇ | L_{b52} |
| 211 | Lₐ₉₇ | L_{b57} | 212 | Lₐ₉₇ | L_{b123} |
| 213 | Lₐ₉₇ | L_{b132} | 214 | Lₐ₉₇ | L_{b133} |
| 215 | Lₐ₉₇ | L_{b135} | 216 | Lₐ₉₇ | L_{b162} |
| 217 | Lₐ₁₁₁ | L_{b1} | 218 | Lₐ₁₁₁ | L_{b3} |
| 219 | Lₐ₁₁₁ | L_{b8} | 220 | Lₐ₁₁₁ | L_{b33} |
| 221 | Lₐ₁₁₁ | L_{b36} | 222 | Lₐ₁₁₁ | L_{b52} |
| 223 | Lₐ₁₁₁ | L_{b57} | 224 | Lₐ₁₁₁ | L_{b123} |
| 225 | Lₐ₁₁₁ | L_{b132} | 226 | Lₐ₁₁₁ | L_{b133} |
| 227 | Lₐ₁₁₁ | L_{b135} | 228 | Lₐ₁₁₁ | L_{b162} |
| 229 | Lₐ₁₁₂ | L_{b1} | 230 | Lₐ₁₁₂ | L_{b3} |
| 231 | Lₐ₁₁₂ | L_{b8} | 232 | Lₐ₁₁₂ | L_{b33} |
| 233 | Lₐ₁₁₂ | L_{b36} | 234 | Lₐ₁₁₂ | L_{b52} |
| 235 | Lₐ₁₁₂ | L_{b57} | 236 | Lₐ₁₁₂ | L_{b123} |
| 237 | Lₐ₁₁₂ | L_{b132} | 238 | Lₐ₁₁₂ | L_{b133} |
| 239 | Lₐ₁₁₂ | L_{b135} | 240 | Lₐ₁₁₂ | L_{b162} |
| 241 | Lₐ₁₁₄ | L_{b1} | 242 | Lₐ₁₁₄ | L_{b3} |
| 243 | Lₐ₁₁₄ | L_{b8} | 244 | Lₐ₁₁₄ | L_{b3} |
| 245 | Lₐ₁₁₄ | L_{b36} | 246 | Lₐ₁₁₄ | L_{b52} |
| 247 | Lₐ₁₁₄ | L_{b57} | 248 | Lₐ₁₁₄ | L_{b123} |
| 249 | Lₐ₁₁₄ | L_{b132} | 250 | Lₐ₁₁₄ | L_{b133} |
| 251 | Lₐ₁₁₄ | L_{b135} | 252 | Lₐ₁₁₄ | L_{b162} |
| 253 | Lₐ₁₁₅ | L_{b1} | 254 | Lₐ₁₁₅ | L_{b3} |
| 255 | Lₐ₁₁₅ | L_{b8} | 256 | Lₐ₁₁₅ | L_{b33} |
| 257 | Lₐ₁₁₅ | L_{b36} | 258 | Lₐ₁₁₅ | L_{b52} |
| 259 | Lₐ₁₁₅ | L_{b57} | 260 | Lₐ₁₁₅ | L_{b123} |
| 261 | Lₐ₁₁₅ | L_{b132} | 262 | Lₐ₁₁₅ | L_{b133} |
| 263 | Lₐ₁₁₅ | L_{b135} | 264 | Lₐ₁₁₅ | L_{b162} |
| 265 | Lₐ₁₁₆ | L_{b1} | 266 | Lₐ₁₁₆ | L_{b3} |
| 267 | Lₐ₁₁₆ | L_{b8} | 268 | Lₐ₁₁₆ | L_{b33} |
| 269 | Lₐ₁₁₆ | L_{b36} | 270 | Lₐ₁₁₆ | L_{b52} |
| 271 | Lₐ₁₁₆ | L_{b57} | 272 | Lₐ₁₁₆ | L_{b123} |
| 273 | Lₐ₁₁₆ | L_{b132} | 274 | Lₐ₁₁₆ | L_{b133} |
| 275 | Lₐ₁₁₆ | L_{b135} | 276 | Lₐ₁₁₆ | L_{b162} |
| 277 | Lₐ₁₁₇ | L_{b1} | 278 | Lₐ₁₁₇ | L_{b3} |
| 279 | Lₐ₁₁₇ | L_{b8} | 280 | Lₐ₁₁₇ | L_{b33} |
| 281 | Lₐ₁₁₇ | L_{b36} | 282 | Lₐ₁₁₇ | L_{b52} |
| 283 | Lₐ₁₁₇ | L_{b57} | 284 | Lₐ₁₁₇ | L_{b123} |
| 285 | Lₐ₁₁₇ | L_{b132} | 286 | Lₐ₁₁₇ | L_{b133} |
| 287 | Lₐ₁₁₇ | L_{b135} | 288 | Lₐ₁₁₇ | L_{b162} |
| 289 | Lₐ₄₆₁ | L_{b1} | 290 | Lₐ₄₆₁ | L_{b3} |
| 291 | Lₐ₄₆₁ | L_{b8} | 292 | Lₐ₄₆₁ | L_{b33} |
| 293 | Lₐ₄₆₁ | L_{b36} | 294 | Lₐ₄₆₁ | L_{b52} |
| 295 | Lₐ₄₆₁ | L_{b57} | 296 | Lₐ₄₆₁ | L_{b123} |
| 297 | Lₐ₄₆₁ | L_{b132} | 298 | Lₐ₄₆₁ | L_{b133} |
| 299 | Lₐ₄₆₁ | L_{b135} | 300 | Lₐ₄₆₁ | L_{b162} |
| 301 | Lₐ₄₆₂ | L_{b1} | 302 | Lₐ₄₆₂ | L_{b3} |
| 303 | Lₐ₄₆₂ | L_{b8} | 304 | Lₐ₄₆₂ | L_{b33} |
| 305 | Lₐ₄₆₂ | L_{b36} | 306 | Lₐ₄₆₂ | L_{b52} |
| 307 | Lₐ₄₆₂ | L₆₅₇ | 308 | Lₐ₄₆₂ | L_{b123} |
| 309 | Lₐ₄₆₂ | L_{b132} | 310 | Lₐ₄₆₂ | L_{b133} |
| 311 | Lₐ₄₅₂ | L_{b135} | 312 | Lₐ₄₆₂ | L_{b162} |
| 313 | Lₐ₄₆₃ | L_{b1} | 314 | Lₐ₄₆₃ | L_{b3} |
| 315 | Lₐ₄₆₃ | L_{b8} | 316 | Lₐ₄₆₃ | L_{b33} |
| 317 | Lₐ₄₆₃ | L_{b36} | 318 | Lₐ₄₆₃ | L_{b52} |
| 319 | Lₐ₄₆₃ | L_{b57} | 320 | Lₐ₄₆₃ | L_{b123} |
| 321 | Lₐ₄₆₃ | L_{b132} | 322 | Lₐ₄₆₃ | L_{b133} |
| 323 | Lₐ₄₆₃ | L_{b135} | 324 | Lₐ₄₆₃ | L_{b162} |
| 325 | Lₐ₄₆₄ | L_{b1} | 326 | Lₐ₄₆₄ | L_{b3} |
| 327 | Lₐ₄₆₄ | L_{b8} | 328 | Lₐ₄₆₄ | L_{b33} |
| 329 | Lₐ₄₆₄ | L_{b36} | 330 | Lₐ₄₆₄ | L_{b52} |
| 331 | Lₐ₄₆₄ | L_{b57} | 332 | Lₐ₄₆₄ | L_{b123} |
| 333 | Lₐ₄₆₄ | L_{b132} | 334 | Lₐ₄₆₄ | L_{b133} |
| 335 | Lₐ₄₆₄ | L_{b135} | 336 | Lₐ₄₆₄ | L_{b162} |
| 337 | Lₐ₄₆₅ | L_{b1} | 338 | Lₐ₄₆₅ | L_{b3} |
| 339 | Lₐ₄₆₅ | L_{b8} | 340 | Lₐ₄₆₅ | L_{b33} |
| 341 | Lₐ₄₆₅ | L_{b36} | 342 | Lₐ₄₆₅ | L_{b52} |
| 343 | Lₐ₄₆₅ | L_{b57} | 344 | Lₐ₄₆₅ | L_{b123} |
| 345 | Lₐ₄₆₅ | L_{b132} | 346 | Lₐ₄₆₅ | L_{b133} |
| 347 | Lₐ₄₆₅ | L_{b135} | 348 | Lₐ₄₆₅ | L_{b162} |
| 349 | Lₐ₄₆₆ | L_{b1} | 350 | Lₐ₄₆₆ | L_{b3} |
| 351 | Lₐ₄₆₆ | L_{b8} | 352 | Lₐ₄₆₆ | L_{b33} |
| 353 | Lₐ₄₆₆ | L_{b36} | 354 | Lₐ₄₆₆ | L_{b52} |
| 355 | Lₐ₄₆₆ | L_{b57} | 356 | Lₐ₄₆₆ | L_{b123} |
| 357 | Lₐ₄₆₆ | L_{b132} | 358 | Lₐ₄₆₆ | L_{b133} |
| 359 | Lₐ₄₆₆ | L_{b135} | 360 | Lₐ₄₆₆ | L_{b162} |
| 361 | Lₐ₄₆₇ | L_{b1} | 362 | Lₐ₄₆₇ | L_{b3} |
| 363 | Lₐ₄₆₇ | L_{b8} | 364 | Lₐ₄₆₇ | L_{b33} |
| 365 | Lₐ₄₆₇ | L_{b36} | 366 | Lₐ₄₆₇ | L_{b52} |
| 367 | Lₐ₄₆₇ | L_{b57} | 368 | Lₐ₄₆₇ | L_{b123} |
| 369 | Lₐ₄₆₇ | L_{b132} | 370 | Lₐ₄₆₇ | L_{b133} |
| 371 | Lₐ₄₆₇ | L_{b135} | 372 | Lₐ₄₆₇ | L_{b162} |
| 373 | Lₐ₄₆₈ | L_{b1} | 374 | Lₐ₄₆₈ | L_{b3} |
| 375 | Lₐ₄₆₈ | L_{b8} | 376 | Lₐ₄₆₈ | L_{b33} |
| 377 | Lₐ₄₆₈ | L_{b36} | 378 | Lₐ₄₆₈ | L_{b52} |
| 379 | Lₐ₄₆₈ | L₆₅₇ | 380 | Lₐ₄₆₈ | L_{b123} |
| 381 | Lₐ₄₆₈ | L_{b132} | 382 | Lₐ₄₆₈ | L_{b133} |
| 383 | Lₐ₄₅₈ | L_{b135} | 384 | Lₐ₄₆₈ | L_{b162} |
| 385 | Lₐ₄₆₉ | L_{b1} | 386 | Lₐ₄₆₉ | L_{b3} |
| 387 | Lₐ₄₆₉ | L_{b8} | 388 | Lₐ₄₆₉ | L_{b33} |
| 389 | Lₐ₄₆₉ | L_{b36} | 390 | Lₐ₄₆₉ | L_{b52} |
| 391 | Lₐ₄₆₉ | L_{b57} | 392 | Lₐ₄₆₉ | L_{b123} |
| 393 | Lₐ₄₆₉ | L_{b132} | 394 | Lₐ₄₆₉ | L_{b133} |
| 395 | Lₐ₄₆₉ | L_{b135} | 396 | Lₐ₄₆₉ | L_{b162} |
| 397 | Lₐ₄₇₀ | L_{b1} | 398 | Lₐ₄₇₀ | L_{b3} |
| 399 | Lₐ₄₇₀ | L_{b8} | 400 | Lₐ₄₇₀ | L_{b33} |
| 401 | Lₐ₄₇₀ | L_{b36} | 402 | Lₐ₄₇₀ | L_{b52} |
| 403 | Lₐ₄₇₀ | L_{b57} | 404 | Lₐ₄₇₀ | L_{b123} |
| 405 | Lₐ₄₇₀ | L_{b132} | 406 | Lₐ₄₇₀ | L_{b133} |
| 407 | Lₐ₄₇₀ | L_{b135} | 408 | Lₐ₄₇₀ | L_{b162} |
| 409 | Lₐ₄₉₁ | L_{b1} | 410 | Lₐ₄₉₁ | L_{b3} |
| 411 | Lₐ₄₉₁ | L_{b8} | 412 | Lₐ₄₉₁ | L_{b33} |
| 413 | Lₐ₄₉₁ | L_{b36} | 414 | Lₐ₄₉₁ | L_{b52} |
| 415 | Lₐ₄₉₁ | L_{b57} | 416 | Lₐ₄₉₁ | L_{b123} |
| 417 | Lₐ₄₉₁ | L_{b132} | 418 | Lₐ₄₉₁ | L_{b133} |
| 419 | Lₐ₄₉₁ | L_{b135} | 420 | Lₐ₄₉₁ | L_{b162} |
| 421 | Lₐ₄₉₂ | L_{b1} | 422 | Lₐ₄₉₂ | L_{b3} |
| 423 | Lₐ₄₉₂ | L_{b8} | 424 | Lₐ₄₉₂ | L_{b33} |
| 425 | Lₐ₄₉₂ | L_{b36} | 426 | Lₐ₄₉₂ | L_{b52} |
| 427 | Lₐ₄₉₂ | L_{b57} | 428 | Lₐ₄₉₂ | L_{b123} |
| 429 | Lₐ₄₉₂ | L_{b132} | 430 | Lₐ₄₉₂ | L_{b133} |
| 431 | Lₐ₄₉₂ | L_{b135} | 432 | Lₐ₄₉₂ | L_{b162} |
| 433 | Lₐ₄₉₃ | L_{b1} | 434 | Lₐ₄₉₃ | L_{b3} |
| 435 | Lₐ₄₉₃ | L_{b8} | 436 | Lₐ₄₉₃ | L_{b33} |
| 437 | Lₐ₄₉₃ | L_{b36} | 438 | Lₐ₄₉₃ | L_{b52} |
| 439 | Lₐ₄₉₃ | L_{b57} | 440 | Lₐ₄₉₃ | L_{b123} |
| 441 | Lₐ₄₉₃ | L_{b132} | 442 | Lₐ₄₉₃ | L_{b133} |
| 443 | Lₐ₄₉₃ | L_{b135} | 444 | Lₐ₄₉₃ | L_{b162} |
| 445 | Lₐ₄₉₄ | L_{b1} | 446 | Lₐ₄₉₄ | L_{b3} |
| 447 | Lₐ₄₉₄ | L_{b8} | 448 | Lₐ₄₉₄ | L_{b33} |
| 449 | Lₐ₄₉₄ | L_{b36} | 450 | Lₐ₄₉₄ | L_{b52} |
| 451 | Lₐ₄₉₄ | L_{b57} | 452 | Lₐ₄₉₄ | L_{b123} |
| 453 | Lₐ₄₉₄ | L_{b132} | 454 | Lₐ₄₉₄ | L_{b133} |
| 455 | Lₐ₄₉₄ | L_{b135} | 456 | Lₐ₄₉₄ | L_{b162} |
| 457 | Lₐ₄₉₅ | L_{b1} | 458 | Lₐ₄₉₅ | L_{b3} |
| 459 | Lₐ₄₉₅ | L_{b8} | 460 | Lₐ₄₉₅ | L_{b33} |
| 461 | Lₐ₄₉₅ | L_{b36} | 462 | Lₐ₄₉₅ | L_{b52} |
| 463 | Lₐ₄₉₅ | L_{b57} | 464 | Lₐ₄₉₅ | L_{b123} |
| 465 | Lₐ₄₉₅ | L_{b132} | 466 | Lₐ₄₉₅ | L_{b133} |
| 467 | Lₐ₄₉₅ | L_{b135} | 468 | Lₐ₄₉₅ | L_{b162} |
| 469 | Lₐ₄₉₆ | L_{b1} | 470 | Lₐ₄₉₆ | L_{b3} |
| 471 | Lₐ₄₉₆ | L_{b8} | 472 | Lₐ₄₉₆ | L_{b33} |
| 473 | Lₐ₄₉₆ | L_{b36} | 474 | Lₐ₄₉₆ | L_{b52} |
| 475 | Lₐ₄₉₆ | L_{b57} | 476 | Lₐ₄₉₆ | L_{b123} |
| 477 | Lₐ₄₉₆ | L_{b132} | 478 | Lₐ₄₉₆ | L_{b133} |
| 479 | Lₐ₄₉₆ | L_{b135} | 480 | Lₐ₄₉₆ | L_{b162} |
| 481 | Lₐ₄₉₇ | L_{b1} | 482 | Lₐ₄₉₇ | L_{b3} |
| 483 | Lₐ₄₉₇ | L_{b8} | 484 | Lₐ₄₉₇ | L_{b33} |
| 485 | Lₐ₄₉₇ | L_{b36} | 486 | Lₐ₄₉₇ | L_{b52} |
| 487 | Lₐ₄₉₇ | L_{b57} | 488 | Lₐ₄₉₇ | L_{b123} |
| 489 | Lₐ₄₉₇ | L_{b132} | 490 | Lₐ₄₉₇ | L_{b133} |
| 491 | Lₐ₄₉₇ | L_{b135} | 492 | Lₐ₄₉₇ | L_{b162} |
| 493 | Lₐ₄₉₈ | L_{b1} | 494 | Lₐ₄₉₈ | L_{b3} |
| 495 | Lₐ₄₉₈ | L_{b8} | 496 | Lₐ₄₉₈ | L_{b33} |
| 497 | Lₐ₄₉₈ | L_{b36} | 498 | Lₐ₄₉₈ | L_{b52} |
| 499 | Lₐ₄₉₈ | L_{b57} | 500 | Lₐ₄₉₈ | L_{b123} |
| 501 | Lₐ₄₉₈ | L_{b132} | 502 | Lₐ₄₉₈ | L_{b133} |
| 503 | Lₐ₄₉₈ | L_{b135} | 504 | Lₐ₄₉₈ | L_{b162} |
| 505 | Lₐ₄₉₉ | L_{b1} | 506 | Lₐ₄₉₉ | L_{b3} |
| 507 | Lₐ₄₉₉ | L_{b8} | 508 | Lₐ₄₉₉ | L_{b33} |
| 509 | Lₐ₄₉₉ | L_{b36} | 510 | Lₐ₄₉₉ | L_{b52} |
| 511 | Lₐ₄₉₉ | L_{b57} | 512 | Lₐ₄₉₉ | L_{b123} |
| 513 | Lₐ₄₉₉ | L_{b132} | 514 | Lₐ₄₉₉ | L_{b133} |
| 515 | Lₐ₄₉₉ | L_{b135} | 516 | Lₐ₄₉₉ | L_{b162} |
| 517 | Lₐ₅₀₀ | L_{b1} | 518 | Lₐ₅₀₀ | L_{b3} |
| 519 | Lₐ₅₀₀ | L_{b8} | 520 | Lₐ₅₀₀ | L_{b33} |
| 521 | Lₐ₅₀₀ | L_{b36} | 522 | Lₐ₅₀₀ | L_{b52} |
| 523 | Lₐ₅₀₀ | L_{b57} | 524 | Lₐ₅₀₀ | L_{b123} |
| 525 | Lₐ₅₀₀ | L_{b132} | 526 | Lₐ₅₀₀ | L_{b133} |
| 527 | Lₐ₅₀₀ | L_{b135} | 528 | Lₐ₅₀₀ | L_{b162} |
| 529 | Lₐ₄₆₁ | L_{b12} | 530 | Lₐ₄₆₁ | L_{b17} |
| 531 | Lₐ₄₆₁ | L_{b24} | 532 | Lₐ₄₆₁ | L_{b26} |
| 533 | Lₐ₄₆₁ | L_{b64} | 534 | Lₐ₄₆₁ | L_{b70} |
| 535 | Lₐ₄₆₁ | L_{b72} | 536 | Lₐ₄₆₁ | L_{b73} |
| 537 | Lₐ₄₆₂ | L_{b12} | 538 | Lₐ₄₆₂ | L_{b17} |
| 539 | Lₐ₄₆₂ | L_{b24} | 540 | Lₐ₄₆₂ | L_{b26} |
| 541 | Lₐ₄₆₂ | L_{b64} | 542 | Lₐ₄₆₂ | L_{b70} |
| 543 | Lₐ₄₆₂ | L_{b72} | 544 | Lₐ₄₆₂ | L_{b73} |
| 545 | Lₐ₄₆₃ | L_{b12} | 546 | Lₐ₄₆₃ | L_{b17} |
| 547 | Lₐ₄₆₃ | L_{b24} | 548 | Lₐ₄₆₃ | L_{b26} |
| 549 | Lₐ₄₆₃ | L_{b64} | 550 | Lₐ₄₆₃ | L_{b70} |
| 551 | Lₐ₄₆₃ | L_{b72} | 552 | Lₐ₄₆₃ | L_{b73} |
| 553 | Lₐ₄₆₄ | L_{b12} | 554 | Lₐ₄₆₄ | L_{b17} |
| 555 | Lₐ₄₆₄ | L_{b24} | 556 | Lₐ₄₆₄ | L_{b26} |
| 557 | Lₐ₄₆₄ | L_{b64} | 558 | Lₐ₄₆₄ | L_{b70} |
| 559 | Lₐ₄₆₄ | L_{b72} | 560 | Lₐ₄₆₄ | L_{b73} |
| 561 | Lₐ₄₆₅ | L_{b12} | 562 | Lₐ₄₆₅ | L_{b17} |
| 563 | Lₐ₄₆₅ | L_{b24} | 564 | Lₐ₄₆₅ | L_{b26} |
| 565 | Lₐ₄₆₅ | L_{b64} | 566 | Lₐ₄₆₅ | L_{b70} |
| 567 | Lₐ₄₆₅ | L_{b72} | 568 | Lₐ₄₆₅ | L_{b73} |
| 569 | Lₐ₄₆₆ | L_{b12} | 570 | Lₐ₄₆₆ | L_{b17} |
| 571 | Lₐ₄₆₆ | L_{b24} | 572 | Lₐ₄₆₆ | L_{b26} |
| 573 | Lₐ₄₆₆ | L_{b64} | 574 | Lₐ₄₆₆ | L_{b70} |
| 575 | Lₐ₄₆₆ | L_{b72} | 576 | Lₐ₄₆₆ | L_{b73} |
| 577 | Lₐ₄₆₇ | L_{b12} | 578 | Lₐ₄₆₇ | L_{b17} |
| 579 | Lₐ₄₆₇ | L_{b24} | 580 | Lₐ₄₆₇ | L_{b26} |
| 581 | Lₐ₄₆₇ | L_{b64} | 582 | Lₐ₄₆₇ | L_{b70} |
| 583 | Lₐ₄₆₇ | L_{b72} | 584 | Lₐ₄₆₇ | L_{b73} |
| 585 | Lₐ₄₆₈ | L_{b12} | 586 | Lₐ₄₆₈ | L_{b17} |
| 587 | Lₐ₄₆₈ | L_{b24} | 588 | Lₐ₄₆₈ | L_{b26} |
| 589 | Lₐ₄₆₈ | L_{b64} | 590 | Lₐ₄₆₈ | L_{b70} |
| 591 | Lₐ₄₆₈ | L_{b72} | 592 | Lₐ₄₆₈ | L_{b73} |
| 593 | Lₐ₄₆₉ | L_{b12} | 594 | Lₐ₄₆₉ | L_{b17} |
| 595 | Lₐ₄₆₉ | L_{b24} | 596 | Lₐ₄₆₉ | L_{b26} |
| 597 | Lₐ₄₆₉ | L_{b64} | 598 | Lₐ₄₆₉ | L_{b70} |
| 599 | Lₐ₄₆₉ | L_{b72} | 600 | Lₐ₄₆₉ | L_{b73} |
| 601 | Lₐ₄₇₀ | L_{b12} | 602 | Lₐ₄₇₀ | L_{b17} |
| 603 | Lₐ₄₇₀ | L_{b24} | 604 | Lₐ₄₇₀ | L_{b26} |
| 605 | Lₐ₄₇₀ | L_{b64} | 606 | Lₐ₄₇₀ | L_{b70} |
| 607 | Lₐ₄₇₀ | L_{b72} | 608 | Lₐ₄₇₀ | L_{b73} |
| 609 | Lₐ₄₉₁ | L_{b12} | 610 | Lₐ₄₉₁ | L_{b17} |
| 611 | Lₐ₄₉₁ | L_{b24} | 612 | Lₐ₄₉₁ | L_{b26} |
| 613 | Lₐ₄₉₁ | L_{b64} | 614 | Lₐ₄₉₁ | L₆₇₀ |
| 615 | Lₐ₄₉₁ | L_{b72} | 616 | Lₐ₄₉₁ | L_{b73} |
| 617 | Lₐ₄₉₂ | L_{b12} | 618 | Lₐ₄₉₂ | L_{b17} |
| 619 | Lₐ₄₉₂ | L_{b24} | 620 | Lₐ₄₉₂ | L_{b26} |
| 621 | Lₐ₄₉₂ | L_{b64} | 622 | Lₐ₄₉₂ | L_{b70} |
| 623 | Lₐ₄₉₂ | L_{b72} | 624 | Lₐ₄₉₂ | L_{b73} |
| 625 | Lₐ₄₉₃ | L_{b12} | 626 | Lₐ₄₉₃ | L_{b17} |
| 627 | Lₐ₄₉₃ | L_{b24} | 628 | Lₐ₄₉₃ | L_{b26} |
| 629 | Lₐ₄₉₃ | L_{b64} | 630 | Lₐ₄₉₃ | L_{b70} |
| 631 | Lₐ₄₉₃ | L_{b72} | 632 | Lₐ₄₉₃ | L_{b73} |
| 633 | Lₐ₄₉₄ | L_{b12} | 634 | Lₐ₄₉₄ | L_{b17} |
| 635 | Lₐ₄₉₄ | L_{b24} | 636 | Lₐ₄₉₄ | L_{b26} |
| 637 | Lₐ₄₉₄ | L_{b64} | 638 | Lₐ₄₉₄ | L_{b70} |
| 639 | Lₐ₄₉₄ | L_{b72} | 640 | Lₐ₄₉₄ | L_{b73} |
| 641 | Lₐ₄₉₅ | L_{b12} | 642 | Lₐ₄₉₅ | L_{b17} |
| 643 | Lₐ₄₉₅ | L_{b24} | 644 | Lₐ₄₉₅ | L_{b26} |
| 645 | Lₐ₄₉₅ | L_{b64} | 646 | Lₐ₄₉₅ | L_{b70} |
| 647 | Lₐ₄₉₅ | L_{b72} | 648 | Lₐ₄₉₅ | L_{b73} |
| 649 | Lₐ₄₉₆ | L_{b12} | 650 | Lₐ₄₉₆ | L_{b17} |
| 651 | Lₐ₄₉₆ | L_{b24} | 652 | Lₐ₄₉₆ | L_{b26} |
| 653 | Lₐ₄₉₆ | L_{b64} | 654 | Lₐ₄₉₆ | L_{b70} |
| 655 | Lₐ₄₉₆ | L_{b72} | 656 | Lₐ₄₉₆ | L_{b73} |
| 657 | Lₐ₄₉₇ | L_{b12} | 658 | Lₐ₄₉₇ | L_{b17} |
| 659 | Lₐ₄₉₇ | L_{b24} | 660 | Lₐ₄₉₇ | L_{b26} |
| 661 | Lₐ₄₉₇ | L_{b64} | 662 | Lₐ₄₉₇ | L_{b70} |
| 663 | Lₐ₄₉₇ | L_{b72} | 664 | Lₐ₄₉₇ | L_{b73} |
| 665 | Lₐ₄₉₈ | L_{b12} | 666 | Lₐ₄₉₈ | L_{b17} |
| 667 | Lₐ₄₉₈ | L_{b24} | 668 | Lₐ₄₉₈ | L_{b26} |
| 669 | Lₐ₄₉₈ | L_{b64} | 670 | Lₐ₄₉₈ | L_{b70} |
| 671 | Lₐ₄₉₈ | L_{b72} | 672 | Lₐ₄₉₈ | L_{b73} |
| 673 | Lₐ₄₉₉ | L_{b12} | 674 | Lₐ₄₉₉ | L_{b17} |
| 675 | Lₐ₄₉₉ | L_{b24} | 676 | Lₐ₄₉₉ | L_{b26} |
| 677 | Lₐ₄₉₉ | L_{b64} | 678 | Lₐ₄₉₉ | L_{b70} |
| 679 | Lₐ₄₉₉ | L_{b72} | 680 | Lₐ₄₉₉ | L_{b73} |
| 681 | Lₐ₅₀₀ | L_{b12} | 682 | Lₐ₅₀₀ | L_{b17} |
| 683 | Lₐ₅₀₀ | L_{b24} | 684 | Lₐ₅₀₀ | L_{b26} |
| 685 | Lₐ₅₀₀ | L_{b64} | 686 | Lₐ₅₀₀ | L_{b70} |
| 687 | Lₐ₅₀₀ | L_{b72} | 688 | Lₐ₅₀₀ | L_{b73} |

hydrogen in Metal Complex 1 to Metal Complex 688 can be partially or fully substituted with deuterium.

17. The organic electroluminescent device according to claim 1, wherein the fluorescent emissive material has a structure represented by Formula 3: 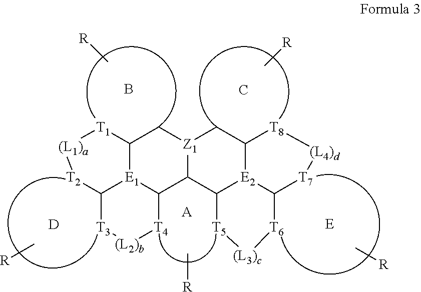
wherein,
the ring A, the ring B, the ring C, the ring D and the ring E are each independently selected from an unsaturated carbocyclic ring having 5 to 30 carbon atoms or an unsaturated heterocyclic ring having 3 to 30 carbon atoms;
Z₁, E₁ and E₂ are each independently selected from B, N, P, P═O, P═S, As, As═O, As═S, SiR_{Si1} or GeR_{Ge1};
T₁ to T₅ are each independently selected from C, CRₜ or N;
a, b, c and d are each independently selected from 0 or 1;
L₁, L₂, L₃ and L₄ are, at each occurrence identically or differently, selected from a single bond, O, S, Se, BR_{L} or NR_{L};
R represents, at each occurrence identically or differently, mono-substitution, multiple substitutions or non-substitution;
R, Rₜ, R_{L}, R_{Si1} and R_{Ge1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R, Rₜ, R_{L}, R_{Si1}, R_{Ge1} and R^{B} can be optionally joined to form a ring.

18. The organic electroluminescent device according to claim 17, wherein the ring A, the ring B, the ring C, the ring D and the ring E are each independently selected from a five-membered unsaturated carbocyclic ring, an aromatic ring having 6 to 30 carbon atoms or a heteroaromatic ring having 3 to 30 carbon atoms;
preferably, the ring A, the ring B, the ring C, the ring D and the ring E are each independently selected from a five-membered unsaturated carbocyclic ring, an aromatic ring having 6 to 18 carbon atoms or a heteroaromatic ring having 3 to 18 carbon atoms;
more preferably, the ring A, the ring B, the ring C, the ring D and the ring E are each independently selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring or a combination thereof; and
more preferably, the ring A, the ring B, the ring C, the ring D and the ring E are selected from a benzene ring.

19. The organic electroluminescent device according to claim 17, wherein Z₁ is selected from B, P═O or P═S, and E₁ and E₂ are each independently selected from N or P; and
preferably, Z₁ is selected from B, and E₁ and E₂ are selected from N.

20. The organic electroluminescent device according to claim 17, wherein L₁, L₂, L₃ and L₄ are, at each occurrence identically or differently, selected from a single bond, O, BR_{L} or NR_{L}.

21. The organic electroluminescent device according to claim 17, wherein a+b+c+d is greater than or equal to 1:
preferably, a+d is greater than or equal to 1; and
more preferably, a is 0, and d is 1; or a is 1, and d is 1.

22. The organic electroluminescent device according to claim 1, wherein the fluorescent emissive material has a structure represented by one of Formula 4-1 to Formula 4-7: 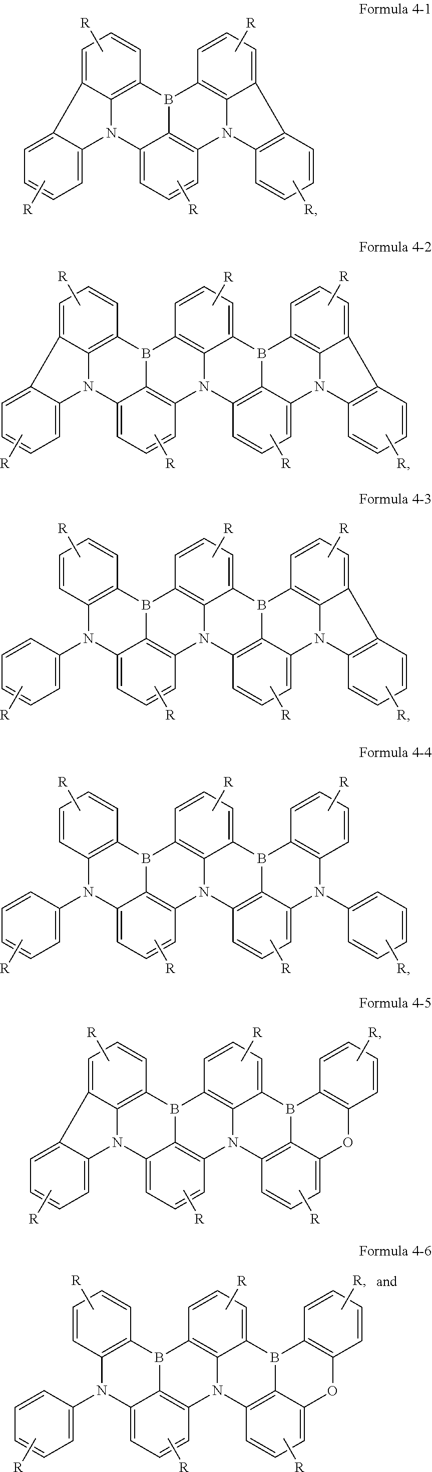 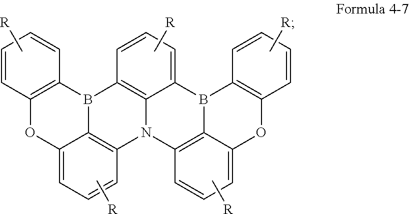
wherein,
R represents, at each occurrence identically or differently, mono-substitution, multiple substitutions or non-substitution;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR^{B}R^{B} and combinations thereof;
R^{B} is, at each occurrence identically or differently, selected from the group consisting of; hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R and R^{B} can be optionally joined to form a ring; and
preferably, the fluorescent emissive material has a structure represented by Formula 4-1 or Formula 4-2.

23. The organic electroluminescent device according to claim 17, wherein R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms and combinations thereof;
preferably, R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms and combinations thereof; and
more preferably, a plurality of R exist in Formula 4-1 to Formula 4-7, and at least one of the plurality of R is selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms or a combination thereof.

24. The organic electroluminescent device according to claim 1, wherein the fluorescent emissive material is selected from the group consisting of Compound DF-1 to Compound DF-102: 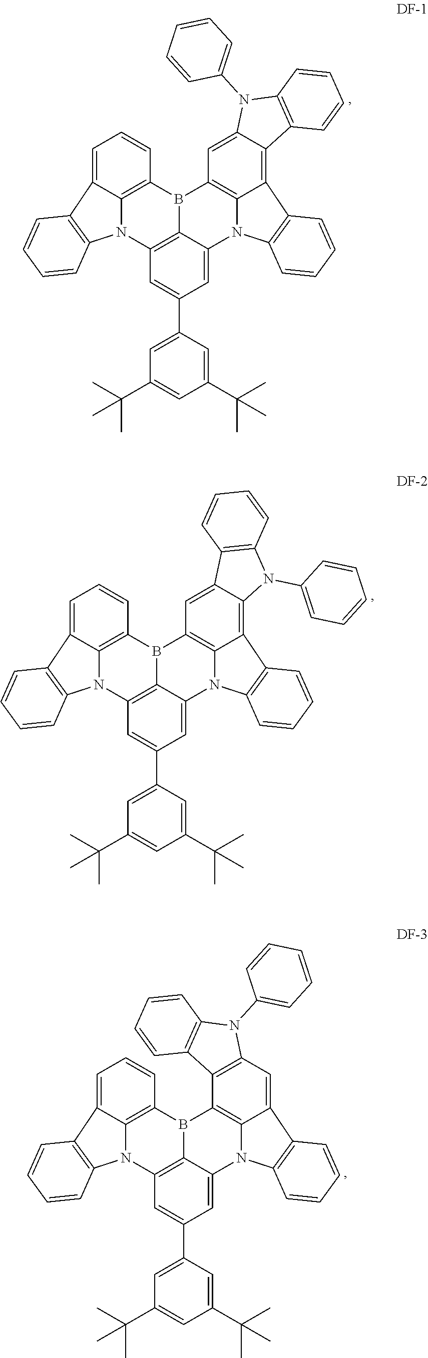 [SMILES: CC(C)(C)c1cc(-c2cc3c4c(c2)-n2c5ccccc5c5c6c7ccccc7n(-c7ccccc7)c6cc(c52)B4c2cccc4c5ccccc5n-3c24)cc(C(C)(C)C)c1 ; CC(C)(C)c1cc(-c2cc3c4c(c2)-n2c5ccccc5c5c2c(cc2c6ccccc6n(-c6ccccc6)c25)B4c2cccc4c5ccccc5n-3c24)cc(C(C)(C)C)c1 ; CC(C)(C)c1cc(-c2cc3c4c(c2)-n2c5ccccc5c5cc6c(c(c52)B4c2cccc4c5ccccc5n-3c24)c2ccccc2n6-c2ccccc2)cc(C(C)(C)C)c1] 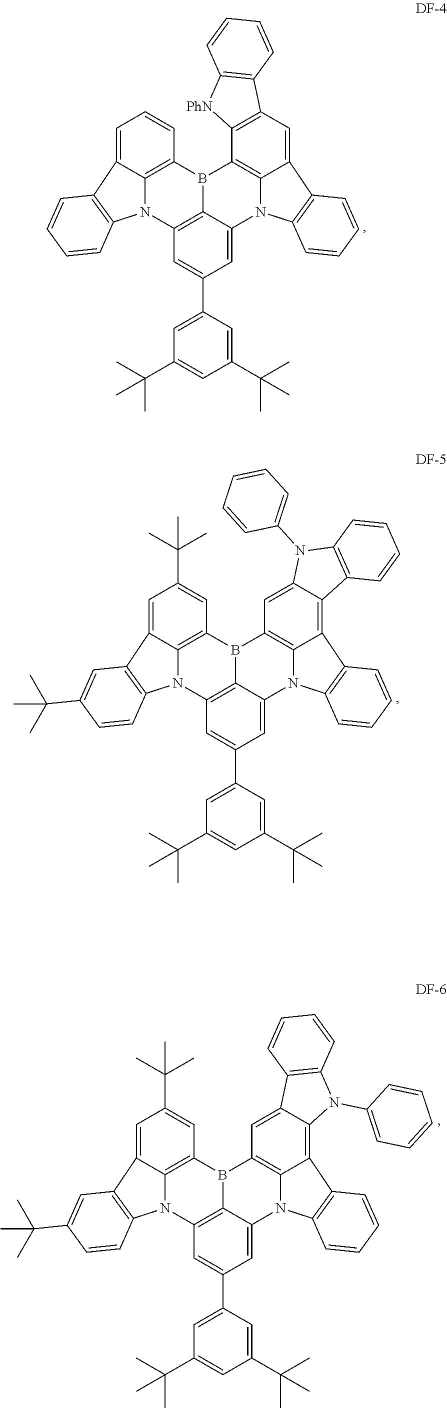 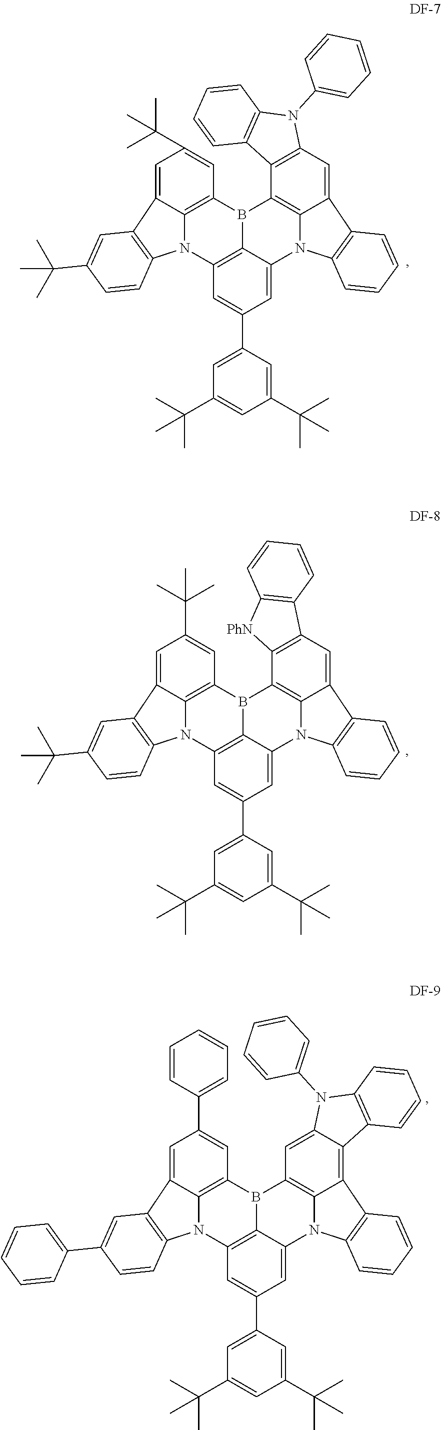 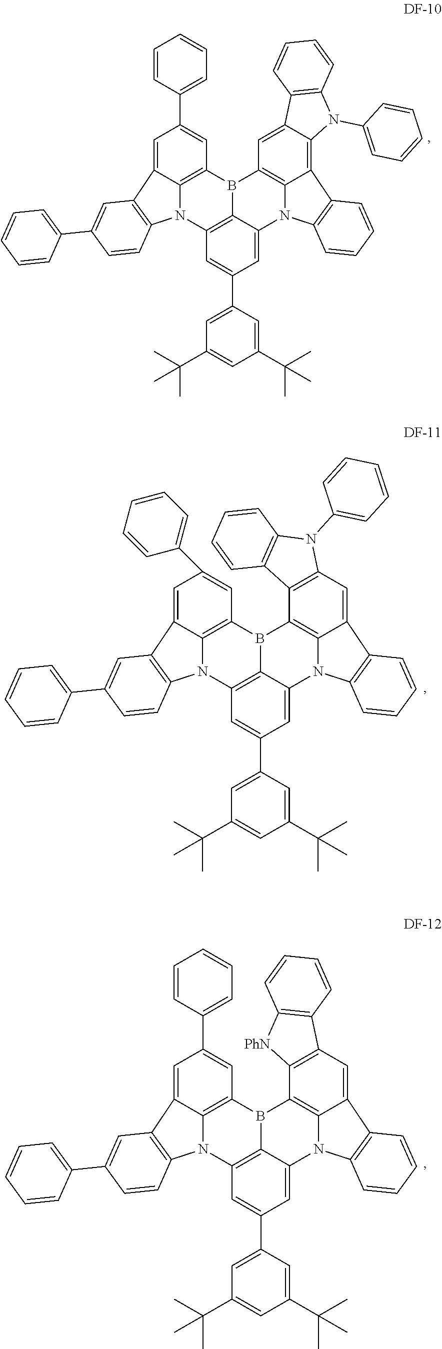 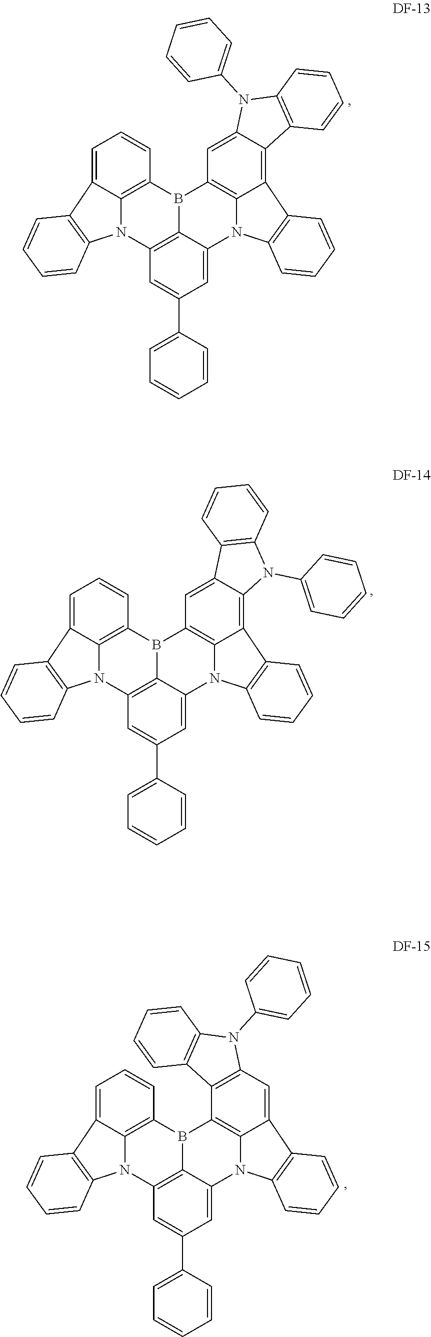 [SMILES: c1ccc(-c2cc3c4c(c2)-n2c5ccccc5c5c6c7ccccc7n(-c7ccccc7)c6cc(c52)B4c2cccc4c5ccccc5n-3c24)cc1 ; c1ccc(-c2cc3c4c(c2)-n2c5ccccc5c5c2c(cc2c6ccccc6n(-c6ccccc6)c25)B4c2cccc4c5ccccc5n-3c24)cc1 ; c1ccc(-c2cc3c4c(c2)-n2c5ccccc5c5cc6c(c(c52)B4c2cccc4c5ccccc5n-3c24)c2ccccc2n6-c2ccccc2)cc1] 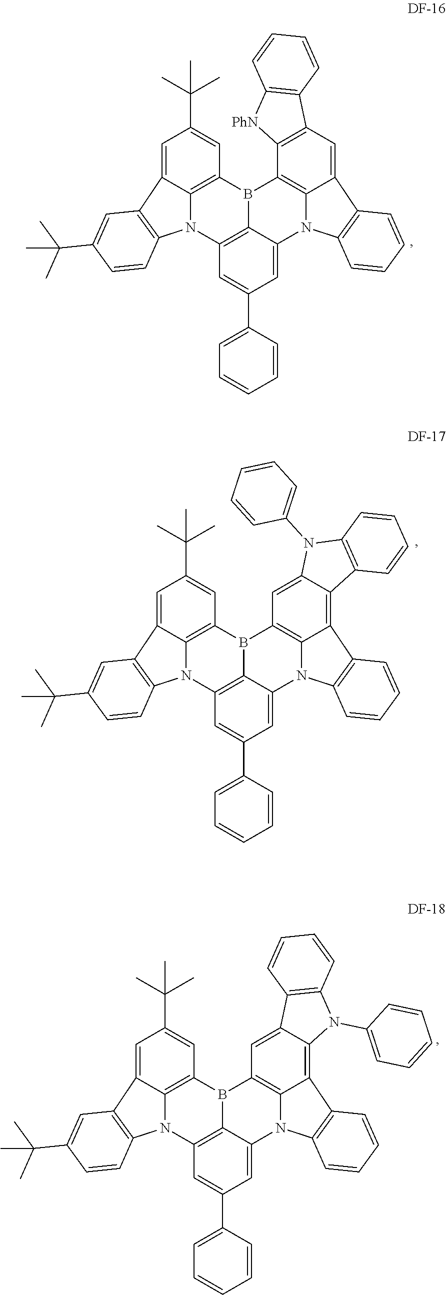 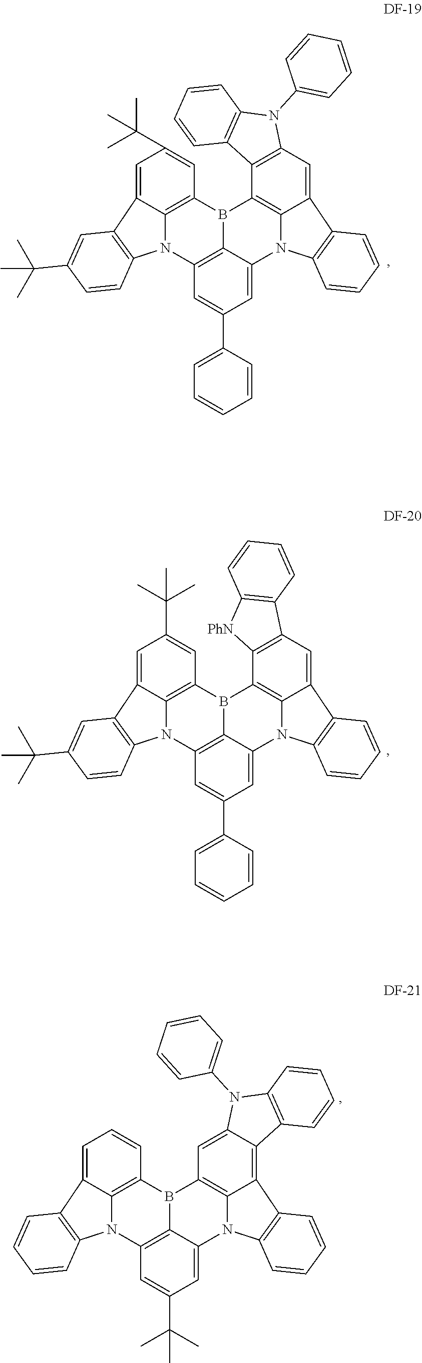 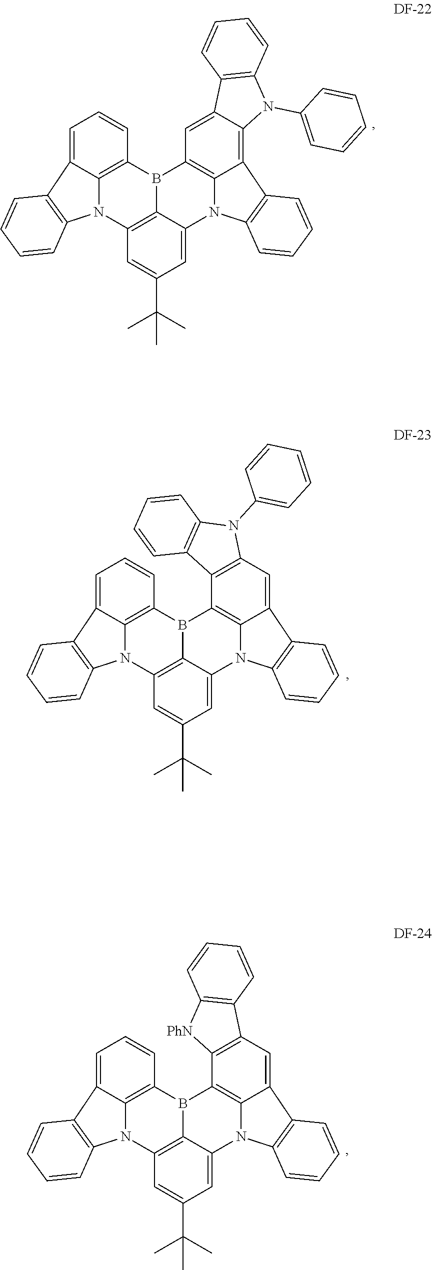 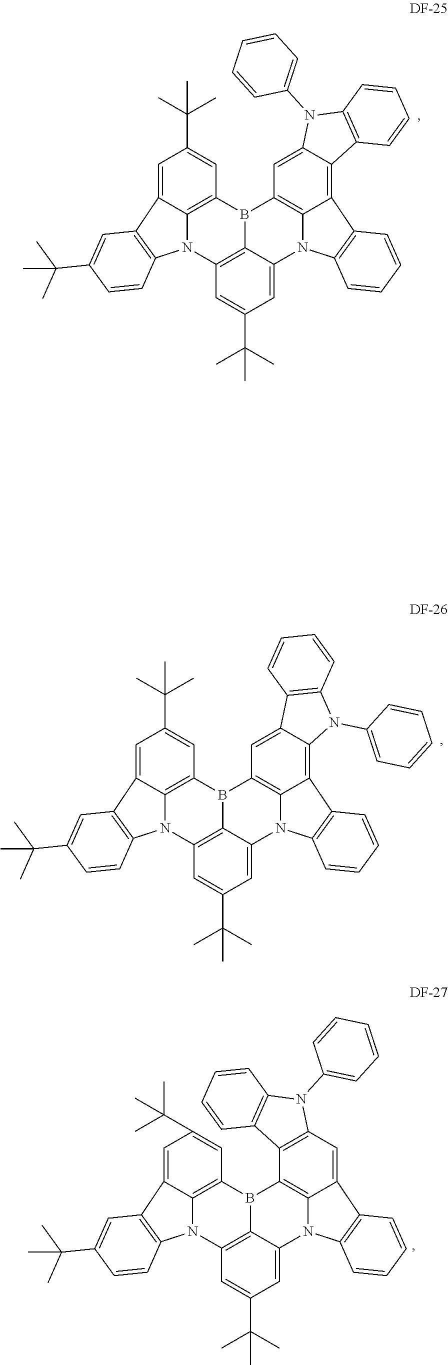 [SMILES: CC(C)(C)c1cc2c3c(c1)-n1c4ccccc4c4c5c6ccccc6n(-c6ccccc6)c5cc(c41)B3c1cc(C(C)(C)C)cc3c4cc(C(C)(C)C)ccc4n-2c13 ; CC(C)(C)c1cc2c3c(c1)-n1c4ccccc4c4c1c(cc1c5ccccc5n(-c5ccccc5)c14)B3c1cc(C(C)(C)C)cc3c4cc(C(C)(C)C)ccc4n-2c13 ; CC(C)(C)c1cc2c3c(c1)-n1c4ccccc4c4cc5c(c(c41)B3c1cc(C(C)(C)C)cc3c4cc(C(C)(C)C)ccc4n-2c13)c1ccccc1n5-c1ccccc1] 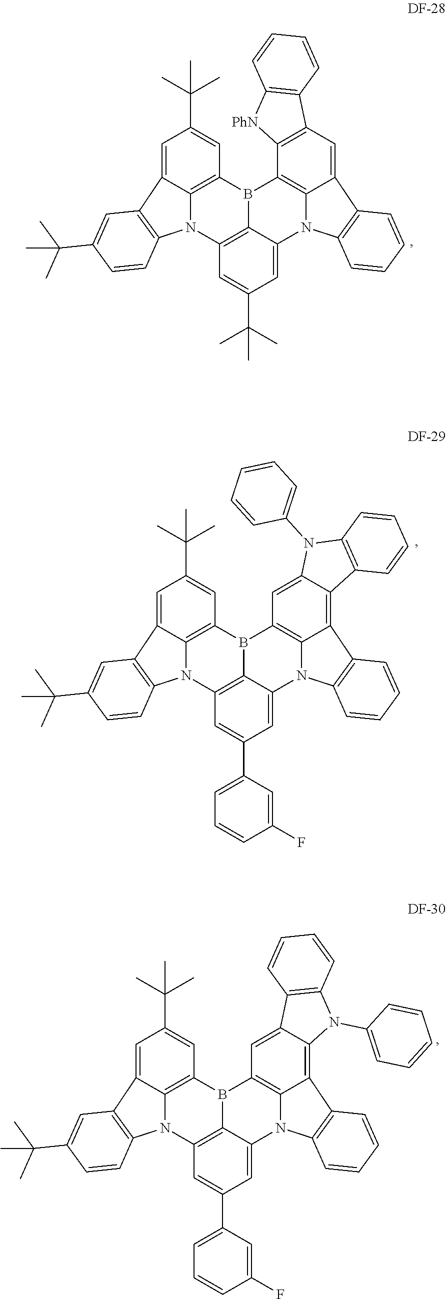 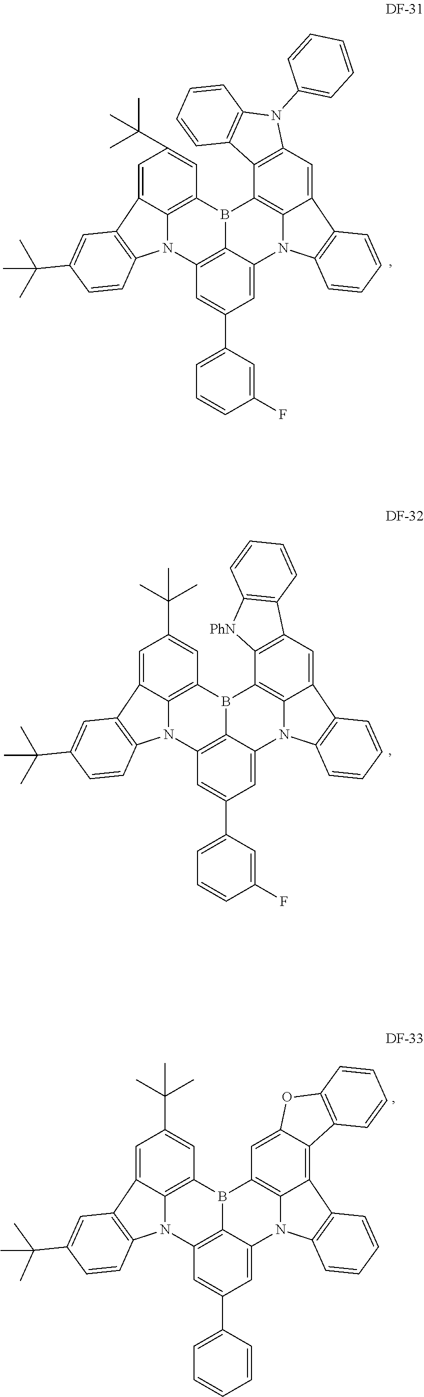 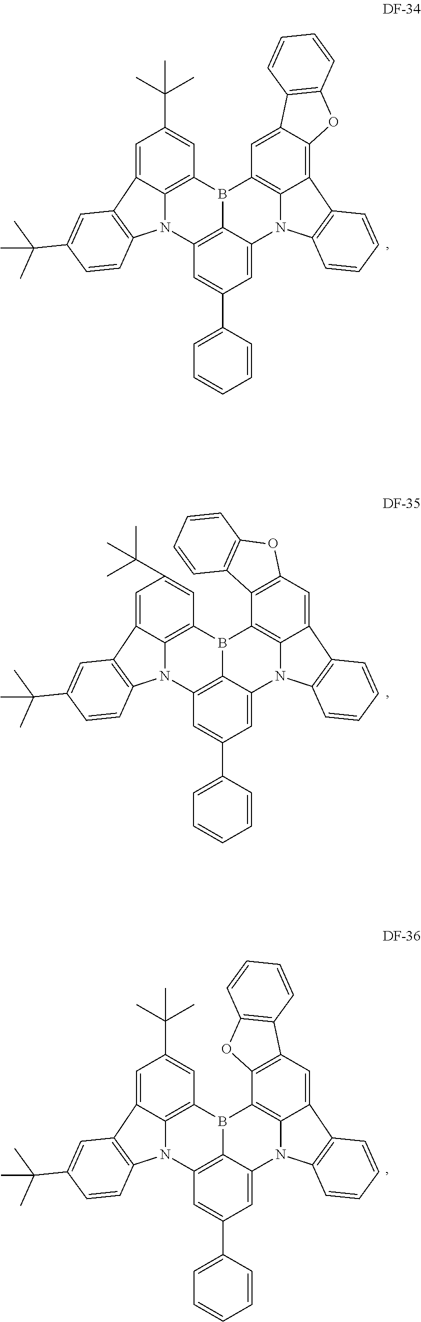 [SMILES: CC(C)(C)c1ccc2c(c1)c1cc(C(C)(C)C)cc3c1n2-c1cc(-c2ccccc2)cc2c1B3c1cc3c4ccccc4oc3c3c4ccccc4n-2c13 ; CC(C)(C)c1ccc2c(c1)c1cc(C(C)(C)C)cc3c1n2-c1cc(-c2ccccc2)cc2c1B3c1c3c(cc4c5ccccc5n-2c14)oc1ccccc13 ; CC(C)(C)c1ccc2c(c1)c1cc(C(C)(C)C)cc3c1n2-c1cc(-c2ccccc2)cc2c1B3c1c3oc4ccccc4c3cc3c4ccccc4n-2c13] 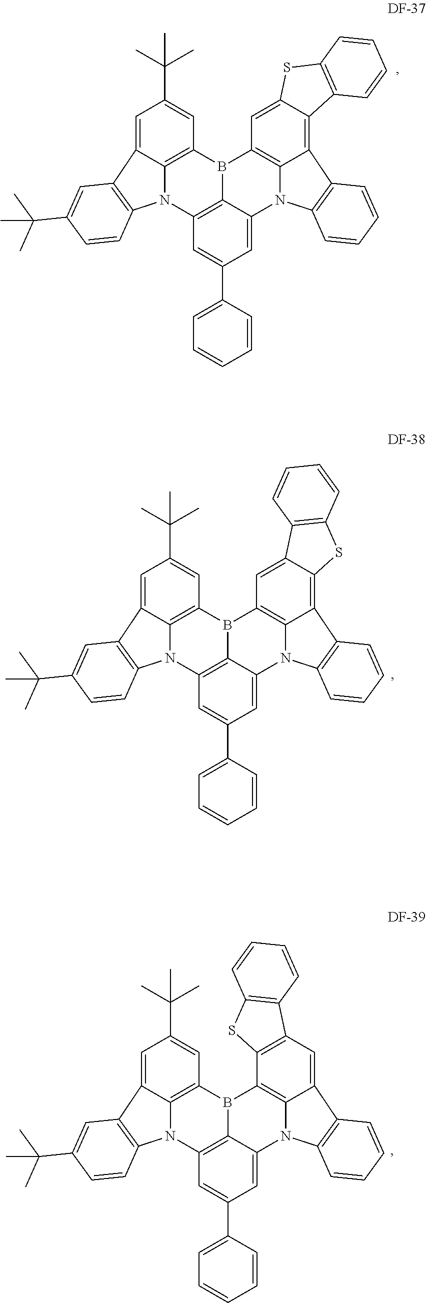 [SMILES: CC(C)(C)c1ccc2c(c1)c1cc(C(C)(C)C)cc3c1n2-c1cc(-c2ccccc2)cc2c1B3c1cc3sc4ccccc4c3c3c4ccccc4n-2c13 ; CC(C)(C)c1ccc2c(c1)c1cc(C(C)(C)C)cc3c1n2-c1cc(-c2ccccc2)cc2c1B3c1cc3c4ccccc4sc3c3c4ccccc4n-2c13 ; CC(C)(C)c1ccc2c(c1)c1cc(C(C)(C)C)cc3c1n2-c1cc(-c2ccccc2)cc2c1B3c1c3sc4ccccc4c3cc3c4ccccc4n-2c13] 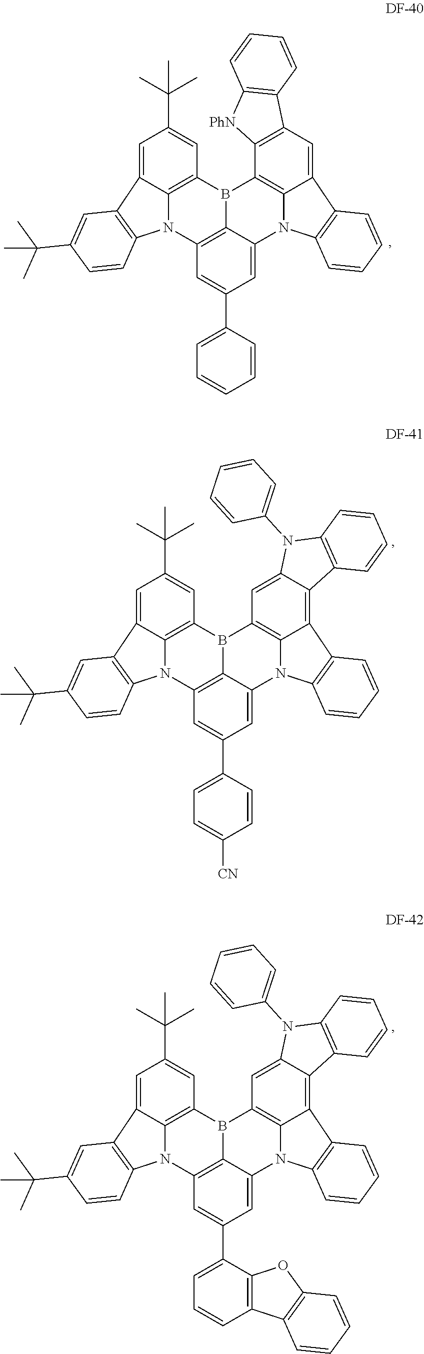 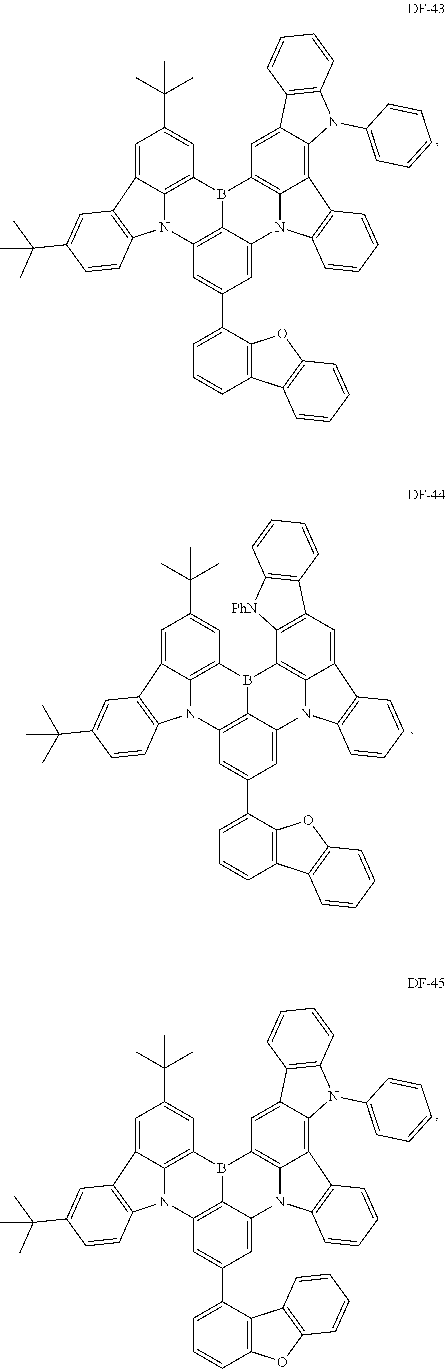 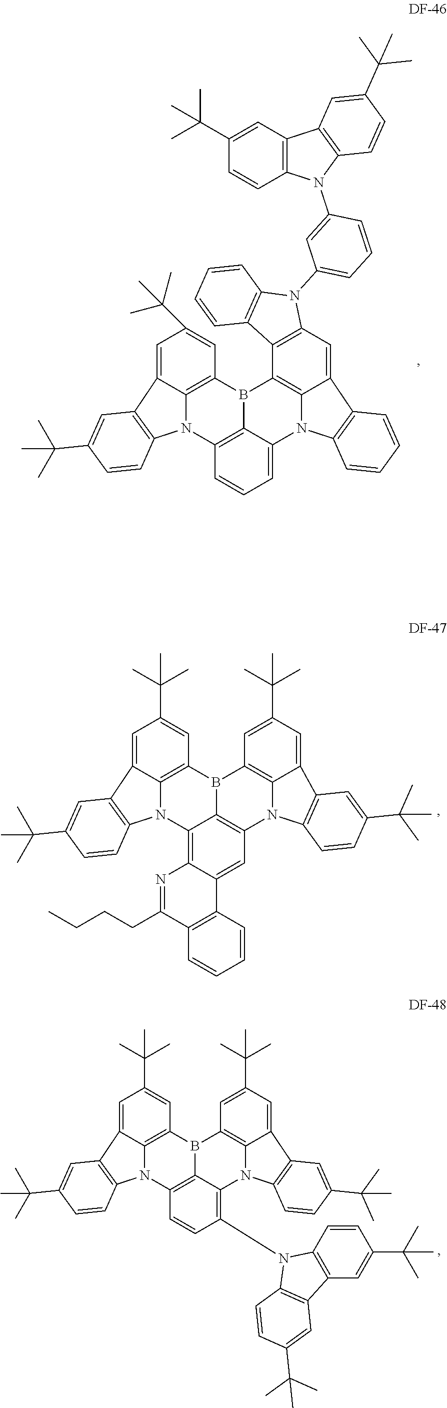 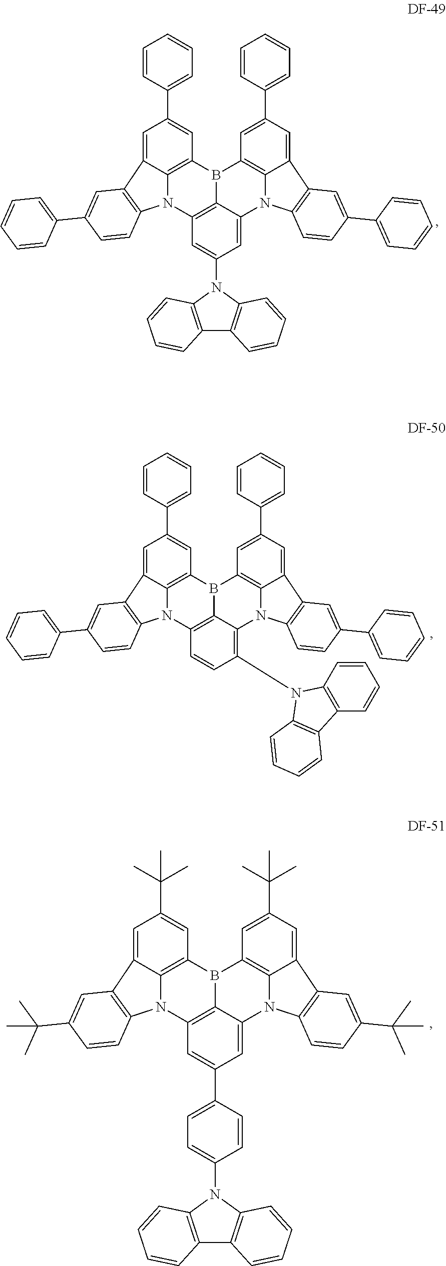 [SMILES: c1ccc(-c2ccc3c(c2)c2cc(-c4ccccc4)cc4c2n3-c2cc(-n3c5ccccc5c5ccccc53)cc3c2B4c2cc(-c4ccccc4)cc4c5cc(-c6ccccc6)ccc5n-3c24)cc1 ; c1ccc(-c2ccc3c(c2)c2cc(-c4ccccc4)cc4c2n3-c2ccc(-n3c5ccccc5c5ccccc53)c3c2B4c2cc(-c4ccccc4)cc4c5cc(-c6ccccc6)ccc5n-3c24)cc1 ; CC(C)(C)c1ccc2c(c1)c1cc(C(C)(C)C)cc3c1n2-c1cc(-c2ccc(-n4c5ccccc5c5ccccc54)cc2)cc2c1B3c1cc(C(C)(C)C)cc3c4cc(C(C)(C)C)ccc4n-2c13] 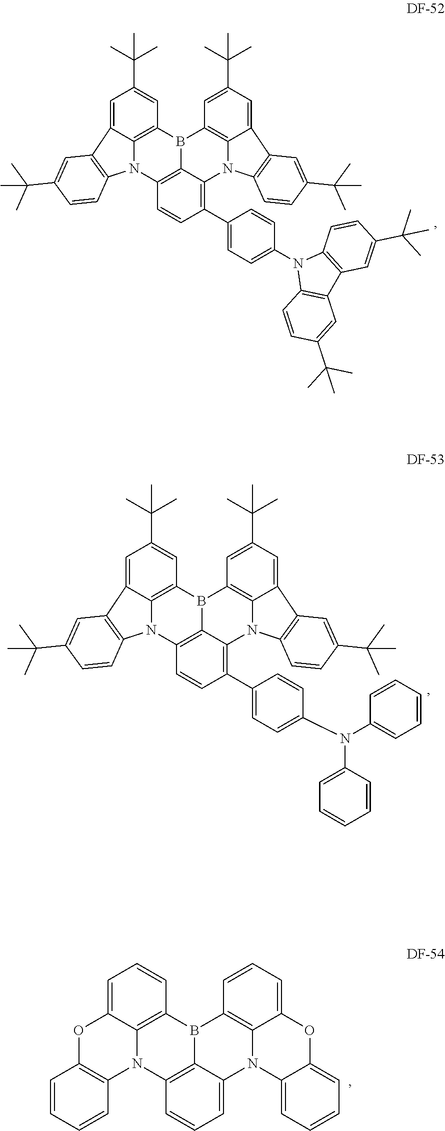 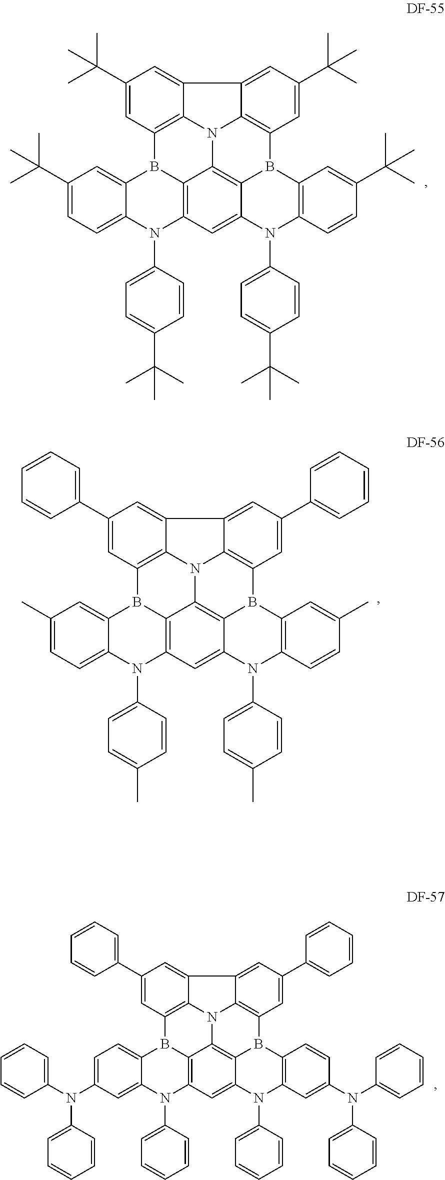 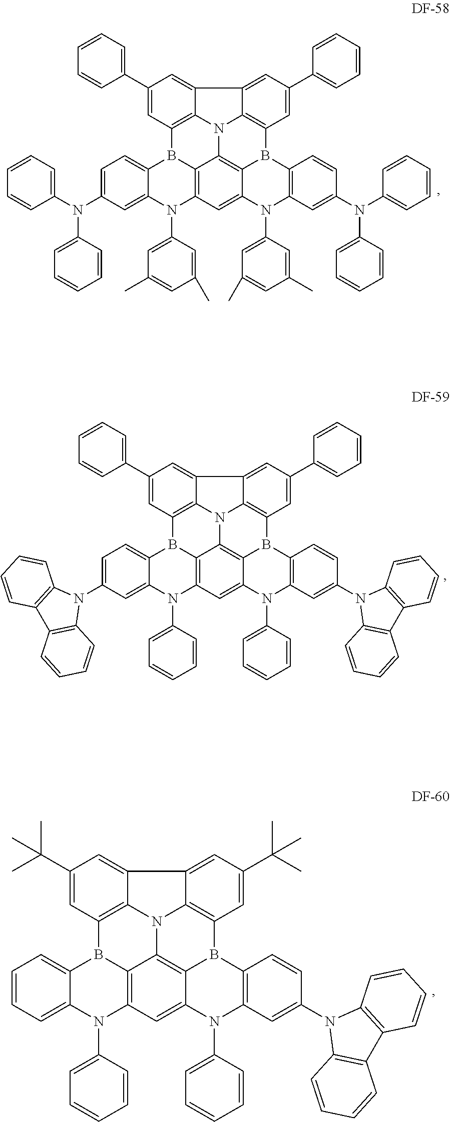 [SMILES: Cc1cc(C)cc(N2c3cc(N(c4ccccc4)c4ccccc4)ccc3B3c4c2cc2c5c4-n4c6c3cc(-c3ccccc3)cc6c3cc(-c6ccccc6)cc(c34)B5c3ccc(N(c4ccccc4)c4ccccc4)cc3N2c2cc(C)cc(C)c2)c1 ; c1ccc(-c2cc3c4c(c2)c2cc(-c5ccccc5)cc5c2n4-c2c4c(cc6c2B5c2ccc(-n5c7ccccc7c7ccccc75)cc2N6c2ccccc2)N(c2ccccc2)c2cc(-n5c6ccccc6c6ccccc65)ccc2B43)cc1 ; CC(C)(C)c1cc2c3c(c1)c1cc(C(C)(C)C)cc4c1n3-c1c3c(cc5c1B4c1ccc(-n4c6ccccc6c6ccccc64)cc1N5c1ccccc1)N(c1ccccc1)c1ccccc1B32] 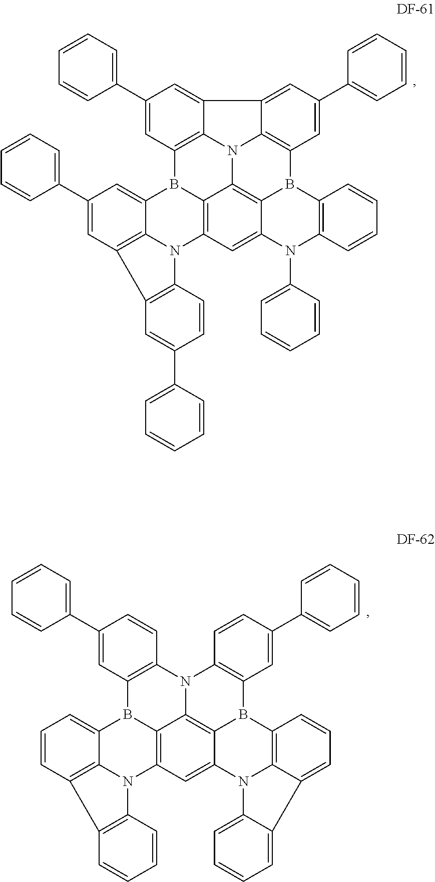 [SMILES: c1ccc(-c2ccc3c(c2)c2cc(-c4ccccc4)cc4c2n3-c2cc3c5c6c2B4c2cc(-c4ccccc4)cc4c7cc(-c8ccccc8)cc(c7n-6c24)B5c2ccccc2N3c2ccccc2)cc1 ; c1ccc(-c2ccc3c(c2)B2c4c(cc5c6c4N3c3ccc(-c4ccccc4)cc3B6c3cccc4c6ccccc6n-5c34)-n3c4ccccc4c4cccc2c43)cc1] 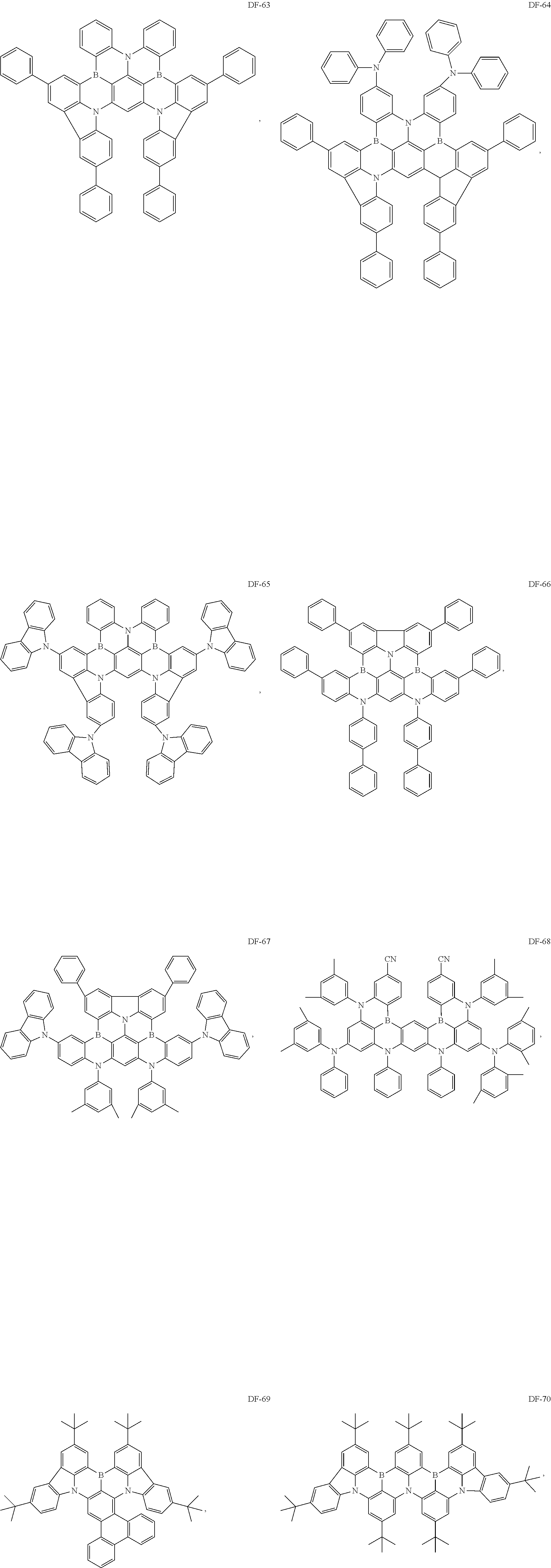 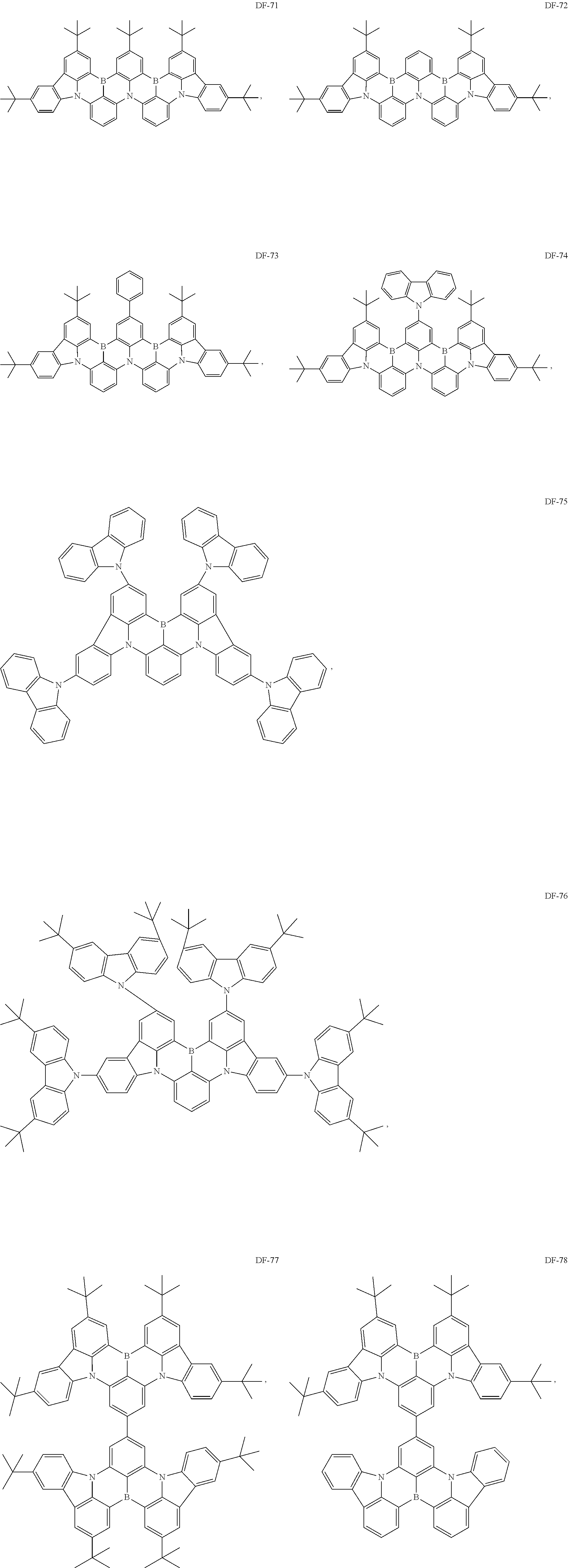 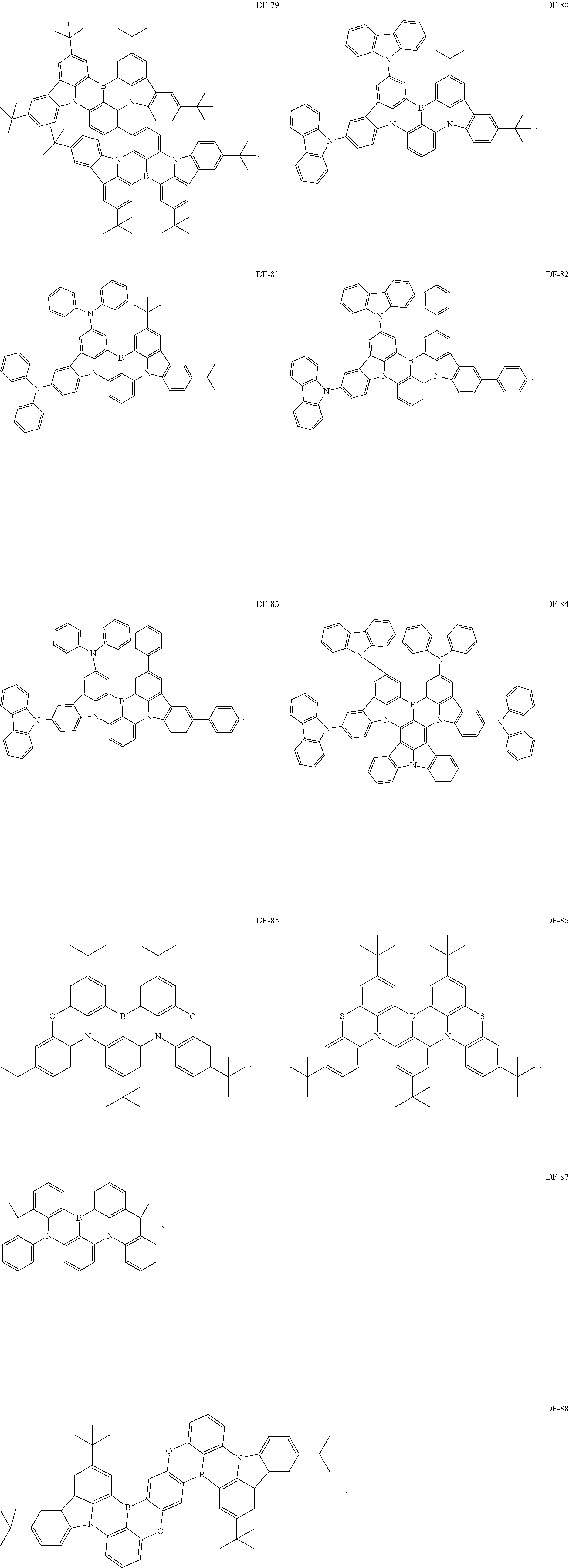 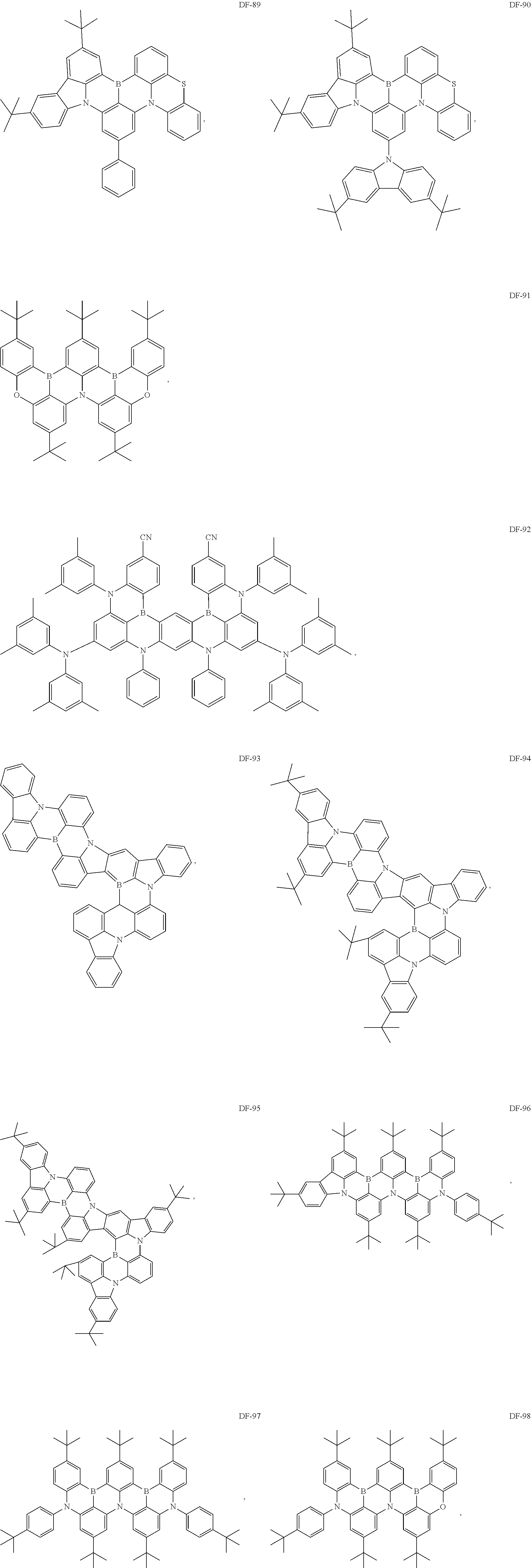 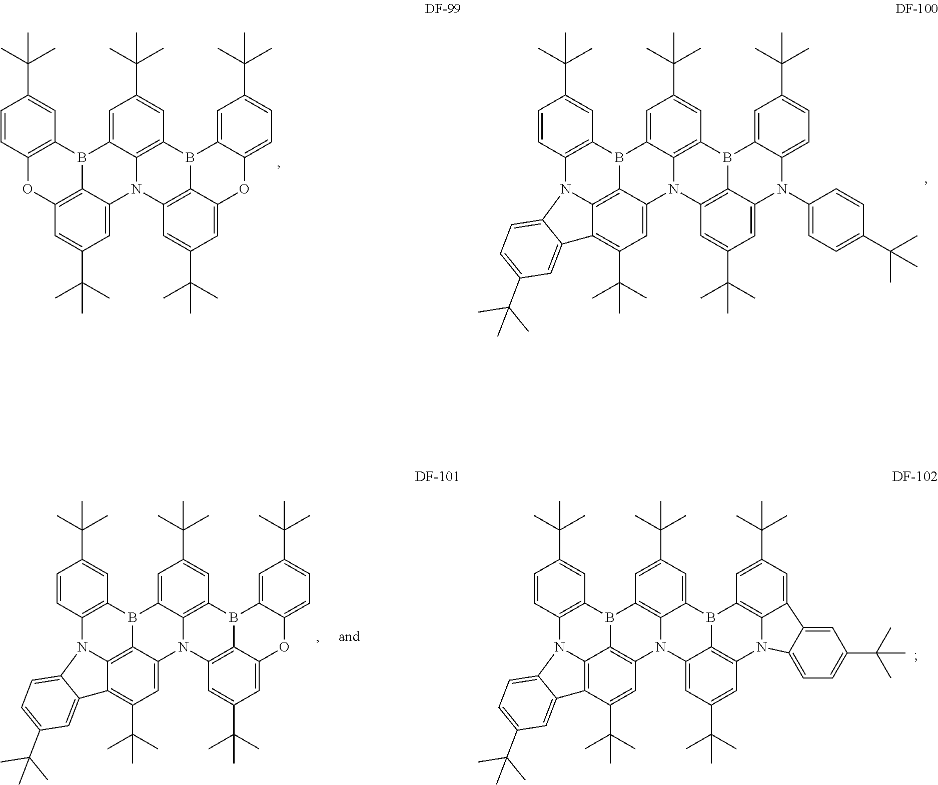
optionally, hydrogen in Compound DF-1 to Compound DF-102 can be partially or fully substituted with deuterium.

25. The organic electroluminescent device according to claim 1, wherein the fluorescent emissive material is a delayed fluorescence material;
preferably, the fluorescent emissive material is a thermally activated delayed fluorescence material.

26. A display device, comprising the organic electroluminescent device according to claim 1.
